(19) United States
(12) Patent Application Publication
(10) Pub. No.: US 2026/0247596 A1
(43) Pub. Date: Aug. 20, 2026

(54) SEMICONDUCTOR DEVICE AND METHOD FOR MANUFACTURING SEMICONDUCTOR DEVICE

(71) Applicant: RAPIDUS CORPORATION, Tokyo (JP)

(72) Inventor: Mitsunari Sukekawa, Albany, NY (US)

(21) Appl. No.: 19/636,400

(22) Filed: Apr. 1, 2026

Related U.S. Application Data
(63) Continuation of application No. PCT/JP2024/029062, filed on Aug. 15, 2024.
(60) Provisional application No. 63/626,165, filed on Jan. 29, 2024.

(51) Int. Cl. H10B 10/00

(52) U.S. Cl. CPC H10B 10/125

(57) ABSTRACT

Semiconductor memory elements with increased integration density are disclosed. In one example, a semiconductor device includes semiconductor elements on a substrate respectively including a first nanosheet semiconductor element, a second nanosheet semiconductor element, and a vertical semiconductor element. A contact connects the first nanosheet semiconductor element and the second nanosheet semiconductor element, and the vertical semiconductor element is disposed between the substrate and the first nanosheet semiconductor element.

### CROSS REFERENCE TO RELATED APPLICATIONS

This application is a continuation of International Application No. PCT/JP2024/029062, filed on August 15, 2024, which claims the benefit of U.S. Provisional Application No. 63/626,165 filed January 29, 2024. The entire contents of each of these applications are incorporated herein by reference.

### TECHNICAL FIELD

The present invention relates to a semiconductor device and a method for manufacturing the semiconductor device.

### BACKGROUND ART

A static random access memory (SRAM) is widely used as a semiconductor device. Since the SRAM has a high reading and writing speed, the SRAM is used for applications in which a high processing speed is required.

In the SRAM, one cell is constituted by six transistors (Tr) consisting of two pull-up (PU) transistors, two pull-down (PD) transistors, and two pass gate (PG) transistors. Since the SRAM has a complicated element structure, it is difficult to improve an integration density (to perform miniaturization and high integration) by downsizing an element and reducing a cell area. In response to such a demand for high integration of the SRAM, a structure in which each transistor is formed by a fin field effect transistor (FinFET) has been proposed (See, for example, Patent Literature 1.).

In addition, as the SRAM, a structure in which each of a pull-up transistor and a pull-down transistor is formed by a complementary field-effect transistor (CFET) in order to reduce a cell area has been proposed (See, for example, Non Patent Literature 1.).

### Citation List

### Patent Literature

Patent Literature 1: US 2014/0131813 A

Non Patent Literature 1: Mohit Kumar Gupta et al., The Complementary FET (CFET) 6T-SRAM, IEEE TRANSACTIONS ON ELECTRON DEVICES, VOL. 68, NO. 12, DECEMBER 2021, 6106-6111

### Summary of Invention

### Technical Problem

However, the SRAM having the structure described in Patent Literature 1 can miniaturize the Tr by the FinFET, but there is no change in the number of Trs arranged on a plane. Therefore, in the structure described in Patent Literature 1, there is a limit to improvement of the integration density.

In addition, in the SRAM having the structure described in Non-Patent Literature 1, two pass gate transistors are arranged in a planar direction of a substrate with respect to pull-up transistors and pull-down transistors constituted by CFETs. Therefore, in the planar arrangement, an extra area for forming the pass gate transistors is required with respect to the area for forming the pull-up transistors and the pull-down transistors. Therefore, even in the structure described in Non-Patent Literature 1, there is a limit to improvement of the integration density.

In order to solve the above-described problems, the present invention provides a semiconductor device capable of improving an integration density, and a method for manufacturing the semiconductor device.

### Solution to Problem

A semiconductor device of the present invention includes a plurality of semiconductor elements on a substrate. Each of the plurality of semiconductor elements includes a first nanosheet semiconductor element, a second nanosheet semiconductor element, and a vertical semiconductor element, and includes a contact that connects the first nanosheet semiconductor element and the second nanosheet semiconductor element, and the vertical semiconductor element is disposed between the substrate and the first nanosheet semiconductor element.

In addition, the semiconductor device of the present invention includes the plurality of semiconductor elements on the substrate. Each of the plurality of semiconductor elements includes at least a first nanosheet semiconductor element, a second nanosheet semiconductor element, and a third nanosheet semiconductor element. The second nanosheet semiconductor element is stacked on the first nanosheet semiconductor element, the first nanosheet semiconductor element and the third nanosheet semiconductor element are arranged in parallel to a surface of the substrate, there is a contact connecting the first nanosheet semiconductor element and the second nanosheet semiconductor element in an element isolation region between the first nanosheet semiconductor element and the second nanosheet semiconductor element, and a gate of the first nanosheet semiconductor element, a gate of the third nanosheet semiconductor element, and the contact are isolated from each other.

The method for manufacturing a semiconductor device according to the present invention is a method for manufacturing a semiconductor device including a first nanosheet semiconductor element, a second nanosheet semiconductor element, and a vertical semiconductor element on a substrate. The method for manufacturing a semiconductor device includes: a step of forming a channel region constituting a vertical semiconductor element and one source/drain region on a substrate; a step of forming a stack of a first semiconductor layer and a sacrificial layer on the channel region of the vertical semiconductor element; a step of forming a stack of a second semiconductor layer and a sacrificial layer; a step of removing the sacrificial layers, embedding a metal layer, and forming a gate electrode covering a periphery of the first semiconductor layer and the second semiconductor layer in a cross section in a gate width direction; a step of forming source/drain regions on side surfaces of the first semiconductor layer and the second semiconductor layer; and a step of forming a contact connecting the source/drain regions formed on the side surfaces of the first semiconductor layer and the second semiconductor layer.

### Advantageous Effects of Invention

According to the present invention, it is possible to provide a semiconductor device capable of improving an integration density and a method for manufacturing a semiconductor memory element.

### BRIEF DESCRIPTION OF DRAWINGS

FIG. 1 is an equivalent circuit diagram of a semiconductor device.

FIG. 2 is a plan layout view (top view) of a semiconductor device of a first embodiment.

FIG. 3 is a cross-sectional view taken along line A-A of the semiconductor device illustrated in FIG. 2.

FIG. 4 is a cross-sectional view taken along line B-B of the semiconductor device illustrated in FIG. 2.

FIG. 5 is a cross-sectional view taken along line C-C of the semiconductor device illustrated in FIG. 2.

FIG. 6 is a manufacturing process diagram (top view) of the semiconductor device of the first embodiment.

FIG. 7 is a manufacturing process diagram (cross-sectional view taken along line A-A) of the semiconductor device of the first embodiment.

FIG. 8 is a manufacturing process diagram (cross-sectional view taken along line B-B) of the semiconductor device of the first embodiment.

FIG. 9 is a manufacturing process diagram (cross-sectional view taken along line C-C) of the semiconductor device of the first embodiment.

FIG. 10 is a manufacturing process diagram (top view) of the semiconductor device of the first embodiment.

FIG. 11 is a manufacturing process diagram (cross-sectional view taken along line A-A) of the semiconductor device of the first embodiment.

FIG. 12 is a manufacturing process diagram (cross-sectional view taken along line B-B) of the semiconductor device of the first embodiment.

FIG. 13 is a manufacturing process diagram (cross-sectional view taken along line C-C) of the semiconductor device of the first embodiment.

FIG. 14 is a manufacturing process diagram (top view) of the semiconductor device of the first embodiment.

FIG. 15 is a manufacturing process diagram (cross-sectional view taken along line A-A) of the semiconductor device of the first embodiment.

FIG. 16 is a manufacturing process diagram (cross-sectional view taken along line B-B) of the semiconductor device of the first embodiment.

FIG. 17 is a manufacturing process diagram (cross-sectional view taken along line C-C) of the semiconductor device of the first embodiment.

FIG. 18 is a manufacturing process diagram (top view) of the semiconductor device of the first embodiment.

FIG. 19 is a manufacturing process diagram (cross-sectional view taken along line A-A) of the semiconductor device of the first embodiment.

FIG. 20 is a manufacturing process diagram (cross-sectional view taken along line B-B) of the semiconductor device of the first embodiment.

FIG. 21 is a manufacturing process diagram (cross-sectional view taken along line C-C) of the semiconductor device of the first embodiment.

FIG. 22 is a manufacturing process diagram (top view) of the semiconductor device of the first embodiment.

FIG. 23 is a manufacturing process diagram (cross-sectional view taken along line A-A) of the semiconductor device of the first embodiment.

FIG. 24 is a manufacturing process diagram (cross-sectional view taken along line B-B) of the semiconductor device of the first embodiment.

FIG. 25 is a manufacturing process diagram (cross-sectional view taken along line C-C) of the semiconductor device of the first embodiment.

FIG. 26 is a manufacturing process diagram (top view) of the semiconductor device of the first embodiment.

FIG. 27 is a manufacturing process diagram (cross-sectional view taken along line A-A) of the semiconductor device of the first embodiment.

FIG. 28 is a manufacturing process diagram (cross-sectional view taken along line B-B) of the semiconductor device of the first embodiment.

FIG. 29 is a manufacturing process diagram (cross-sectional view taken along line C-C) of the semiconductor device of the first embodiment.

FIG. 30 is a manufacturing process diagram (top view) of the semiconductor device of the first embodiment.

FIG. 31 is a manufacturing process diagram (cross-sectional view taken along line A-A) of the semiconductor device of the first embodiment.

FIG. 32 is a manufacturing process diagram (cross-sectional view taken along line B-B) of the semiconductor device of the first embodiment.

FIG. 33 is a manufacturing process diagram (cross-sectional view taken along line C-C) of the semiconductor device of the first embodiment.

FIG. 34 is a manufacturing process diagram (top view) of the semiconductor device of the first embodiment.

FIG. 35 is a manufacturing process diagram (cross-sectional view taken along line A-A) of the semiconductor device of the first embodiment.

FIG. 36 is a manufacturing process diagram (cross-sectional view taken along line B-B) of the semiconductor device of the first embodiment.

FIG. 37 is a manufacturing process diagram (cross-sectional view taken along line C-C) of the semiconductor device of the first embodiment.

FIG. 38 is a manufacturing process diagram (top view) of the semiconductor device of the first embodiment.

FIG. 39 is a manufacturing process diagram (cross-sectional view taken along line A-A) of the semiconductor device of the first embodiment.

FIG. 40 is a manufacturing process diagram (cross-sectional view taken along line B-B) of the semiconductor device of the first embodiment.

FIG. 41 is a manufacturing process diagram (cross-sectional view taken along line C-C) of the semiconductor device of the first embodiment.

FIG. 42 is a manufacturing process diagram (top view) of the semiconductor device of the first embodiment.

FIG. 43 is a manufacturing process diagram (cross-sectional view taken along line A-A) of the semiconductor device of the first embodiment.

FIG. 44 is a manufacturing process diagram (cross-sectional view taken along line B-B) of the semiconductor device of the first embodiment.

FIG. 45 is a manufacturing process diagram (cross-sectional view taken along line C-C) of the semiconductor device of the first embodiment.

FIG. 46 is a manufacturing process diagram (top view) of the semiconductor device of the first embodiment.

FIG. 47 is a manufacturing process diagram (cross-sectional view taken along line A-A) of the semiconductor device of the first embodiment.

FIG. 48 is a manufacturing process diagram (cross-sectional view taken along line B-B) of the semiconductor device of the first embodiment.

FIG. 49 is a manufacturing process diagram (cross-sectional view taken along line C-C) of the semiconductor device of the first embodiment.

FIG. 50 is a plan layout view (top view) of a semiconductor device of a second embodiment.

FIG. 51 is a cross-sectional view taken along line A-A of the semiconductor device illustrated in FIG. 50.

FIG. 52 is a cross-sectional view taken along line B-B of the semiconductor device illustrated in FIG. 50.

FIG. 53 is a cross-sectional view taken along line C-C of the semiconductor device illustrated in FIG. 50.

FIG. 54 is a manufacturing process diagram (cross-sectional view taken along line C-C) of the semiconductor device of the second embodiment.

FIG. 55 is a manufacturing process diagram (cross-sectional view taken along line C-C) of the semiconductor device of the second embodiment.

FIG. 56 is a plan layout view (top view) of a semiconductor device of a third embodiment.

FIG. 57 is a cross-sectional view taken along line A-A of the semiconductor device illustrated in FIG. 56.

FIG. 58 is a cross-sectional view taken along line B-B of the semiconductor device illustrated in FIG. 56.

FIG. 59 is a cross-sectional view taken along line C-C of the semiconductor device illustrated in FIG. 56.

FIG. 60 is a manufacturing process diagram (top view) of the semiconductor device of the third embodiment.

FIG. 61 is a manufacturing process diagram (cross-sectional view taken along line A-A) of the semiconductor device of the third embodiment.

FIG. 62 is a manufacturing process diagram (cross-sectional view taken along line B-B) of the semiconductor device of the third embodiment.

FIG. 63 is a manufacturing process diagram (cross-sectional view taken along line C-C) of the semiconductor device of the third embodiment.

FIG. 64 is a manufacturing process diagram (top view) of the semiconductor device of the third embodiment.

FIG. 65 is a manufacturing process diagram (cross-sectional view taken along line A-A) of the semiconductor device of the third embodiment.

FIG. 66 is a manufacturing process diagram (cross-sectional view taken along line B-B) of the semiconductor device of the third embodiment.

FIG. 67 is a manufacturing process diagram (cross-sectional view taken along line C-C) of the semiconductor device of the third embodiment.

FIG. 68 is a manufacturing process diagram (top view) of the semiconductor device of the third embodiment.

FIG. 69 is a manufacturing process diagram (cross-sectional view taken along line A-A) of the semiconductor device of the third embodiment.

FIG. 70 is a manufacturing process diagram (cross-sectional view taken along line B-B) of the semiconductor device of the third embodiment.

FIG. 71 is a manufacturing process diagram (cross-sectional view taken along line C-C) of the semiconductor device of the third embodiment.

FIG. 72 is a manufacturing process diagram (top view) of the semiconductor device of the third embodiment.

FIG. 73 is a manufacturing process diagram (cross-sectional view taken along line A-A) of the semiconductor device of the third embodiment.

FIG. 74 is a manufacturing process diagram (cross-sectional view taken along line B-B) of the semiconductor device of the third embodiment.

FIG. 75 is a manufacturing process diagram (cross-sectional view taken along line C-C) of the semiconductor device of the third embodiment.

FIG. 76 is a manufacturing process diagram (top view) of the semiconductor device of the third embodiment.

FIG. 77 is a manufacturing process diagram (cross-sectional view taken along line A-A) of the semiconductor device of the third embodiment.

FIG. 78 is a manufacturing process diagram (cross-sectional view taken along line B-B) of the semiconductor device of the third embodiment.

FIG. 79 is a manufacturing process diagram (cross-sectional view taken along line C-C) of the semiconductor device of the third embodiment.

### DESCRIPTION OF EMBODIMENTS

Hereinafter, embodiments of a semiconductor device and a method for manufacturing the semiconductor device will be described with reference to the drawings, but the present invention is not limited to the following examples. Note that, in the following description, only components of a main part of the semiconductor device are illustrated in the drawings, and description of the other components such as an insulating layer is omitted.

The description will be given in the following order.
1. Semiconductor device of first embodiment
2. Method for manufacturing semiconductor device of first embodiment
3. Semiconductor device of second embodiment
4. Method for manufacturing semiconductor device of second embodiment
5. Semiconductor device of third embodiment
6. Method for manufacturing semiconductor device of third embodiment

1. First embodiment of semiconductor device

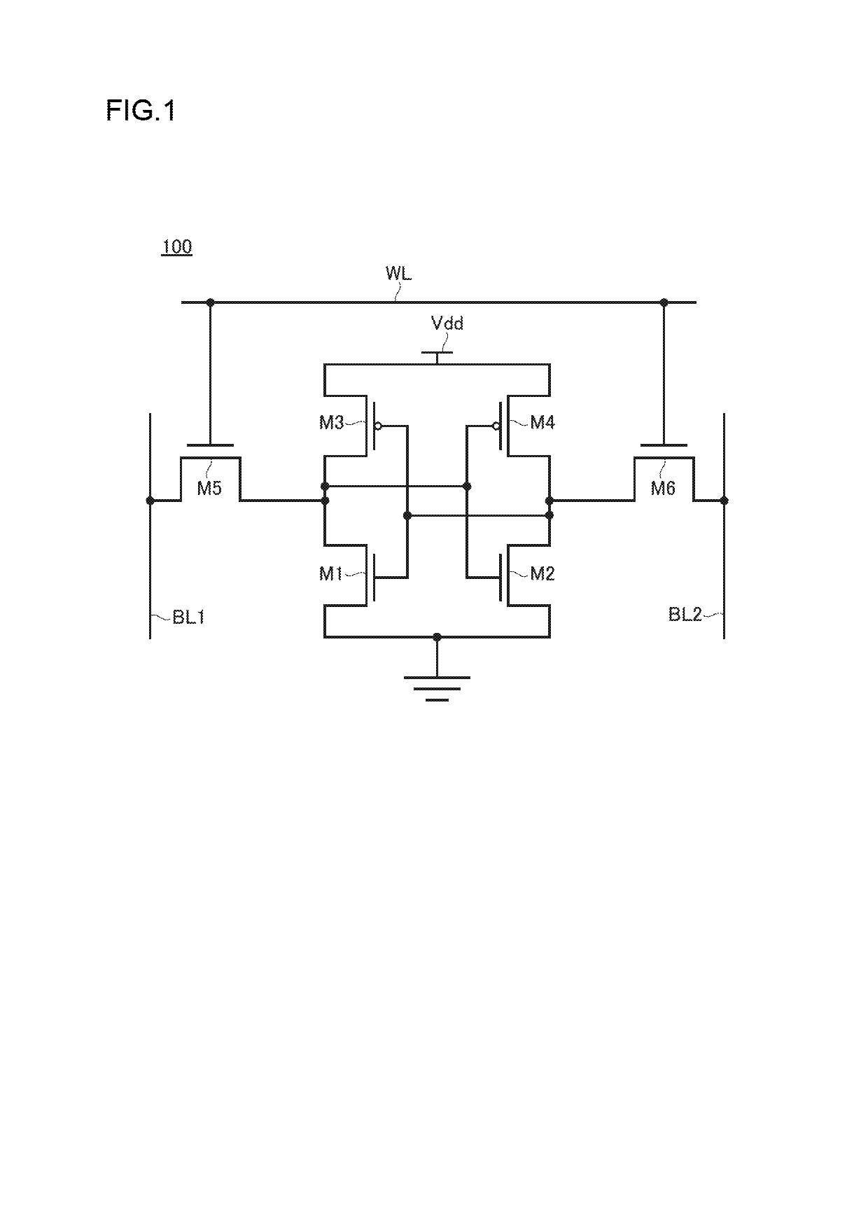

Hereinafter, specific embodiments of a semiconductor device of the present invention will be described. FIGS. 1 to 5 illustrate schematic structure diagrams of a semiconductor memory element as an example of a semiconductor device of a first embodiment.

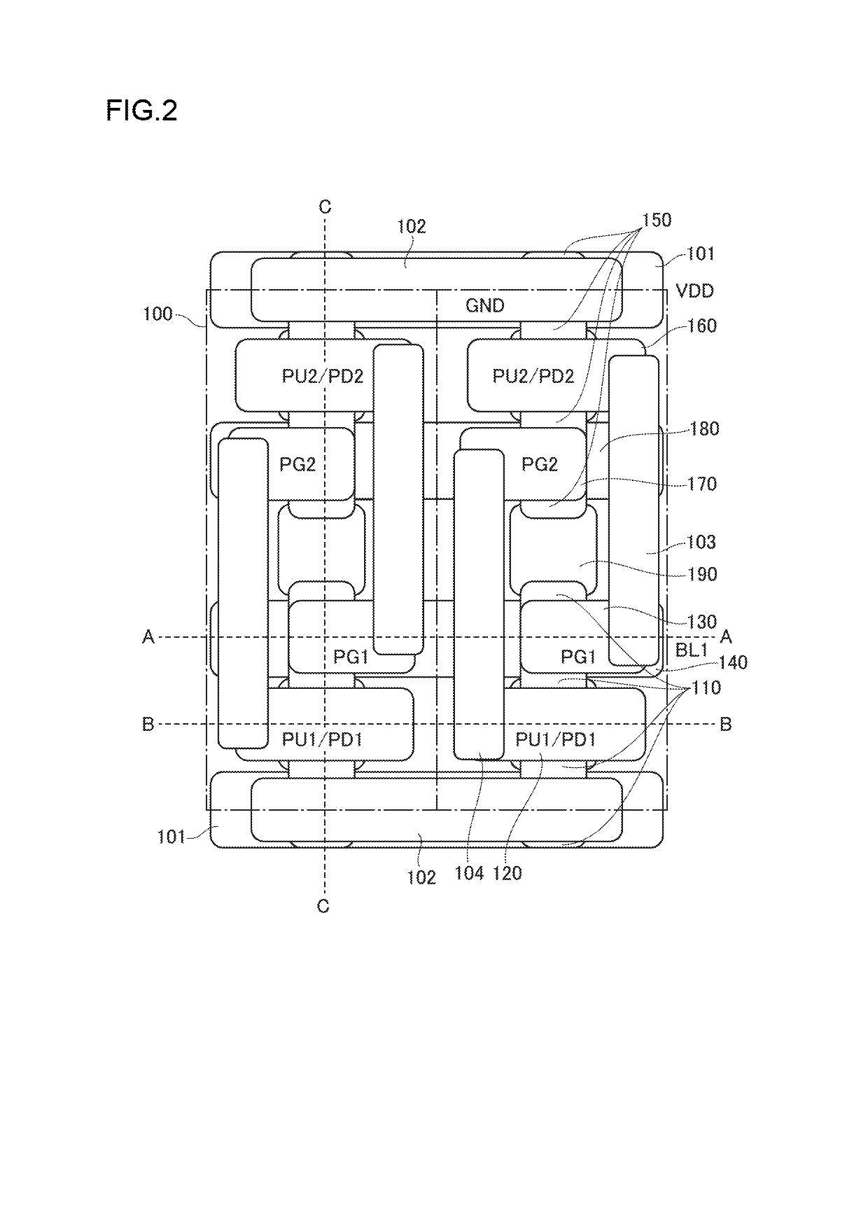

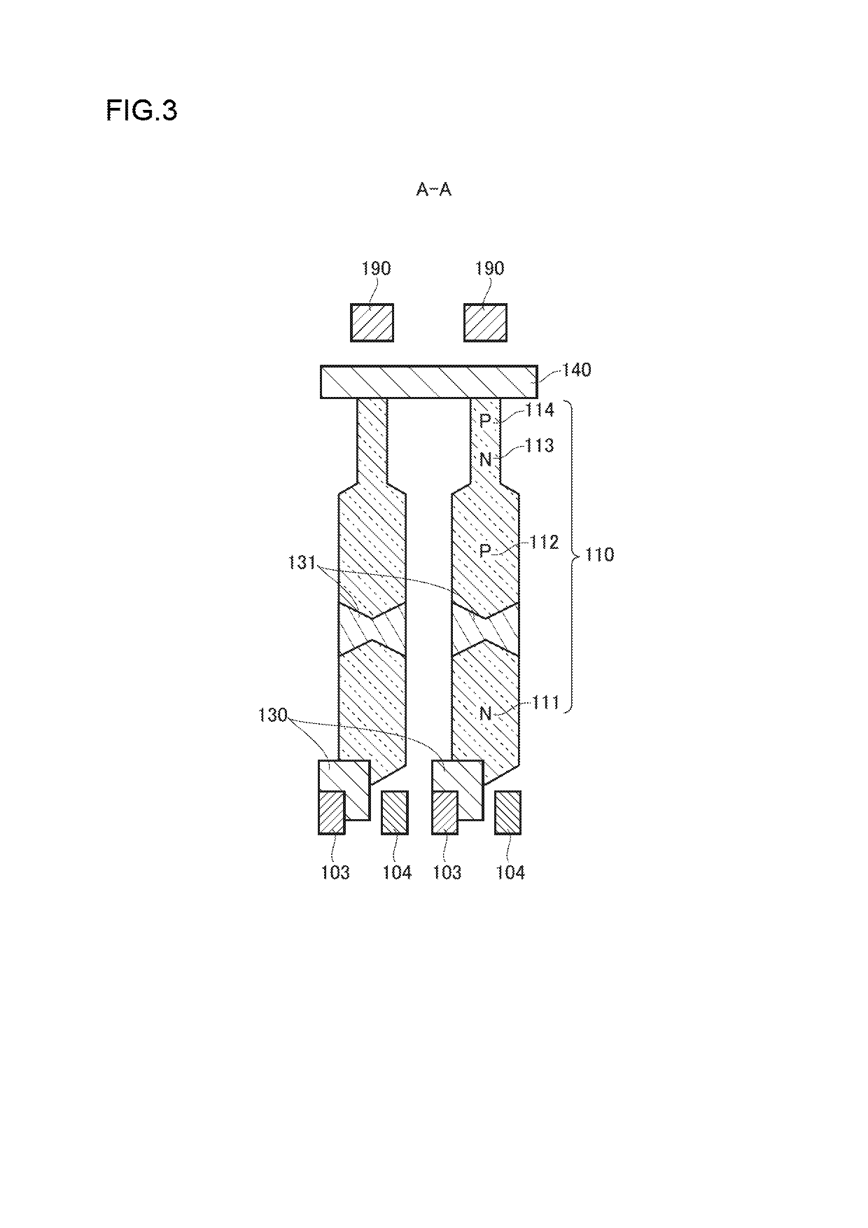

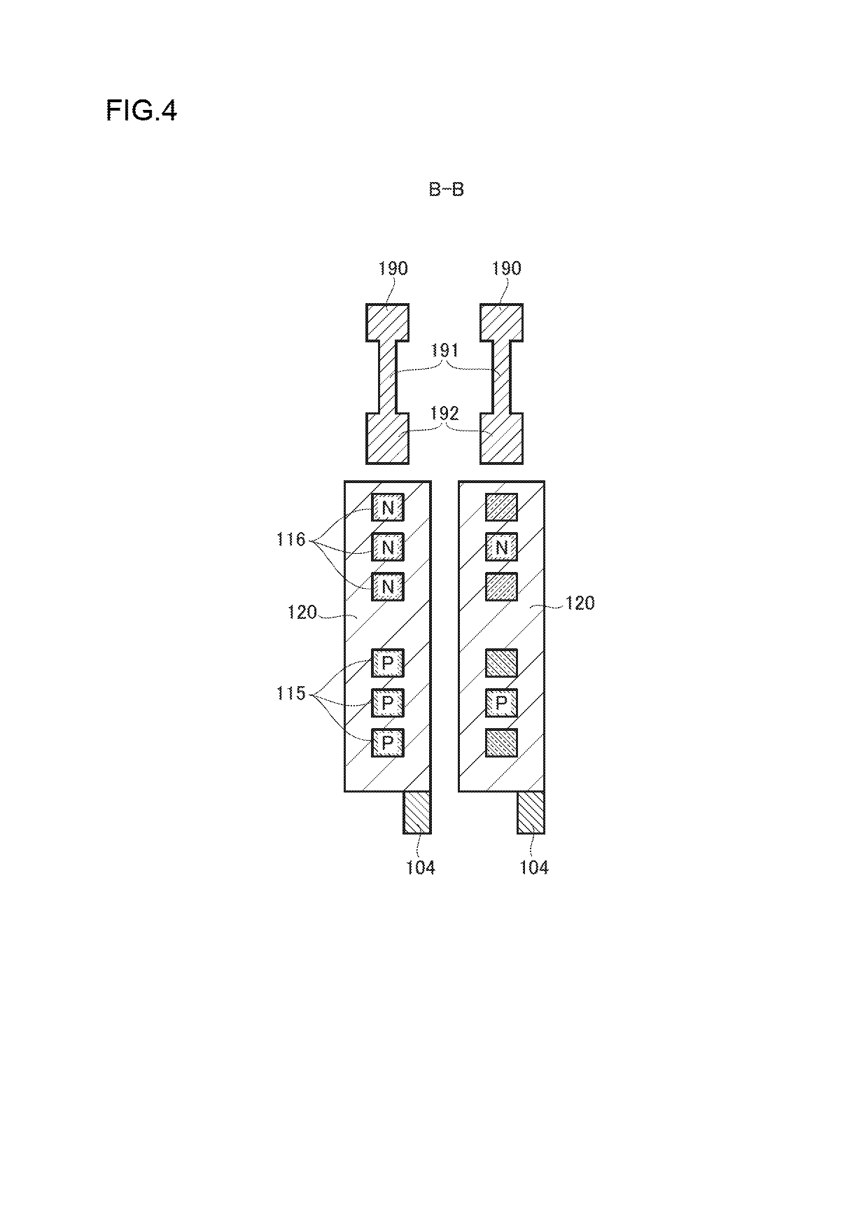

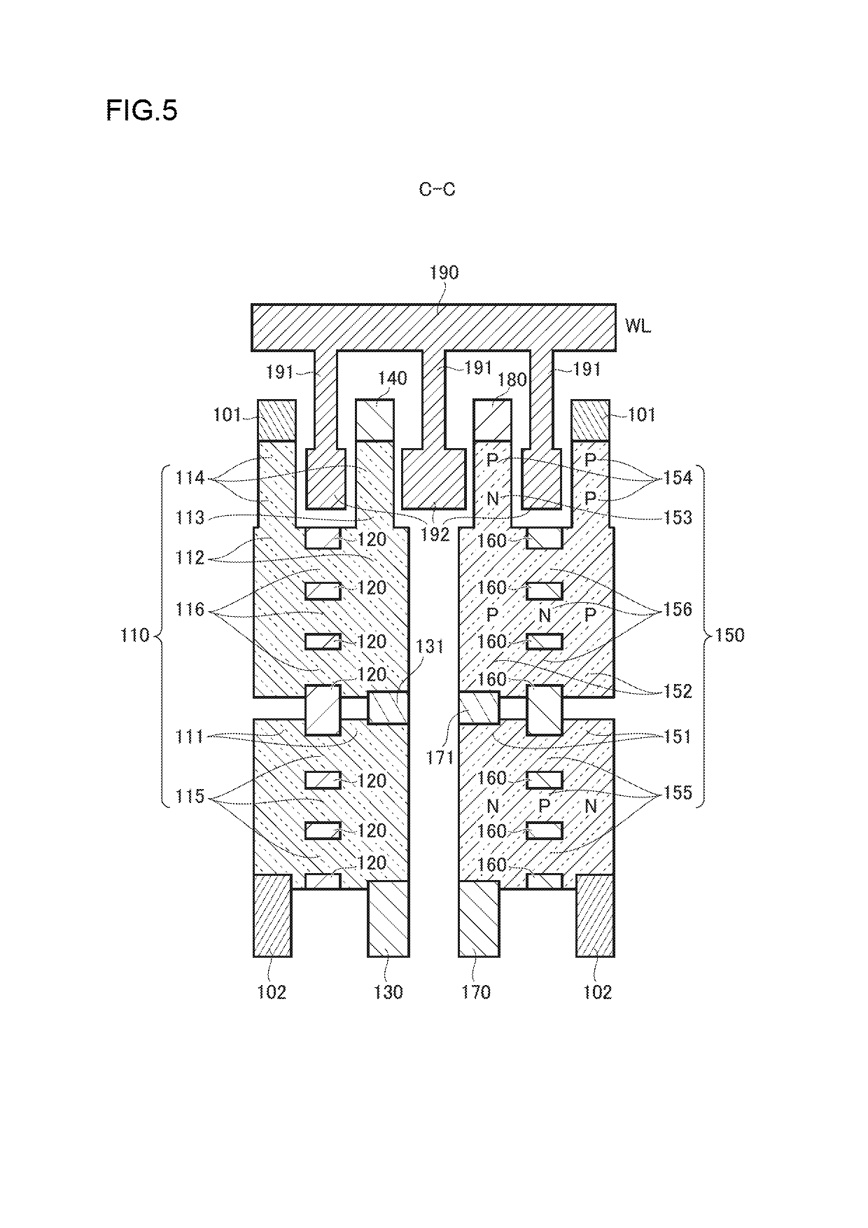

FIG. 1 is an equivalent circuit diagram of a semiconductor memory element. FIG. 2 is a plan layout view (top view) of the semiconductor memory element. FIG. 3 is a cross-sectional view taken along line A-A of the semiconductor memory element illustrated in FIG. 2. FIG. 4 is a cross-sectional view taken along line B-B of the semiconductor memory element illustrated in FIG. 2. FIG. 5 is a cross-sectional view taken along line C-C of the semiconductor memory element illustrated in FIG. 2. Note that, in FIGS. 3, 4, and 5, an upper surface side of the semiconductor memory element illustrated in FIG. 2 is illustrated on a lower side of the drawing.

FIG. 1 illustrates a circuit diagram of a static random access memory (SRAM) cell including six transistors (6Tr) as an example of a semiconductor memory element. An SRAM cell 100 includes four transistors M1, M2, M3, and M4 forming two cross-coupled inverters. The SRAM cell 100 includes a first inverter formed by a pull-up p-type metal oxide semiconductor (PMOS) transistor M3 (PU1) and a pull-down n-type metal oxide semiconductor (NMOS) transistor M1 (PD1). In addition, the SRAM cell 100 also includes a second inverter formed by a pull-up PMOS transistor M4 (PU2) and a pull-down NMOS transistor M2 (PD2). In the SRAM cell 100, both the first inverter and the second inverter are coupled between a power supply voltage Vdd and a ground potential.

Furthermore, the SRAM cell 100 includes a first pass gate (PG) transistor (Tr) M5 (PG1) connected between a bit line BL1 and an output of the first inverter. The SRAM cell 100 further includes a second pass gate (PG) transistor (Tr) M6 (PG2) connected between a second bit line BL2 and an output of the second inverter. Gates of the first pass gate transistor M5 and the second pass gate transistor M6 are connected to a word line (WL) connecting the SRAM cell 100 in a row of an SRAM array. The two pass gate transistors M5 and M6 control an input to and an output from the SRAM cell 100.

As illustrated in FIG. 1, the first inverter and the second inverter are cross-connected. That is, the first inverter has an input connected to an output of the second inverter. Similarly, the second inverter has an input connected to an output of the first inverter.

In an SRAM array (not illustrated) using a 6TrSRAM cell, one cell is disposed in a row direction and a column direction as a plan view. The column of the SRAM array is formed by a pair of bit lines consisting of the first bit line BL1 and the second bit line BL2. One cell of the SRAM array is disposed between each pair of the bit lines. Therefore, as illustrated in FIG. 1, the SRAM cell 100 is disposed between the first bit line BL1 and the second bit line BL2.

Next, FIG. 2 illustrates a plan layout view of the SRAM cell 100. The plan layout view illustrated in FIG. 2 illustrates a state in which two SRAM cells 100 are arranged laterally. In FIG. 2, each of regions indicated by alternate long and short dash lines corresponds to one SRAM cell 100.

The two SRAM cells 100 have a common power supply voltage (VDD) 101 and a common ground (GND) 102.

As illustrated in FIG. 2, the one SRAM cell 100 has a word line (WL) 190 on the VDD 101. There are a first bit line (BL1) 140 and a second bit line (BL2) 180 on the word line 190. There is a semiconductor layer 110, 150 on the first bit line 140 and the second bit line 180. The semiconductor layer 110, 150 is a diffusion layer for

forming the six transistors M1 (first transistor), M2 (second transistor), M3 (third transistor), M4 (fourth transistor), M5 (fifth transistor), and M6 (sixth transistor). In the semiconductor layer 110, 150, a channel, a source/drain, and the like of each of the transistors M1, M2, M3, M4, M5, and M6 are formed. A gate electrode 120, 160 of the transistor M1, M2, M3, M4 is formed on the semiconductor layer 110, 150. The gate electrode 120 (first gate electrode) forms the transistor M1, M3, and the gate electrode 160 (second gate electrode) forms the transistor M2, M4. In addition, there is a FET junction contact 130, 170 of the transistor M1, M2, M3, M4, M5, M6 on the semiconductor layer 110, 150. That is, the transistor M1 (PD1) and the transistor M3 (PU1) are formed by the gate electrode 120 and the semiconductor layer 110. The transistor M2 (PD2) and the transistor M4 (PU2) are formed by the gate electrode 160 and the semiconductor layer 150. The transistor M5 (PG1) is formed by the semiconductor layer 110 and a gate electrode (FIG. 3) connected to the word line 190. The transistor M6 (PG2) is formed by the semiconductor layer 150 and a gate electrode (FIG. 3) connected to the word line 190. The first inverter is formed by the transistor M1 (PD1), the transistor M3 (PU1), and the transistor M5 (PG1). The second inverter is formed by the transistor M2 (PD2), the

transistor M4 (PU2), and the transistor M5 (PG2).

There is a wiring line 103, 104 for connecting the first inverter and the second inverter on the gate electrode 120, 160 and the FET junction contact 130, 170.

As illustrated in FIG. 3, in the cross-sectional view taken along line A-A in FIG. 2, the first bit line 140 is disposed on the word line 190. The semiconductor layer 110 is formed on the first bit line 140. The semiconductor layer 110 is formed in contact with the first bit line 140. The semiconductor layer 110 includes a P-type semiconductor layer 114 (fourth semiconductor layer) and an N-type semiconductor layer 113 (third semiconductor layer) from the first bit line 140 side. Furthermore, the semiconductor layer 110 includes a P-type semiconductor layer 112 (eighth semiconductor layer) and an N-type semiconductor layer 111 (ninth semiconductor layer) on the N-type semiconductor layer 113. In addition, the semiconductor layer 110 includes a PN junction contact 131 between the P-type semiconductor layer 112 and the N-type semiconductor layer 111.

Each of the P-type semiconductor layer 114 and the N-type semiconductor layer 113 is formed in a region narrower than each of the P-type semiconductor layer 112 and the N-type semiconductor layer 111. The PN junction contact 131 is formed between the P-type semiconductor layer 112 and the N-type semiconductor layer 111.

The P-type semiconductor layer 114, the N-type semiconductor layer 113, and the P-type semiconductor layer 112 are a channel region constituting the transistor M5 to be PG1 and source/drain regions. The P-type semiconductor layer 114 and the P-type semiconductor layer 112 are source/drain regions, and the N-type semiconductor layer 113 is a channel region. Therefore, the transistor M5 is a P-channel MOS.

The P-type semiconductor layer 112 is a source/drain region of the transistor M1 to be PD1. The N-type semiconductor layer 111 is a source/drain region of the transistor M3 to be PU1.

The FET junction contact 130 is disposed between the N-type semiconductor layer 111 which is a source/drain region of the transistor M3 and the wiring line 103. The wiring line 104 is disposed adjacent to the wiring line 103. The N-type semiconductor layer 111, which is a source/drain region of the transistor M3 to be PU1, is connected to the transistor M2 to be PD2 and the gate electrode 160 of the transistor M4 to be PU2 by the wiring line 103 via the FET junction contact 130. Therefore, the transistor M5 to be PG1 is connected to the gate electrodes 160 of the transistor M2, M4 by the wiring line 103 via the PN junction contact 131 and the N-type semiconductor layer 111.

As illustrated in FIG. 4, in the cross-sectional view taken along line B-B in FIG. 2, there are three N-type semiconductor layers 116 (first semiconductor layers), three P-type semiconductor layers 115 (second semiconductor layers), and the gate electrode 120 formed around and between these semiconductor layers. The three N-type semiconductor layers 116 are channel regions of the transistor M1 to be PD1. The three P-type semiconductor layers 115 are channel regions of the transistor M3 to be PU1.

The three N-type semiconductor layers 116 and the three P-type semiconductor layers 115 to be channel regions are constituted by nanosheet layers. The entire periphery of a cross section of the three N-type semiconductor layers 116 and the three P-type semiconductor layers 115 to be channel regions constituted by nanosheet layers in a gate width direction is surrounded by the gate electrode 120 via a gate insulating film (not illustrated). Note that, in the semiconductor device, the nanosheet also includes a nanowire.

That is, each of the transistor M1 (first nanosheet semiconductor element) to be PD1 and the transistor M3 (second nanosheet semiconductor element) to be PU1 is a gate all around (GAA)-FET having a nanosheet structure. Each of the transistor M2 (third nanosheet semiconductor element) to be PD2 and the transistor M4 (fourth nanosheet semiconductor element) to be PU2 is also a gate all around (GAA)-FET having a similar structure to the transistor M1, M3 illustrated in FIG. 4.

The word line 190, a word contact 191, and a gate electrode 192 are formed below the gate electrode 120.

The wiring line 104 is connected above the gate electrode 120. The wiring line 104 is connected to the transistor M3 to be PD1, the gate electrode 120 of the transistor M1 to be PU1, and the FET junction contact 170. Similarly to the FET junction contact 130 illustrated in FIG. 3, the FET junction contact 170 is connected to an N-type semiconductor layer 151 (FIG. 5), which is a source/drain region of the transistor M4 to be PU2, and the wiring line 104. Therefore, the gate electrode 120 of the transistor M3, M1 is connected to the transistor M6 to be PG2 via the wiring line 104, the FET junction contact 170, the N-type semiconductor layer 151, and a PN junction contact 171 (FIG. 5).

As illustrated in FIG. 5, in the cross-sectional view taken along line C-C in FIG. 2, the gate electrode 192 is connected to the word line 190 via the word contact 191. The semiconductor layer 110, 150 is formed on a side surface of the gate electrode 192 via a gate insulating film (not illustrated) or the like.

The semiconductor layer 110, 150 has a shape in which a lower central portion is dug in the cross section taken along line C-C. The gate electrode 192 is disposed in the dug recess. The first bit line 140 and the VDD 101 are formed under the semiconductor layer 110. The second bit line 180 and the VDD 101 are formed under the semiconductor layer 150. The gate electrode 192 is formed below the first bit line 140, the second bit line 180, and the VDD 101.

The semiconductor layer 110 includes the P-type semiconductor layer 114 and the N-type semiconductor layer 113 above the first bit line 140 on a side surface of the recess. The semiconductor layer 110 includes the P-type semiconductor layer 114 above the VDD 101 on a side surface of the recess.

In the semiconductor layer 110, the gate electrode 120 and the N-type semiconductor layer 116 are stacked above a bottom surface of the recess. In the semiconductor layer 110, the P-type semiconductor layer 115 and the gate electrode 120 are further stacked via the gate electrode 120 and the PN junction contact 131 disposed above the lowermost N-type semiconductor layer 116. In FIG. 5, three N-type semiconductor layers 116 and three P-type semiconductor layers 115 are formed. Between the N-type semiconductor layers 116 and between the P-type semiconductor layers 115, the gate electrode 120 is formed between the layers of the channel regions, and the PN junction contact 131 is formed in one of portions between the layers of the source/drain regions. An uppermost surface and a lowermost surface of the stack of the N-type semiconductor layer 116, the N-type semiconductor layer 115, and the gate electrode 120 are formed by the gate electrodes 120.

Furthermore, the semiconductor layer 110 includes the P-type semiconductor layer 112 on a side surface of the stack of the N-type semiconductor layer 116 and the gate electrode 120 and above the N-type semiconductor layer 113 and the P-type semiconductor layer 114. The semiconductor layer 110 includes the N-type semiconductor layer 111 on a side surface of the stack of the P-type semiconductor layer 115 and the gate electrode 120. The N-type semiconductor layer 111 and the P-type semiconductor layer 112 are connected via an insulating layer (not illustrated) or the PN junction contact 131.

In the semiconductor layer 110, the transistor M5 to be PG1 is formed by the P-type semiconductor layer 114, the N-type semiconductor layer 113, and the P-type semiconductor layer 112 above the first bit line 140, and the gate electrode 192. As illustrated in FIG. 5, the transistor M5 (first vertical semiconductor element) to be PG1 is a vertical metal-oxide-semiconductor field-effect transistor (MOSFET).

In the semiconductor layer 110, the transistor M1 to be PD1 is formed by the gate electrode 120, the three N-type semiconductor layers 116, and the P-type semiconductor layer 112. The three N-type semiconductor layers 116 are channel regions, and the P-type semiconductor layer 112 formed on both side surfaces of the three N-type semiconductor layers 116 is a source/drain region.

Furthermore, in the semiconductor layer 110, the transistor M3 to be PU1 is formed by the gate electrode 120, the three P-type semiconductor layers 115, and the N-type semiconductor layer 111. The three P-type semiconductor layers 115 are channel regions, and the N-type semiconductor layer 111 formed on both side surfaces of the three P-type semiconductor layers 115 is a source/drain region.

The P-type semiconductor layer 112 which is a source/drain region of the transistor M1 to be PD1 and the N-type semiconductor layer 111 which is a source/drain region of the transistor M3 to be PU1 are connected by the PN junction contact 131.

The FET junction contact 130 for connecting the transistor M3 and the wiring line 103 (FIGS. 2 and 3) is disposed above one of the N-type semiconductor layers 111 which are source/drain regions of the transistor M3 to be PU1. A ground (GND) 102 is connected above the other of the N-type semiconductor layers 111 which are source/drain regions of the transistor M3 to be PU1.

The semiconductor layer 150 includes a P-type semiconductor layer 154 (twelfth semiconductor layer) and an N-type semiconductor layer 153 (seventh semiconductor layer) above the second bit line 180 on a side surface of the recess. The semiconductor layer 150 includes the P-type semiconductor layer 154 above the VDD 101 on a side surface of the recess.

In the semiconductor layer 150, the gate electrode 160 and an N-type semiconductor layer 156 (fifth semiconductor layer) are stacked above a bottom surface of the recess. In the semiconductor layer 150, a P-type semiconductor layer 155 (sixth semiconductor layer) and the gate electrode 160 are further stacked via the gate electrode 160 disposed above the lowermost N-type semiconductor layer 156. In FIG. 5, three N-type semiconductor layers 156 and three P-type semiconductor layers 155 are formed. Between the N-type semiconductor layers 156 and between the P-type semiconductor layers 155, the gate electrode 160 is formed between the layers of the channel regions, and the PN junction contact 171 is formed in one of portions between the layers of the source/drain regions. An uppermost surface and a lowermost surface of the stack of the N-type semiconductor layer 156, the P-type semiconductor layer 155, and the gate electrode 160 are formed by the gate electrodes 160.

Furthermore, the semiconductor layer 150 includes a P-type semiconductor layer 152 (tenth semiconductor layer) on a side surface of the stack of the N-type semiconductor layer 156 and the gate electrode 160 and above the N-type semiconductor layer 153 and the P-type semiconductor layer 154. The semiconductor layer 150 includes an N-type semiconductor layer 151 (eleventh semiconductor layer) on a side surface of the stack of the P-type semiconductor layer 155 and the gate electrode 160. The N-type semiconductor layer 151 is formed above the P-type semiconductor layer 152 via an insulating layer (not illustrated) or the PN junction contact 171.

In the semiconductor layer 150, the transistor M6 to be PG2 is formed by the P-type semiconductor layer 154, the N-type semiconductor layer 153, and the P-type semiconductor layer 152 above the second bit line 180, and the gate electrode 192. As illustrated in FIG. 5, the transistor M6 (second vertical semiconductor element) to be PG2 is a vertical MOSFET.

In the semiconductor layer 150, the transistor M2 to be PD2 is formed by the gate electrode 160, the three N-type semiconductor layers 156, and the P-type semiconductor layer 152. The three N-type semiconductor layers 156 are channel regions, and the P-type semiconductor layer 152 formed on both side surfaces of the three N-type semiconductor layers 156 is a source/drain region.

Furthermore, in the semiconductor layer 150, the transistor M4 to be PU2 is formed by the gate electrode 160, the three P-type semiconductor layers 155, and the N-type semiconductor layer 151. The three P-type semiconductor layers 155 are channel regions, and the N-type semiconductor layer 151 formed on both side surfaces of the three P-type semiconductor layers 155 is a source/drain region.

The P-type semiconductor layer 152 which is a source/drain region of the transistor M2 to be PD2 and the N-type semiconductor layer 151 which is a source/drain region of the transistor M4 to be PU2 are connected by the PN junction contact 171.

The contact 170 for connecting the transistor M4 and the wiring line 104 (FIGS. 2 and 4) is disposed above one of the N-type semiconductor layers 151 which are source/drain regions of the transistor M4 to be PU2. The ground 102 is connected above the other of the N-type semiconductor layers 151 which are source/drain regions of the transistor M4 to be PU2.

In the SRAM cell 100 illustrated in FIGS. 2 to 5, the transistor M1 (PD1) having a GAA-FET structure and the transistor M3 (PU1) similarly having a GAA-FET structure are stacked in the same direction as a stacking direction of the gate electrode 120. In addition, the transistor M2 (PD2) having a GAA-FET structure and the transistor M4 (PU2) similarly having a GAA-FET structure are stacked in the same direction as a stacking direction with the gate electrode 160. That is, the SRAM cell 100 illustrated in FIGS. 2 to 5 has a complementary field effect transistor (CFET) structure in which the transistor M1 (PD1) and the transistor M3 (PU1) having a GAA-FET structure are stacked in a vertical direction. Furthermore, the SRAM cell 100 has a CFET structure in which the transistor M2 (PD2) and the transistor M4 (PU2) having a GAA-FET structure are stacked in a vertical direction. That is, the SRAM cell 100 includes two CFETs consisting of a CFET constituting the PD1 and the PU1 and a CFET constituting the PD2 and the PU2.

The SRAM cell 100 illustrated in FIGS. 2 to 5 includes the transistor M5 (PG1) having a vertical MOS structure under the CFET in which the transistor M1 (PD1) and the transistor M3 (PU1) are stacked in a vertical direction. The transistor M5 is formed under the source/drain region (P-type semiconductor layer 112) of the transistor M1 which is PD1. Therefore, the SRAM cell 100 has a structure in which the first inverter including the transistor M5 (PG1), the transistor M1 (PD1), and the transistor M3 (PU1) is stacked in a vertical direction.

Furthermore, the SRAM cell 100 includes the transistor M6 (PG2) having a vertical MOS structure under the CFET in which the transistor M2 (PD2) and the transistor M4 (PU2) are stacked in a vertical direction. The transistor M6 is formed under the source/drain region (P-type semiconductor layer 152) of the transistor M2 which is PD2. Therefore, the SRAM cell 100 has a structure in which the second inverter including the transistor M6 (PG2), the transistor M2 (PD2), and the transistor M4 (PU2) is stacked in a vertical direction.

Therefore, the SRAM cell 100 includes two semiconductor layers consisting of the semiconductor layer 110 in which the three transistors M1, M3, and M5 are stacked in a vertical direction and the semiconductor layer 150 in which the three transistors M2, M4, and M5 are stacked in the vertical direction.

In the SRAM cell 100, the semiconductor layer 110, 150 is made of, for example, Si or Ge. The gate electrode 120, 160, the FET junction contact 130, 170, and the PN junction contact 131, 171 are made of, for example, tungsten nitride (WN), tantalum nitride (TaN), titanium nitride (TiN), or niobium. The word line (WL) 190, the word contact 191, the bit line (BL) 140, 180, the wiring line 103, 104, the power supply voltage (VDD) 101, and the ground (GND) 102 are made of copper (Cu) or the like.

2. Method for manufacturing semiconductor device of first embodiment

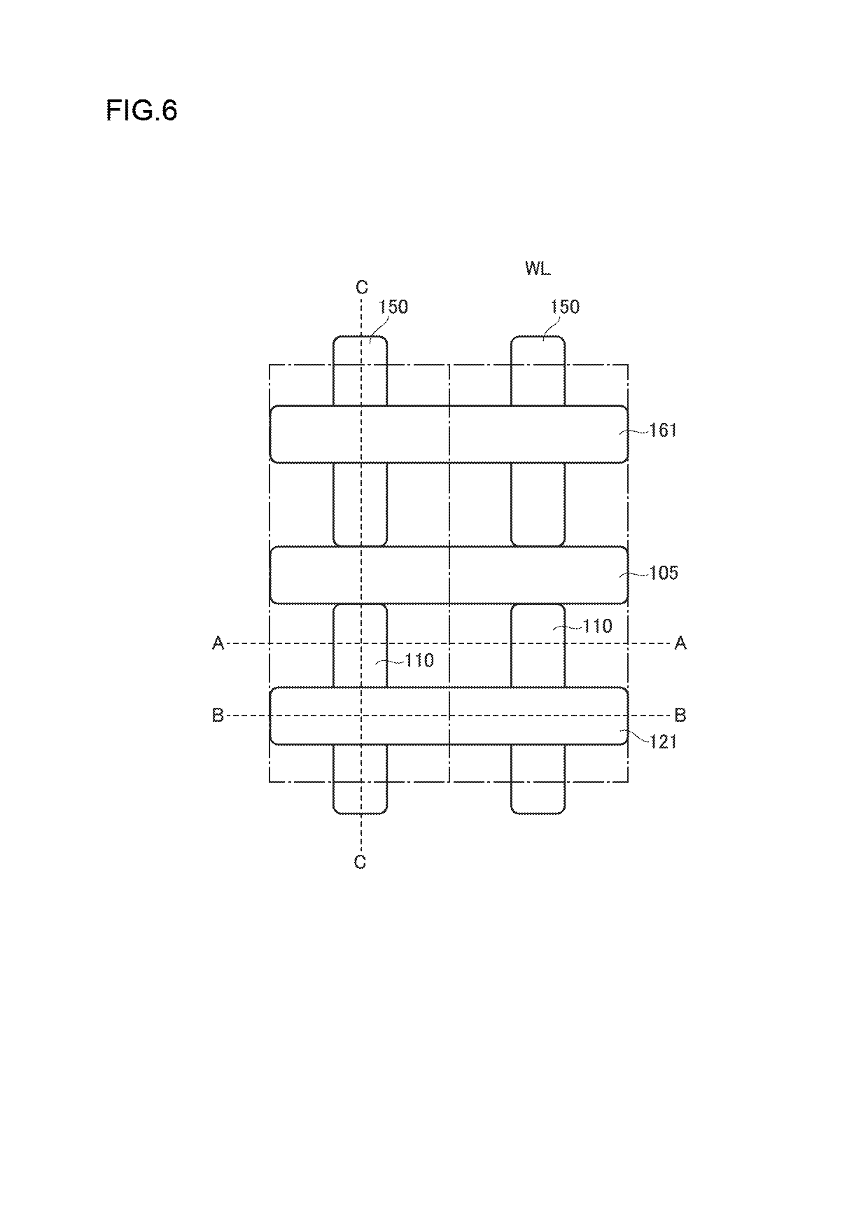

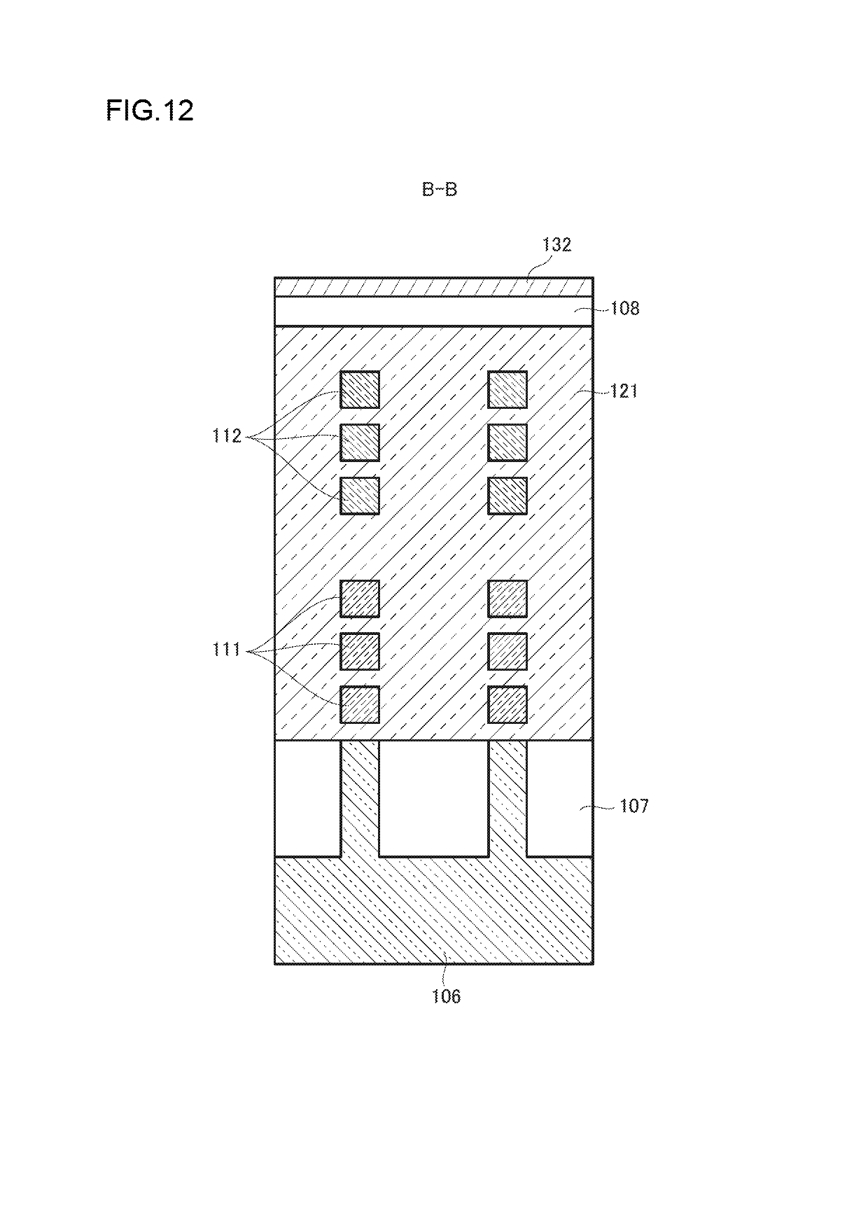

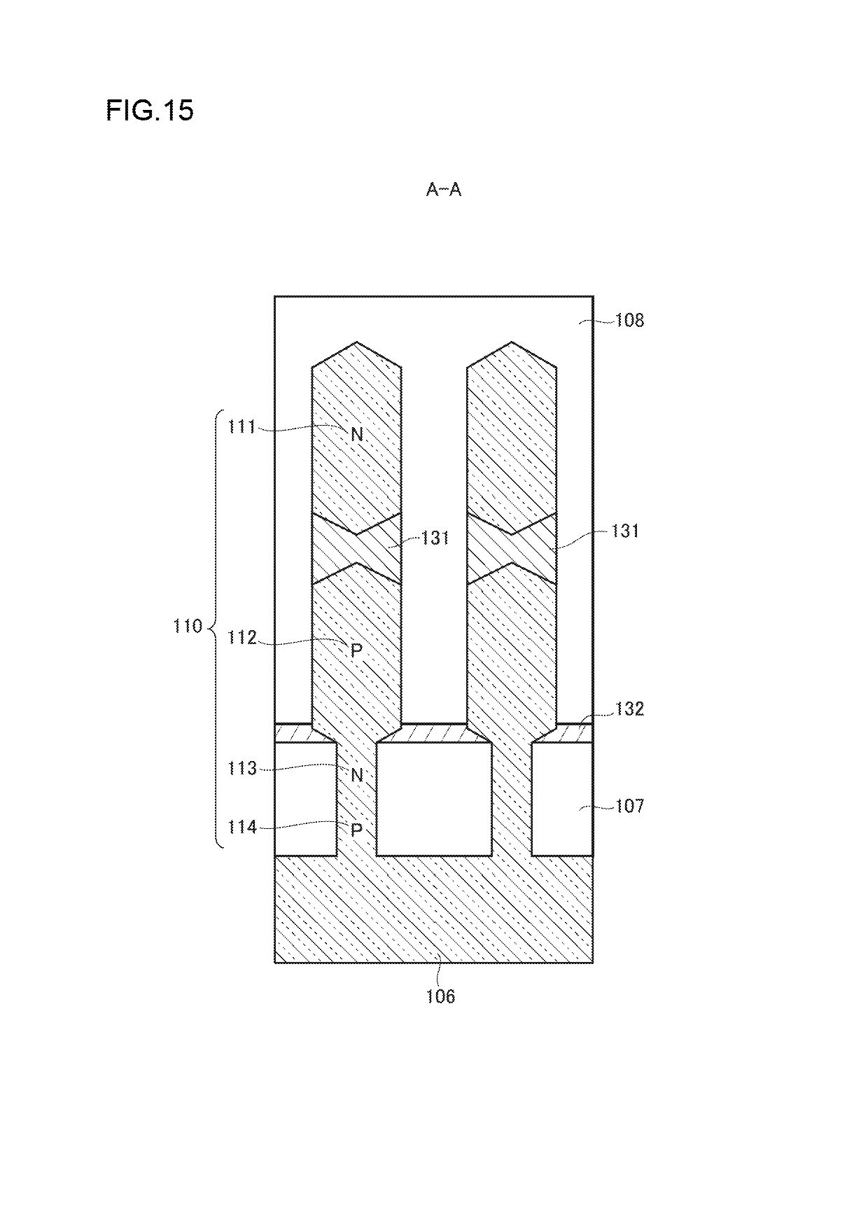

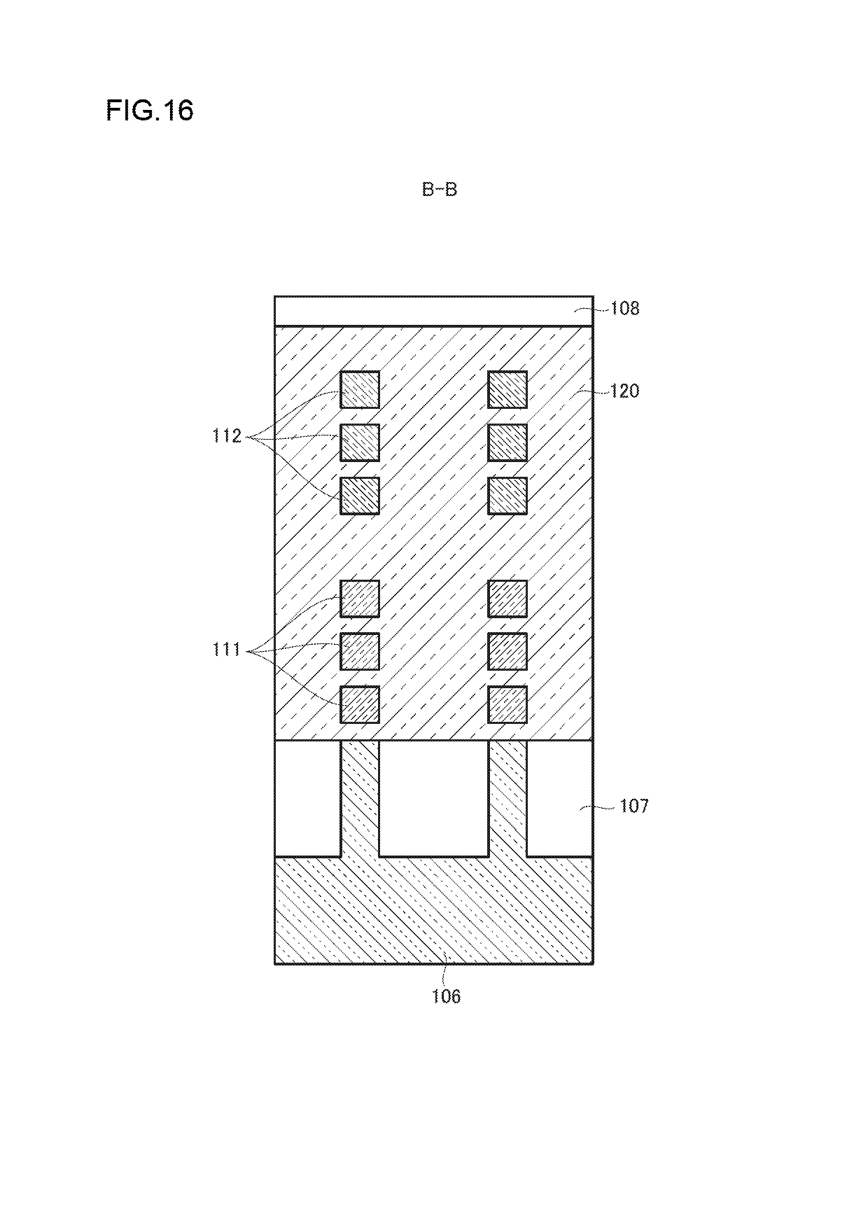

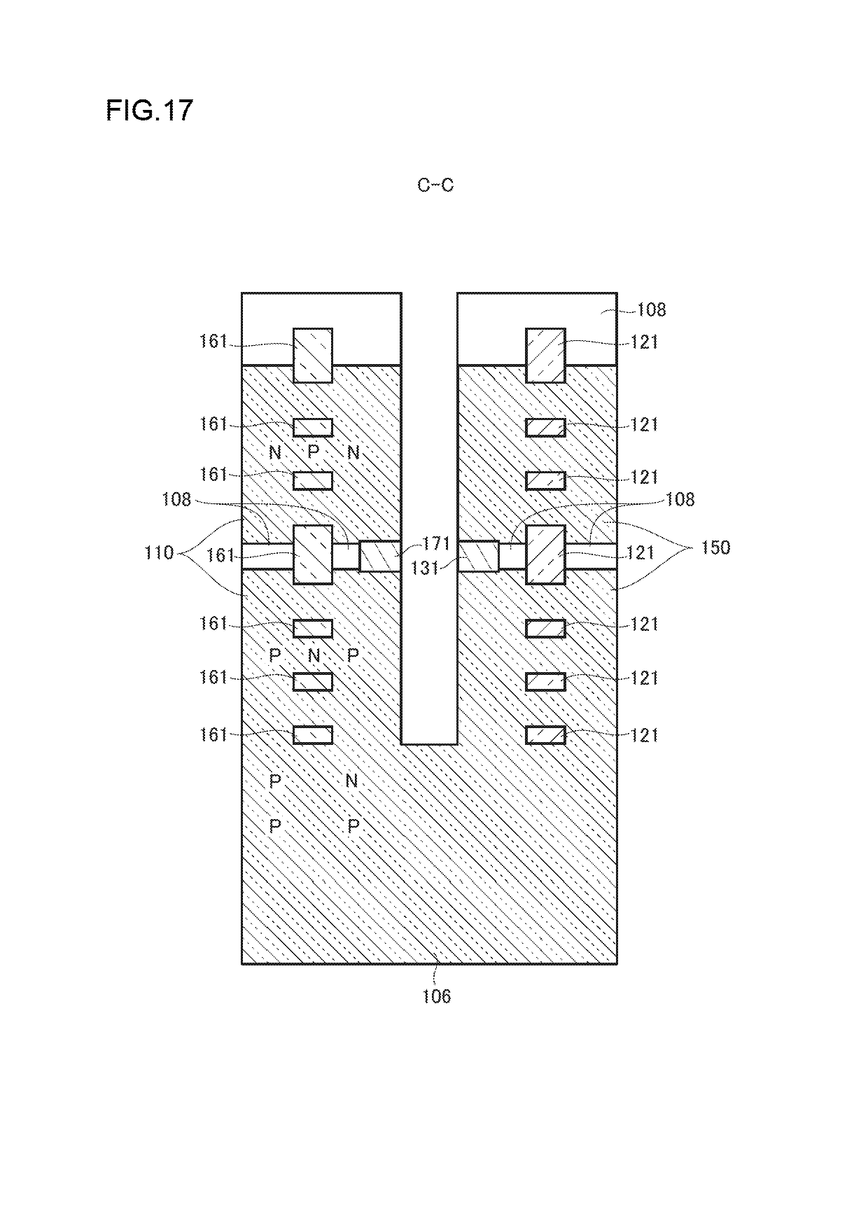

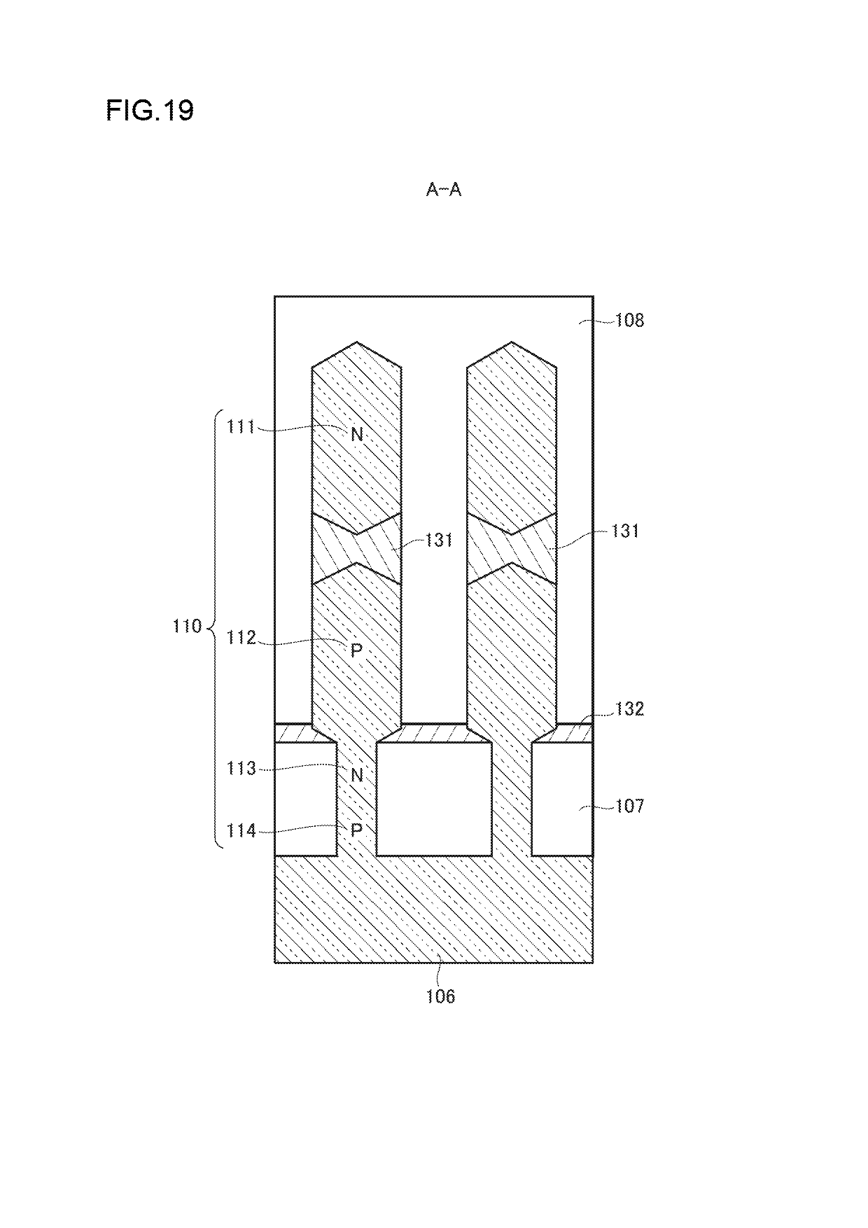

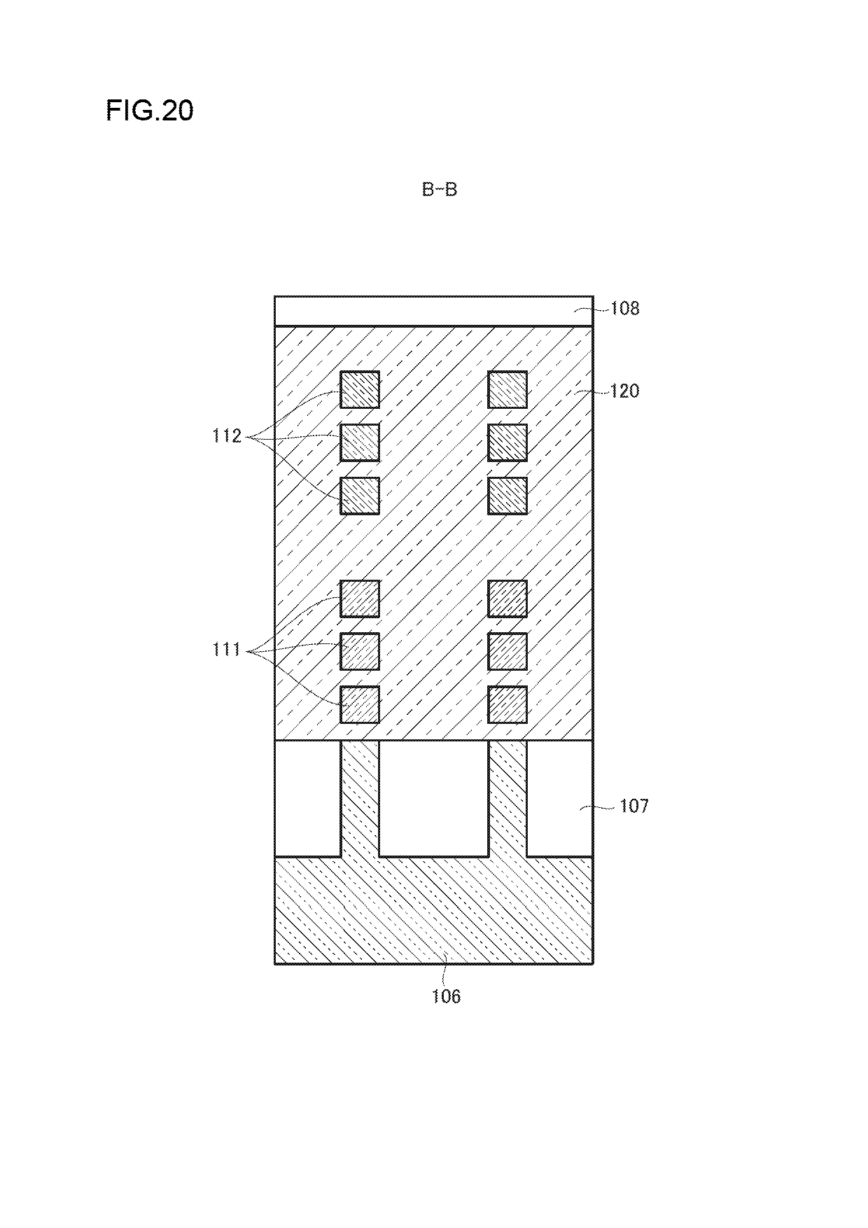

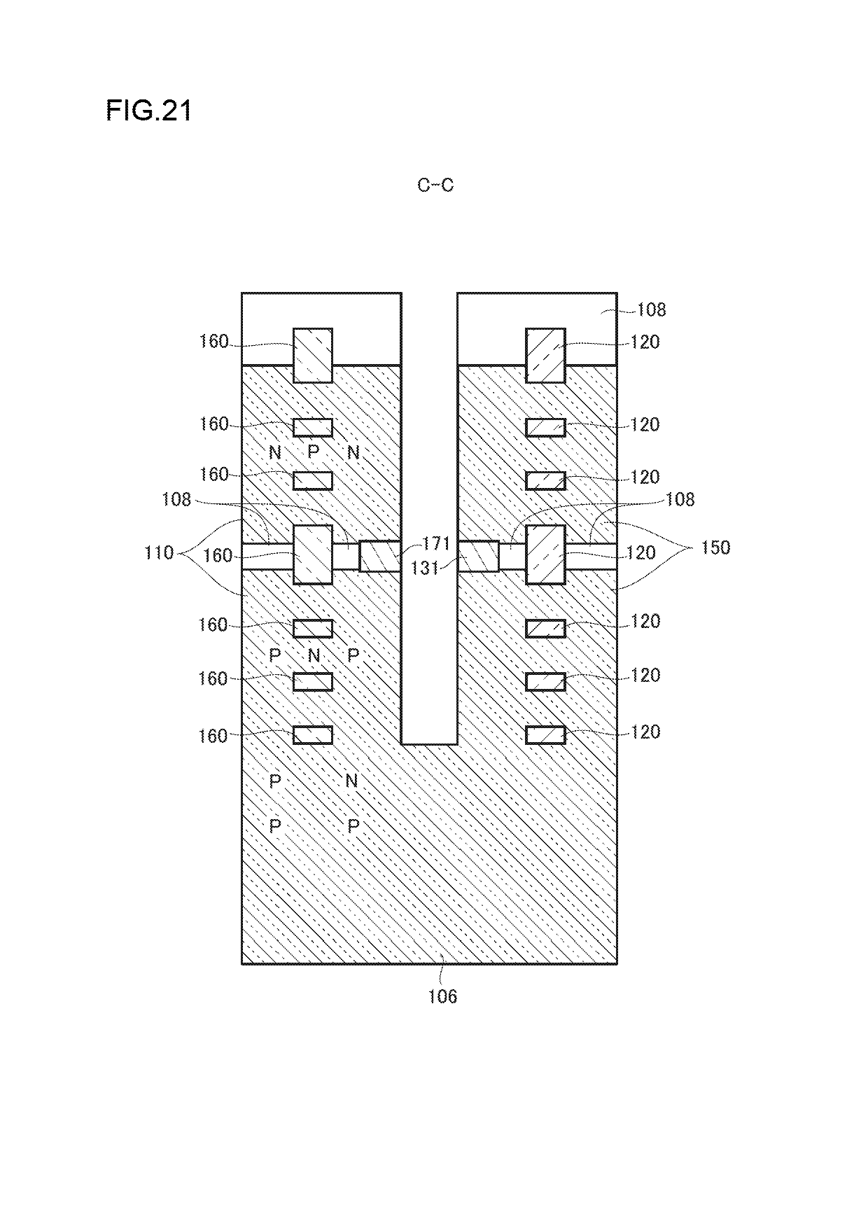

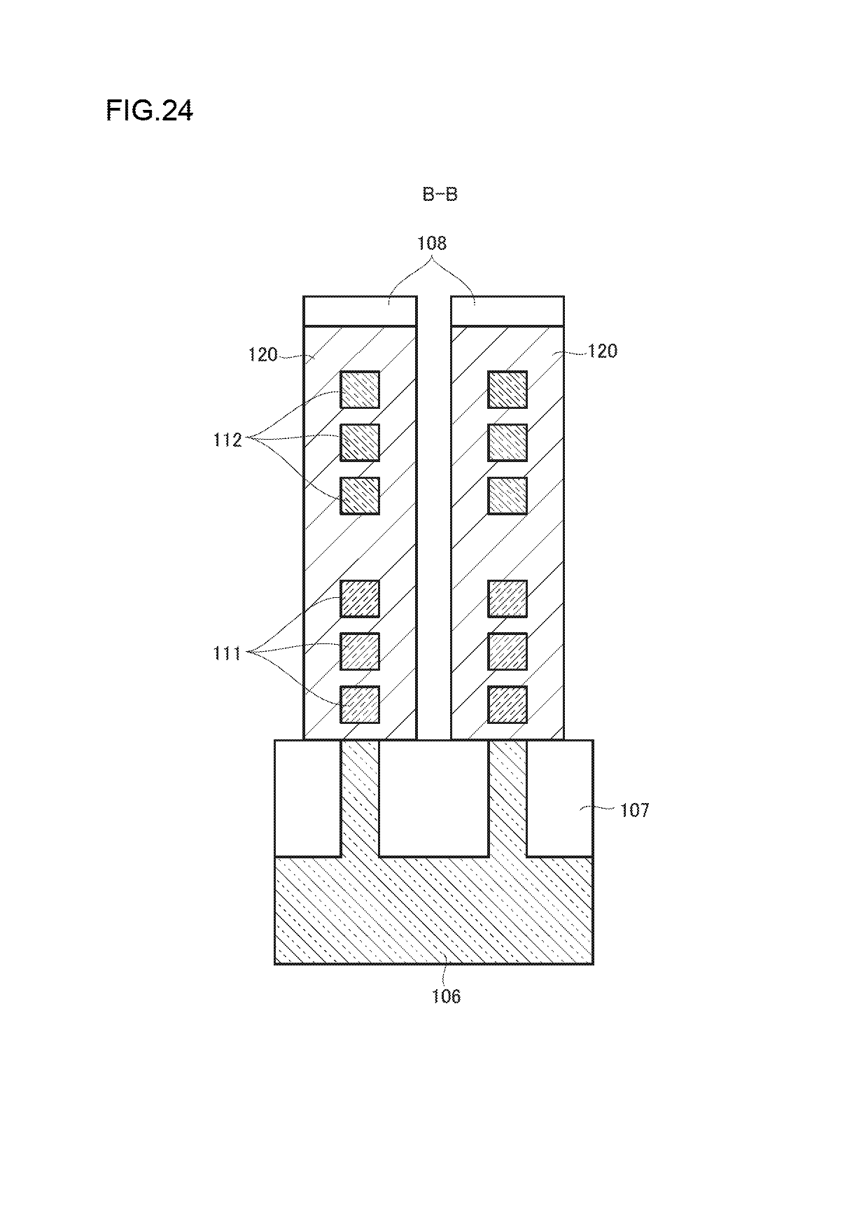

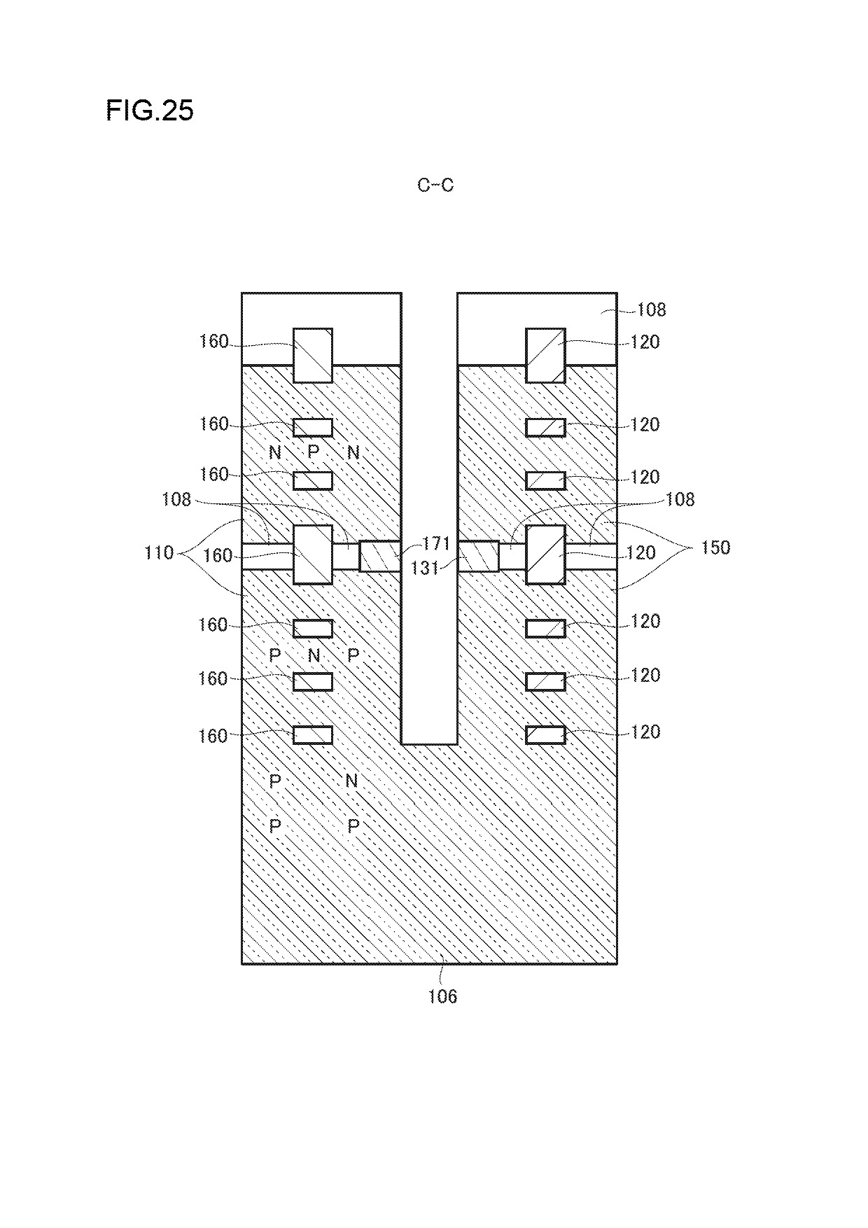

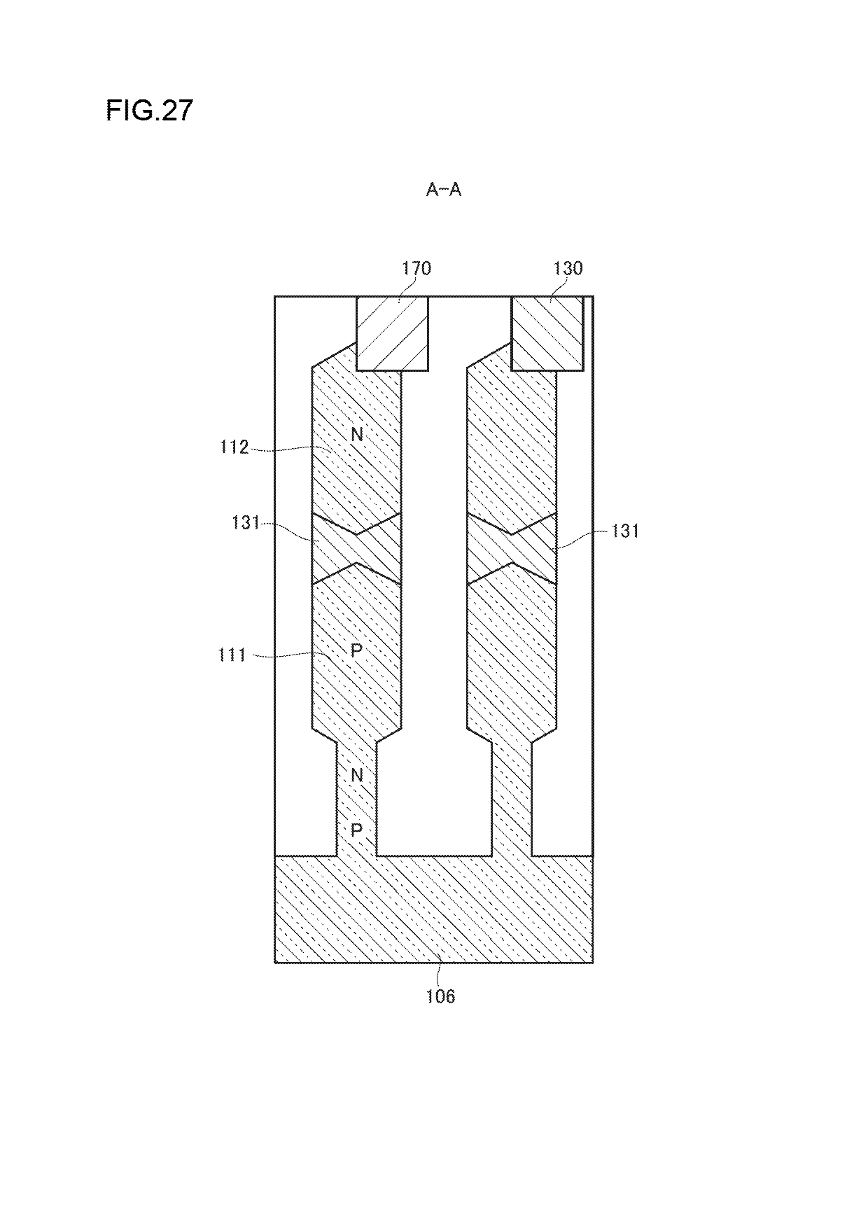

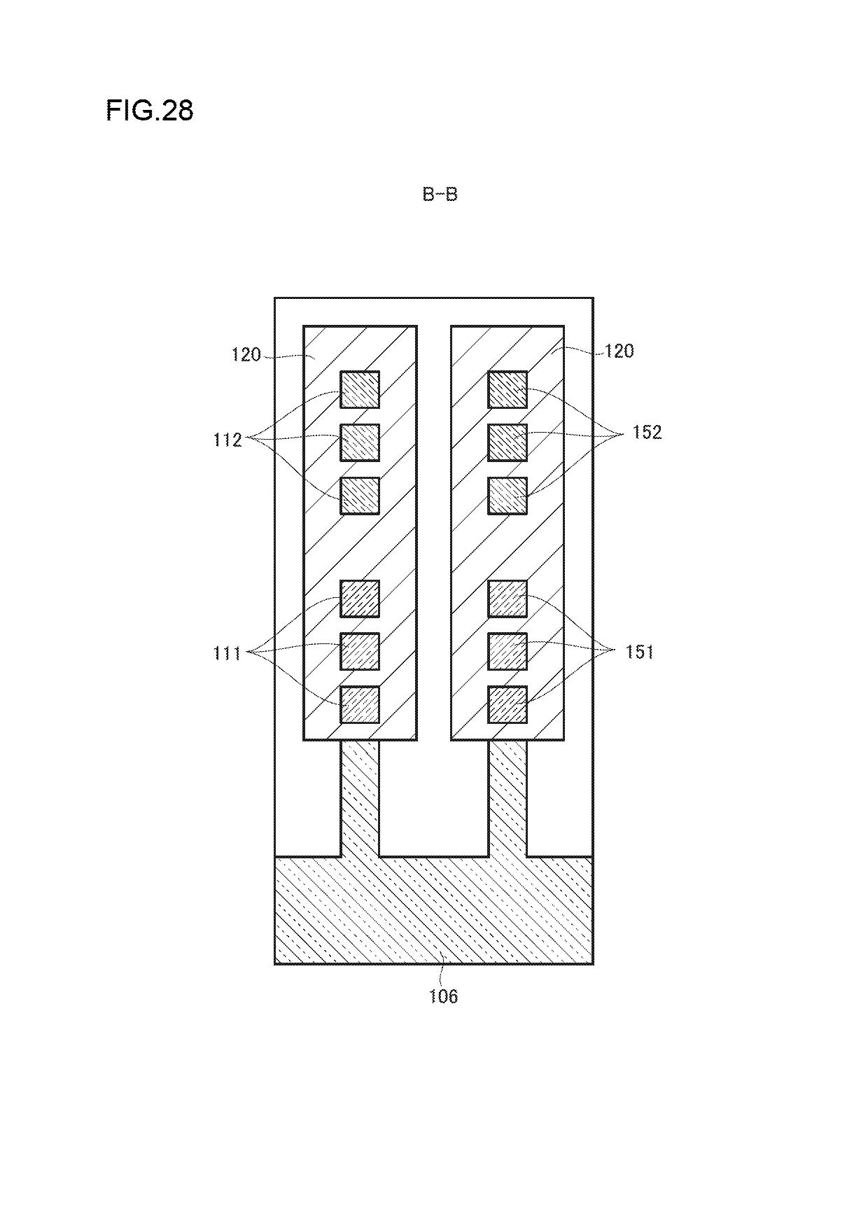

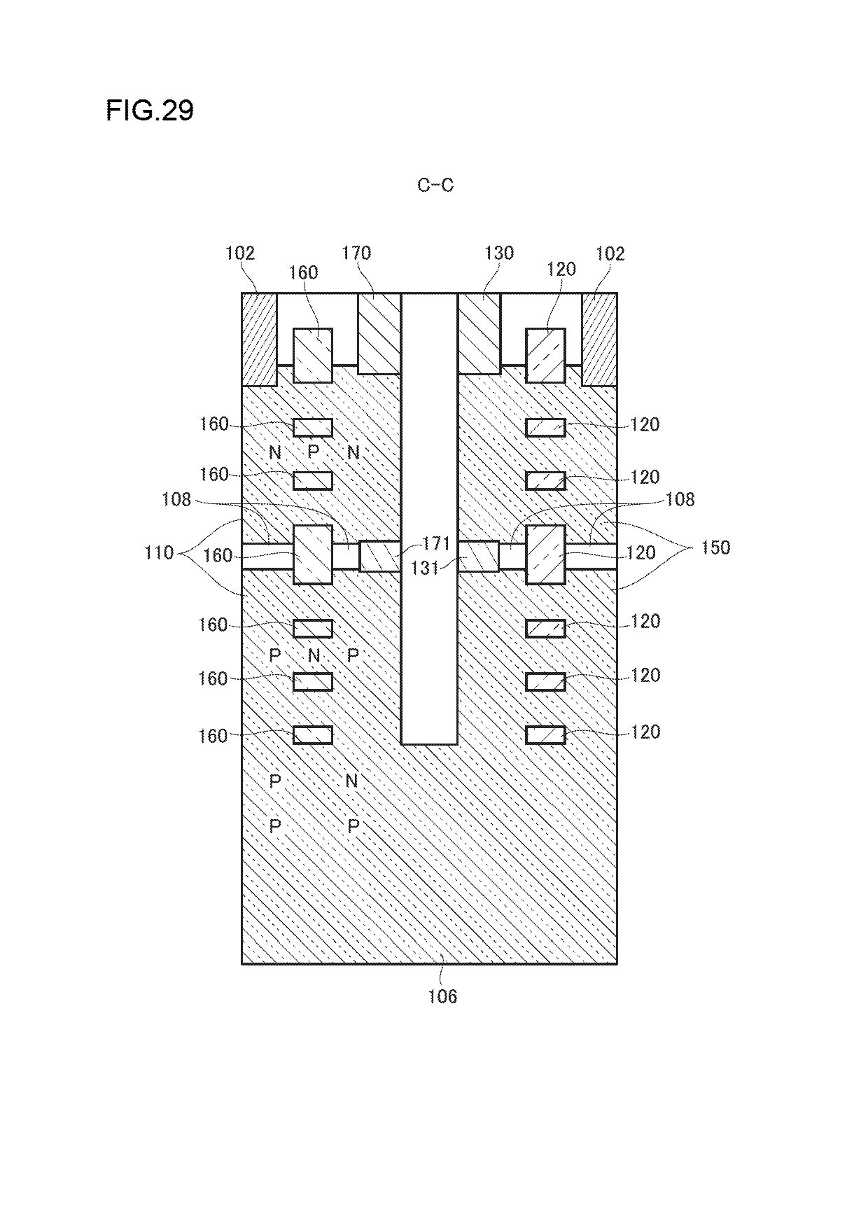

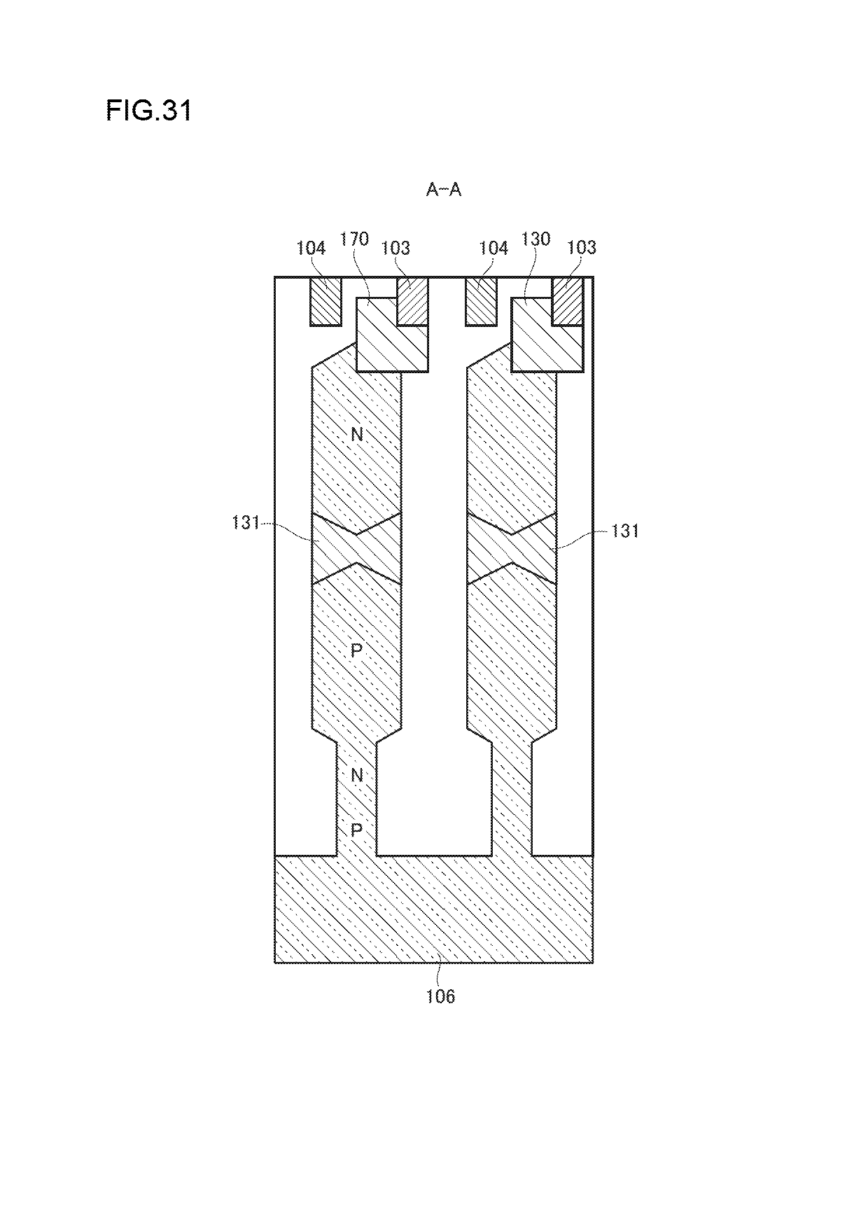

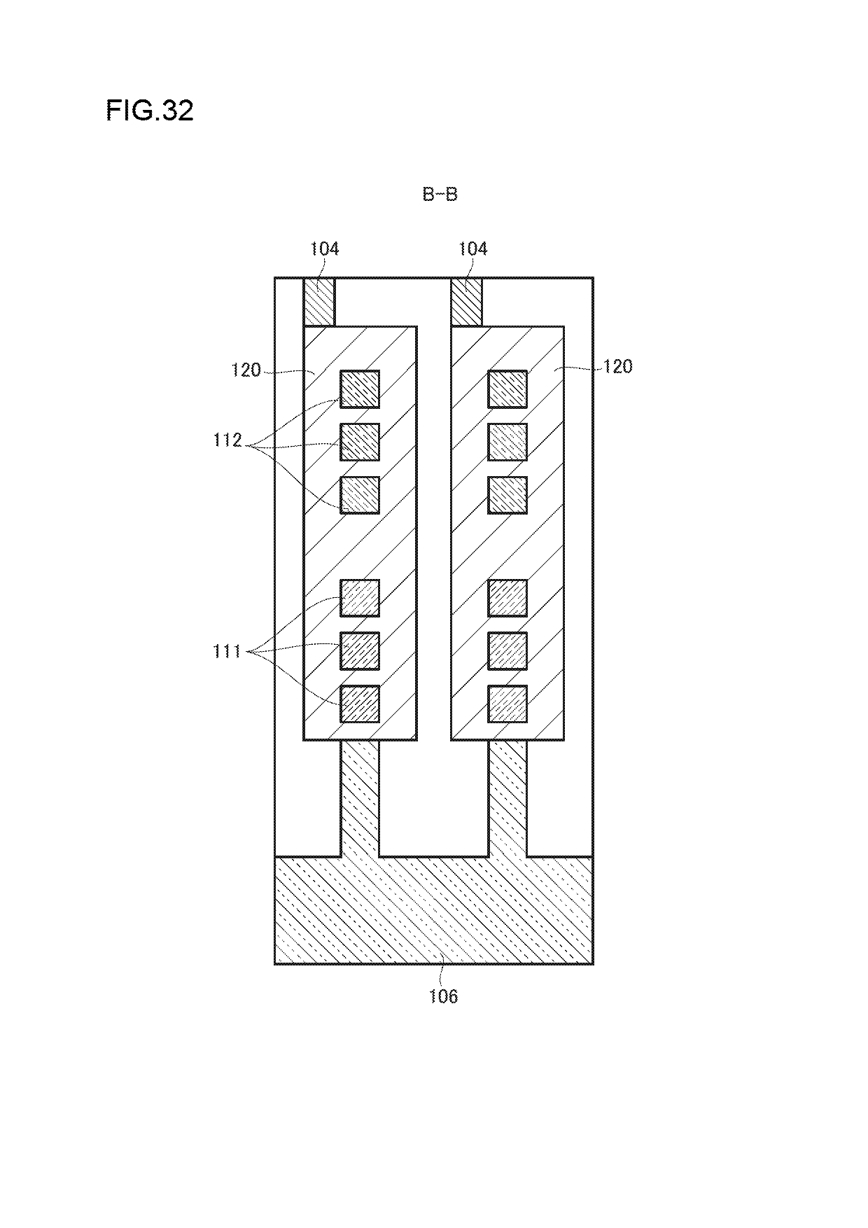

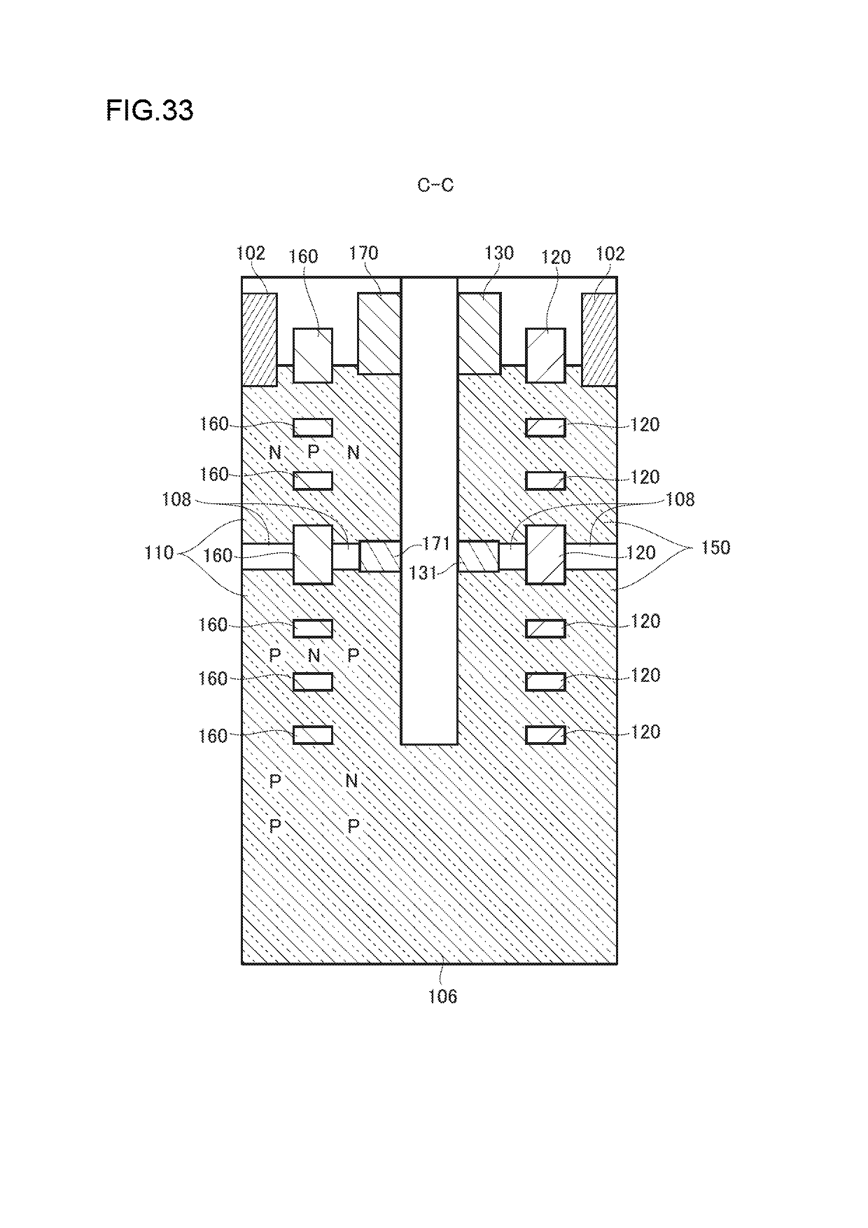

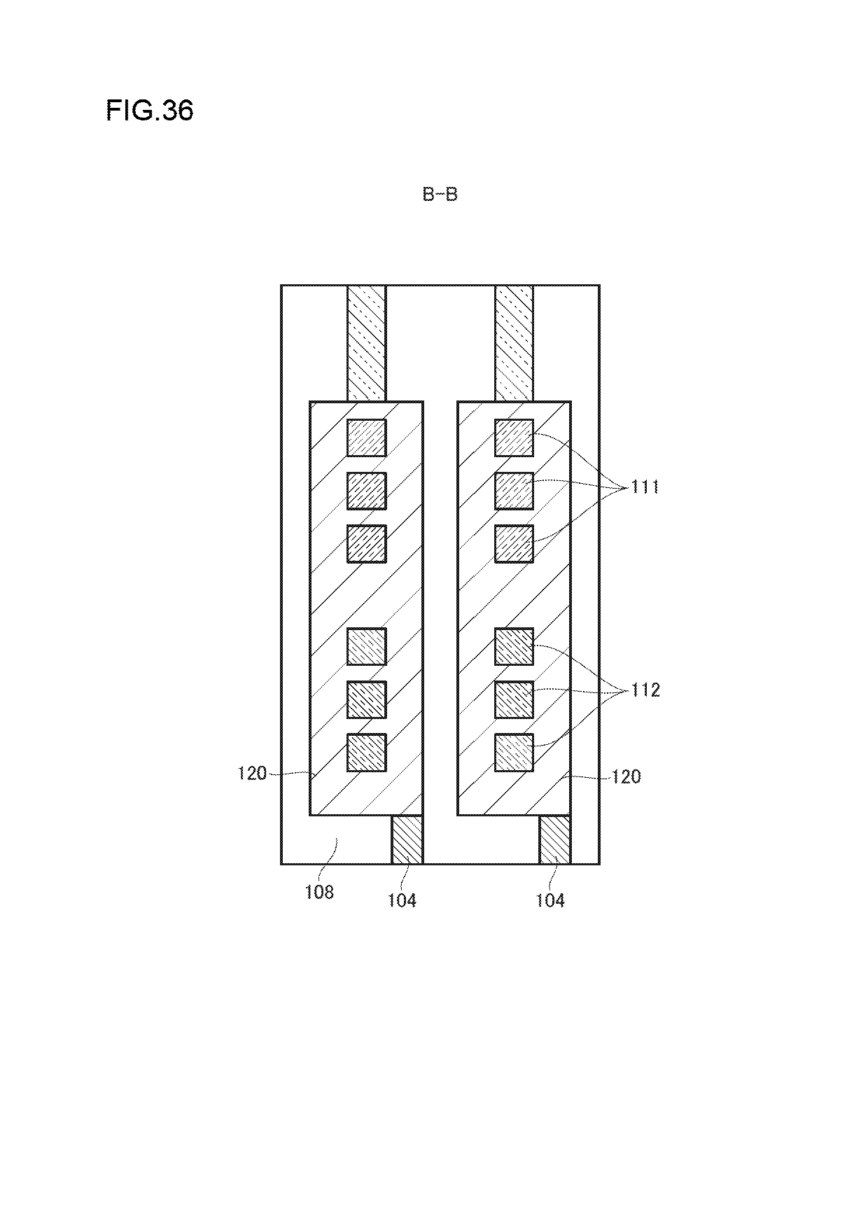

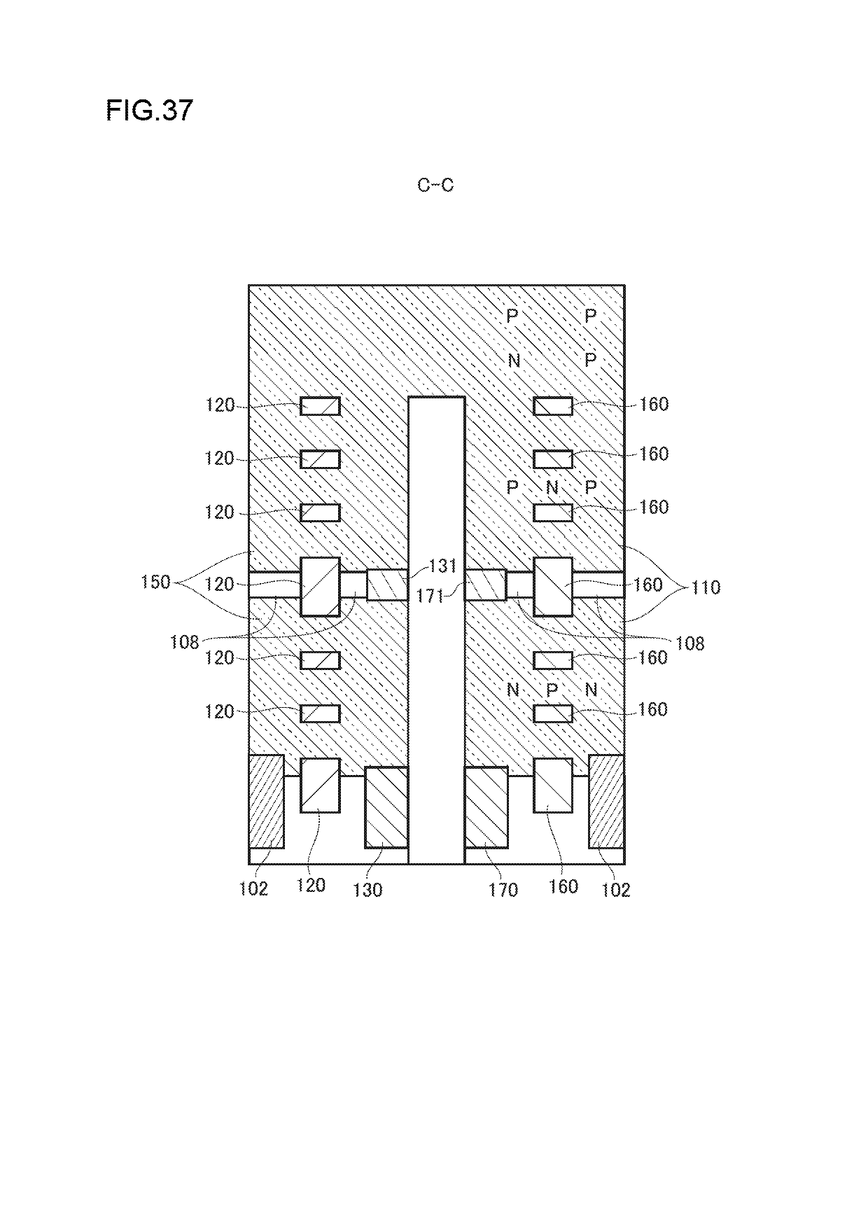

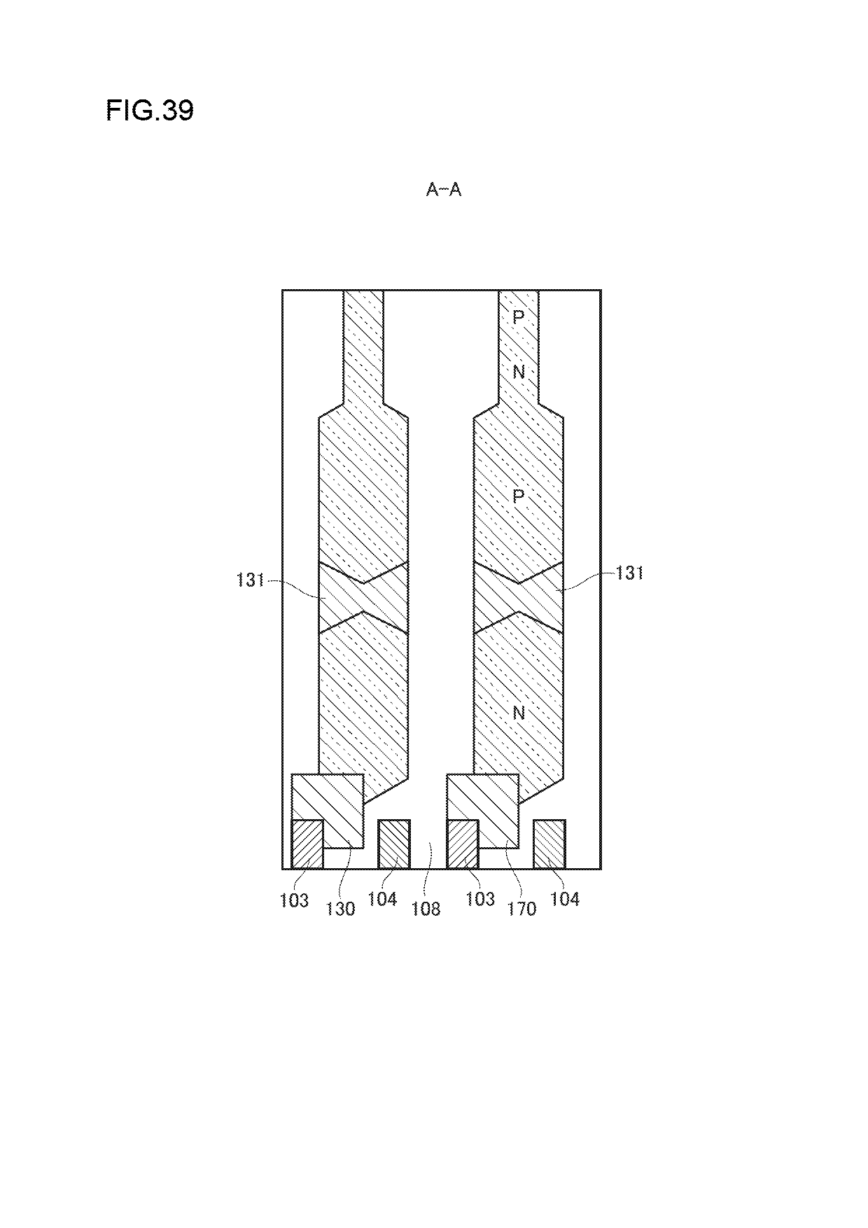

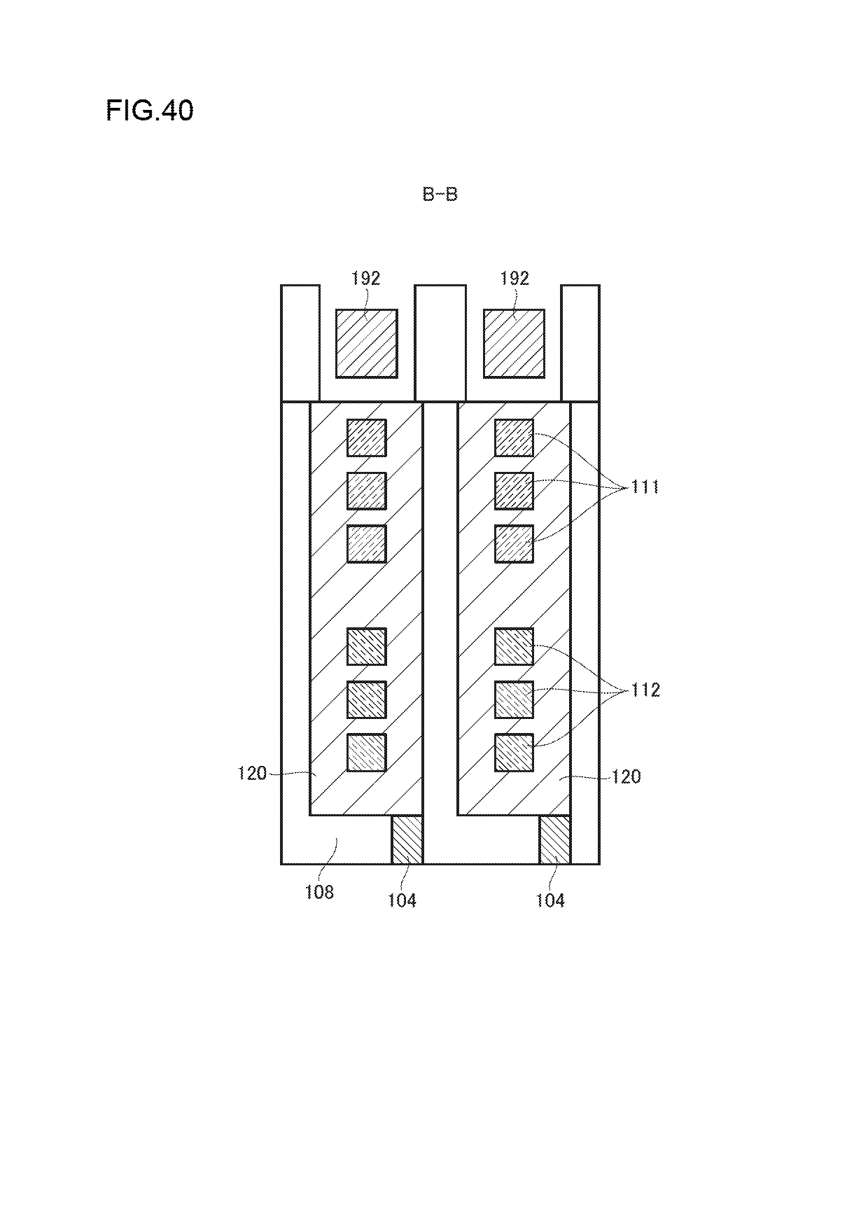

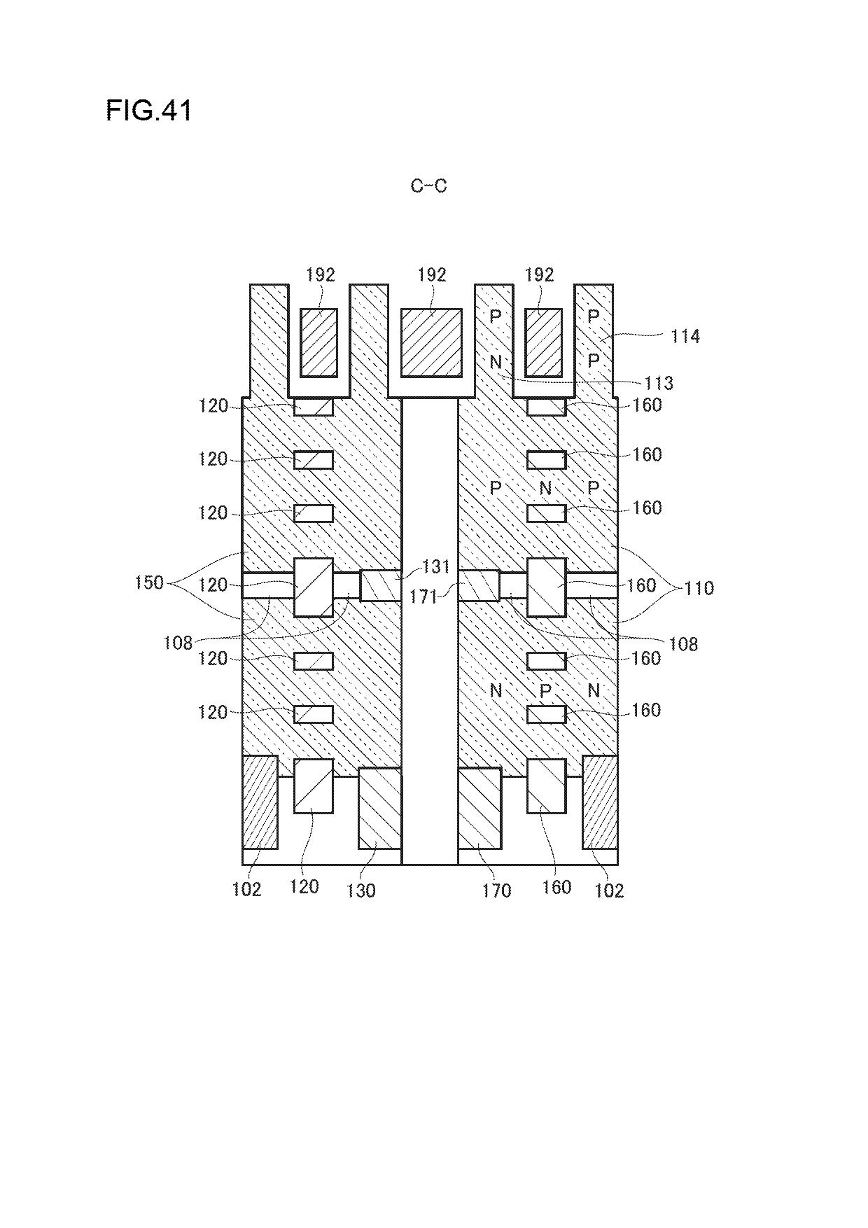

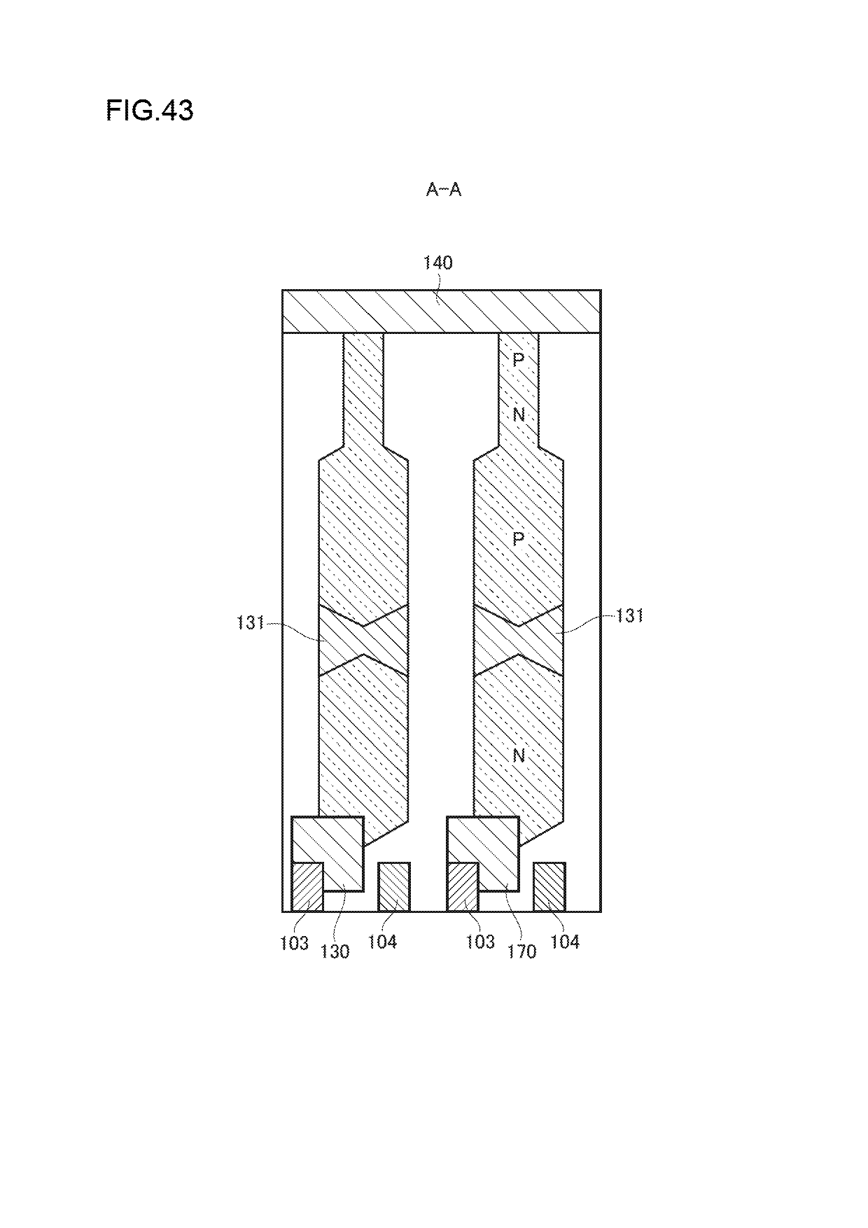

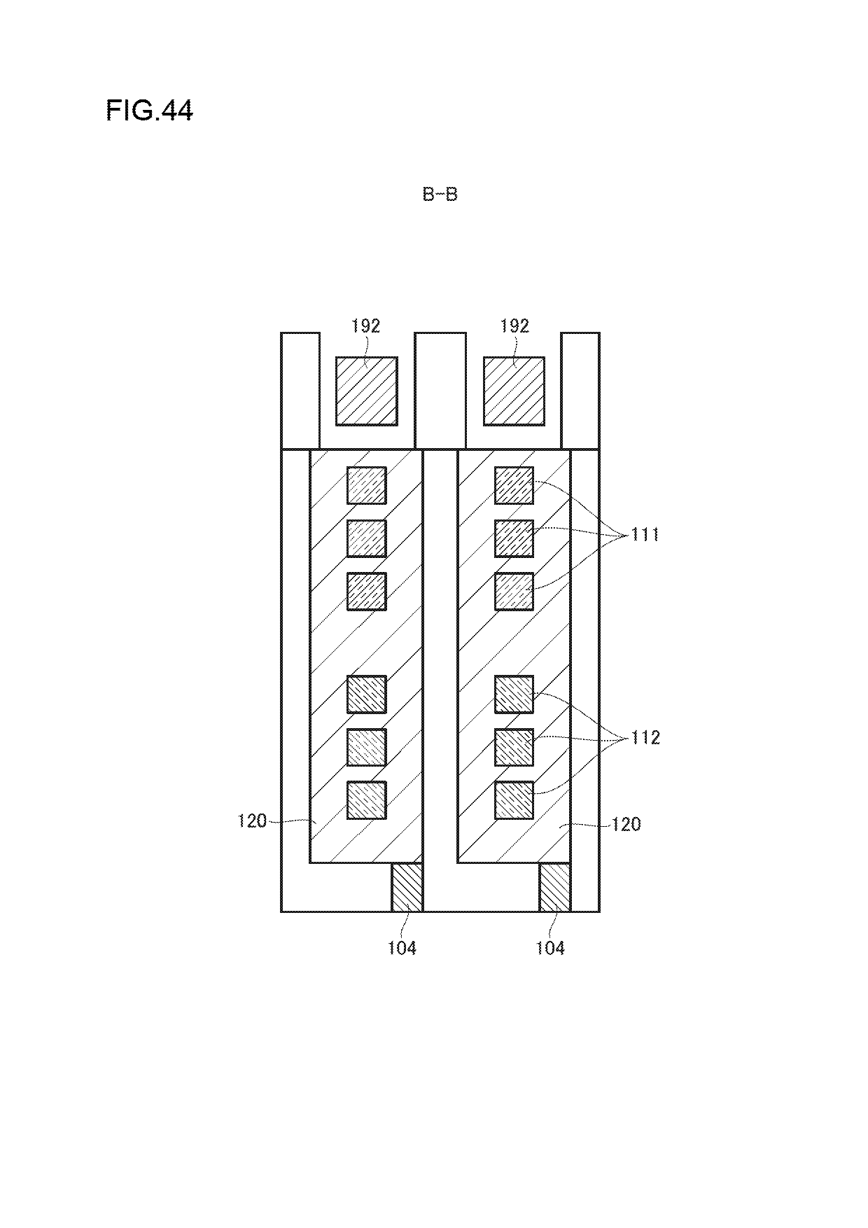

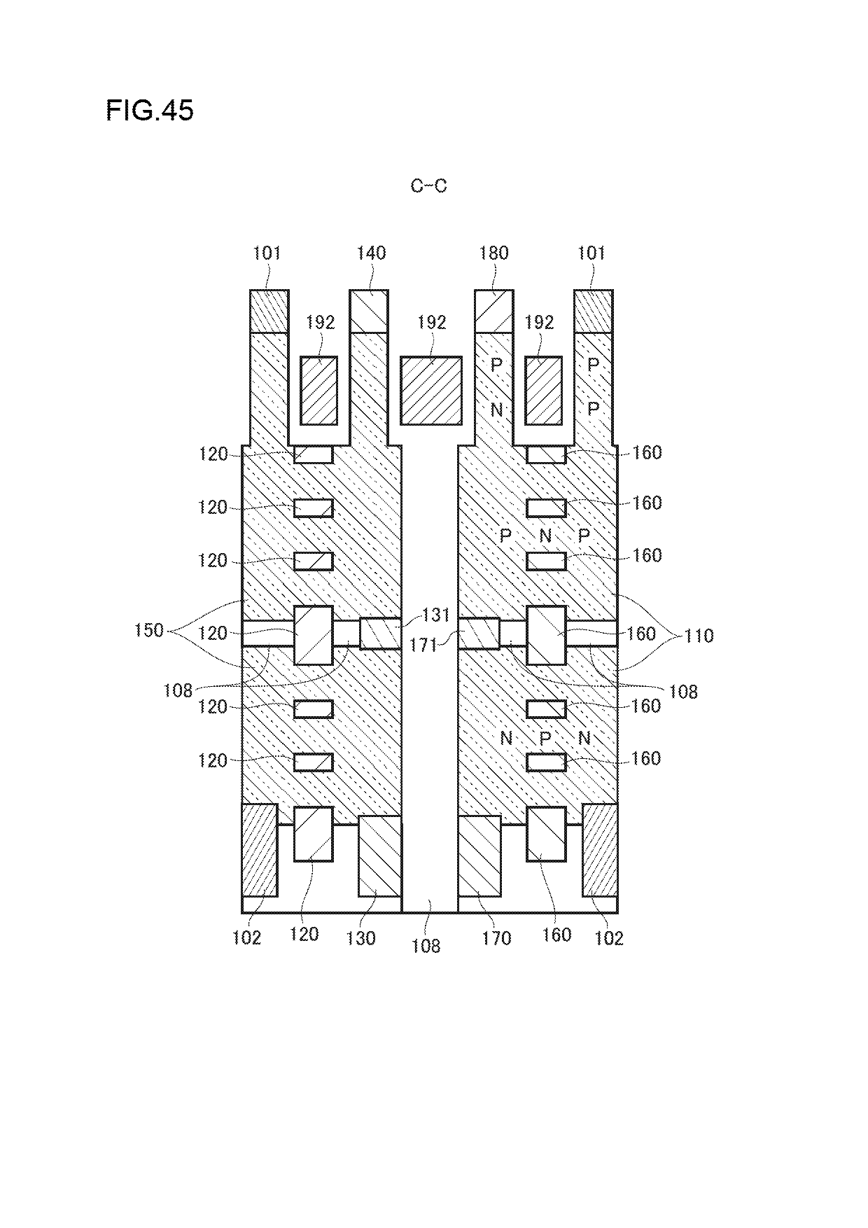

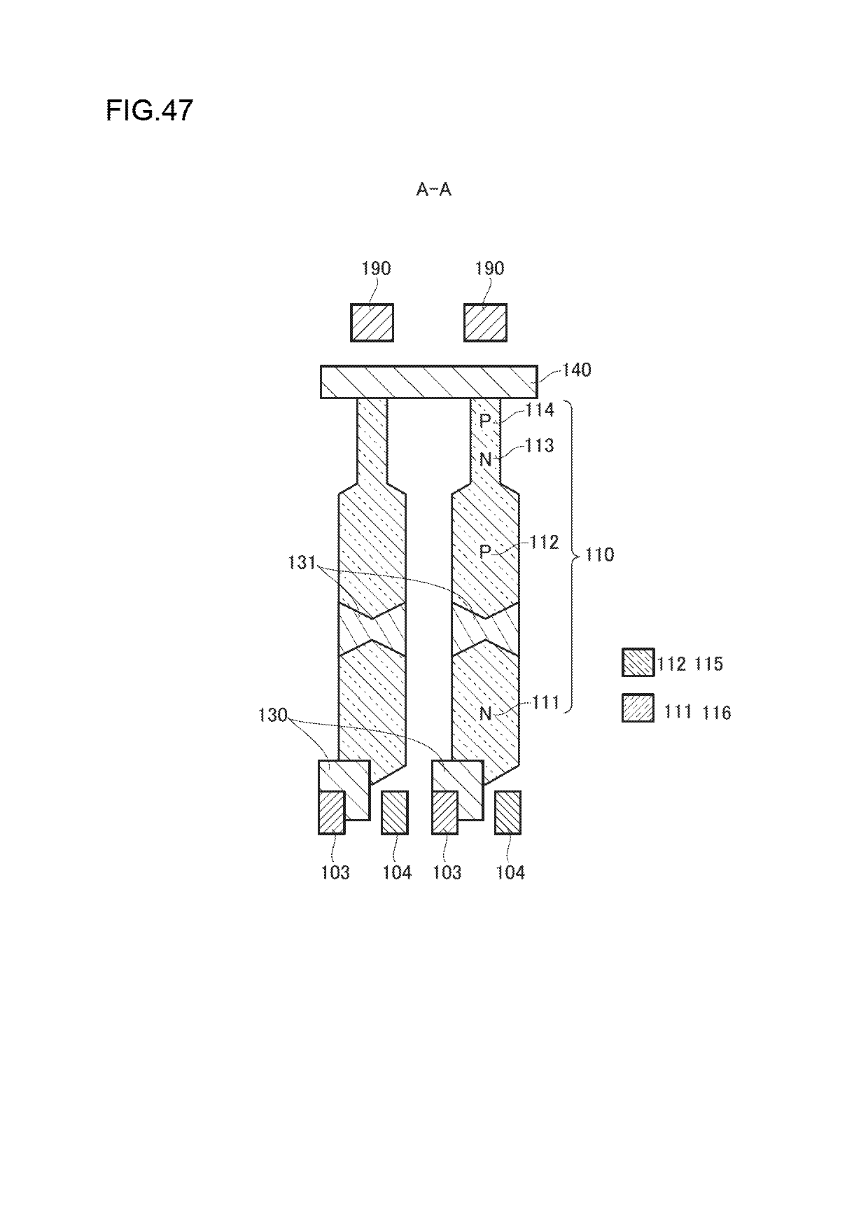

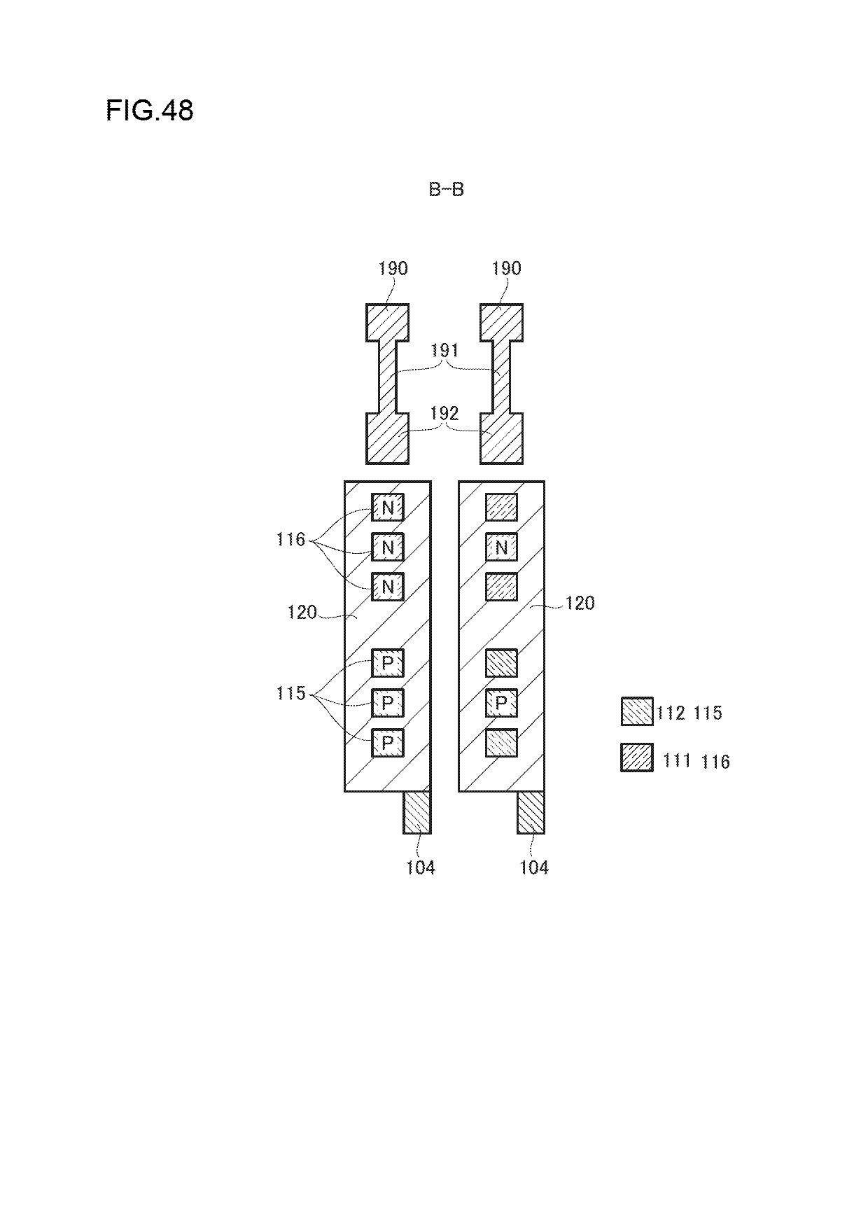

Next, a method for manufacturing the above-described SRAM cell 100 will be described. FIGS. 6 to 49 illustrate manufacturing process diagrams of the SRAM cell 100. In the process of manufacturing the SRAM cell 100 illustrated in FIGS. 6 to 49, similarly to FIGS. 2 to 5 described above, four diagrams consisting of a plan layout view, and a cross-sectional view taken along line A-A, a cross-sectional view taken along line B-B, and a cross-sectional view taken along line C-C in the plan layout view are illustrated for each step. Note that, in the description of the method for manufacturing the SRAM cell 100, similar components to those in FIGS. 2 to 5 described above are denoted by the same reference numerals, and detailed description thereof is omitted.

First, as illustrated in FIGS. 6 to 9, the semiconductor layer 110, 150 having a CFET structure in which two nanosheet transistors having a GAA-FET structure are stacked in a vertical direction and the dummy gate 105, 121, 161 are formed using a known method.

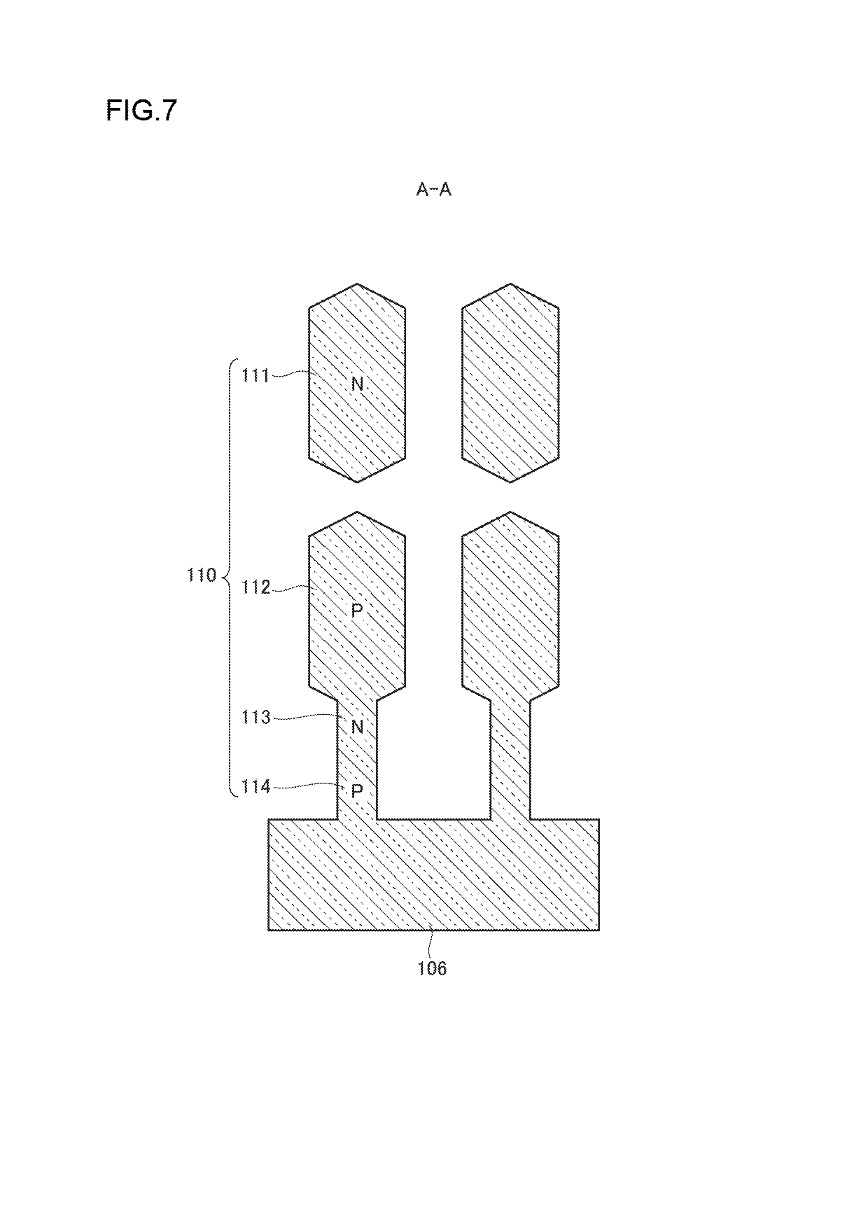

For example, first, N-type or P-type impurities are implanted into a region to be the transistor M5, M6 of the substrate 106 to form the P-type semiconductor layer 114, 154 and the N-type semiconductor layer 113, 153. Then, a stack of a SiGe layer (sacrificial layer) and a Si layer (semiconductor layer) is formed on the substrate 106 by epitaxial growth. In the structure of FIGS. 7 to 9, six SiGe layers and six Si layers are stacked. A Ge layer may be used instead of the Si layer. At this time, by implanting N-type or P-type impurities into the Si layer, the P-type semiconductor layer 115, 155 and the N-type semiconductor layer 116, 156 to be channel regions are formed. Also when a Ge layer is used instead of the Si layer, by implanting N-type or P-type impurities into the Ge layer, the P-type semiconductor layer 115, and 155 and the N-type semiconductor layer 116, 156 to be channel regions are formed.

Next, a patterned hard mask, the dummy gate 105, 121, 161, and the like are formed on the SiGe/Si stack, and the SiGe/Si stack is etched to form an SiGe/Si pillar. Furthermore, element isolation such as a shallow trench isolator (STI) is formed on the substrate 106 in a region excluding the P-type semiconductor layer 114, 154 and the N-type semiconductor layer 113, 153 to be the transistor M5, M6.

A Si layer is formed on a side surface of the SiGe/Si stack by epitaxial growth. At this time, by implanting N-type or P-type impurities into the Si layer, the N-type semiconductor layer 111, 151 and the P-type semiconductor layer 112, 152 to be source/drain regions of the transistors M1 to M4 are formed.

The SiGe layer is selectively removed, and then polysilicon or the like is embedded in the region from which the SiGe layer has been removed to form the dummy gate 105, 121, 161.

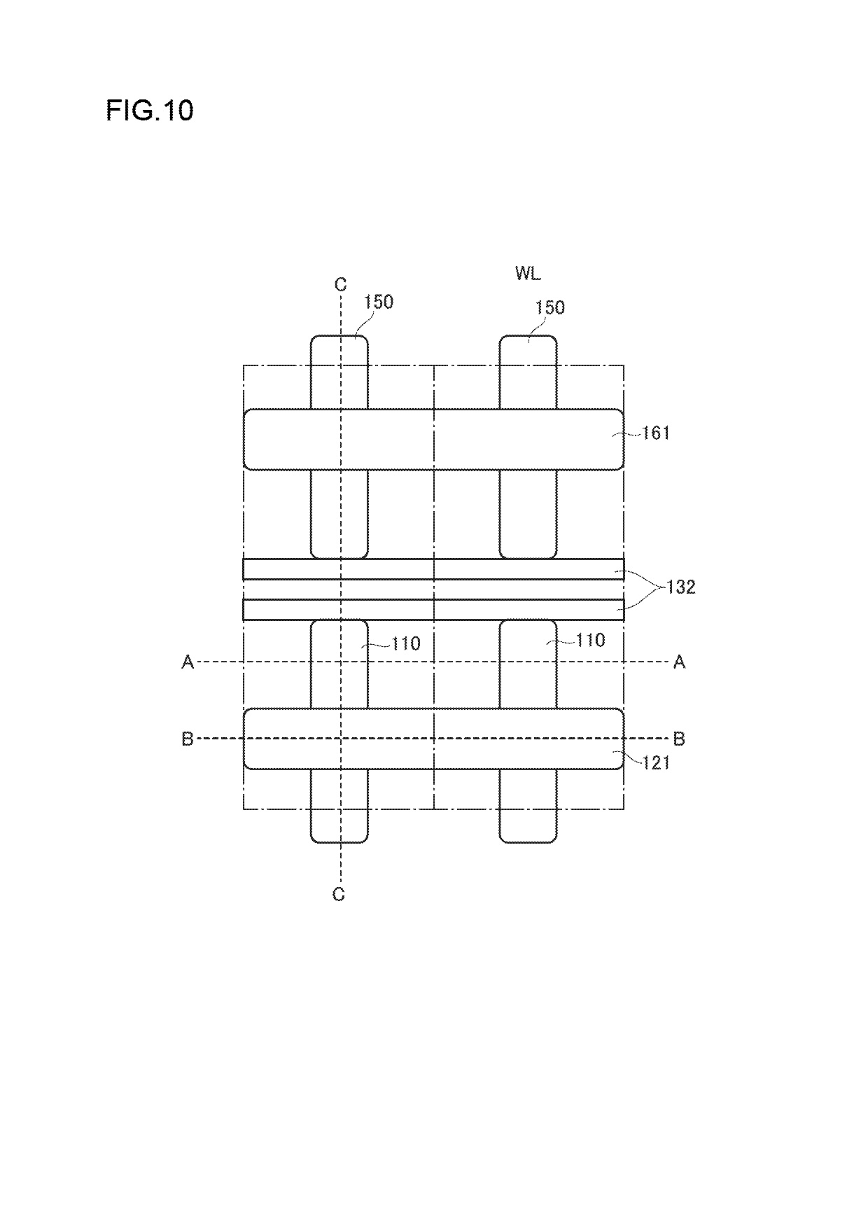

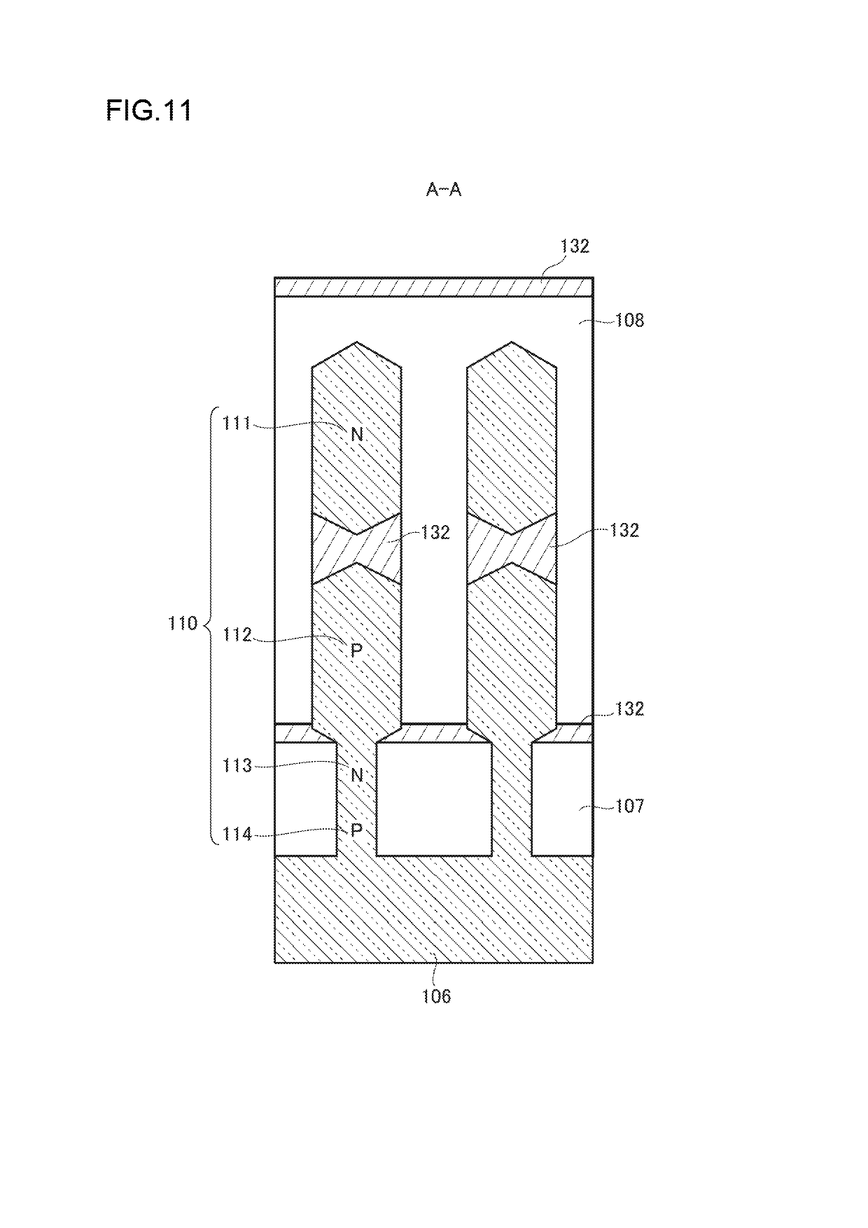

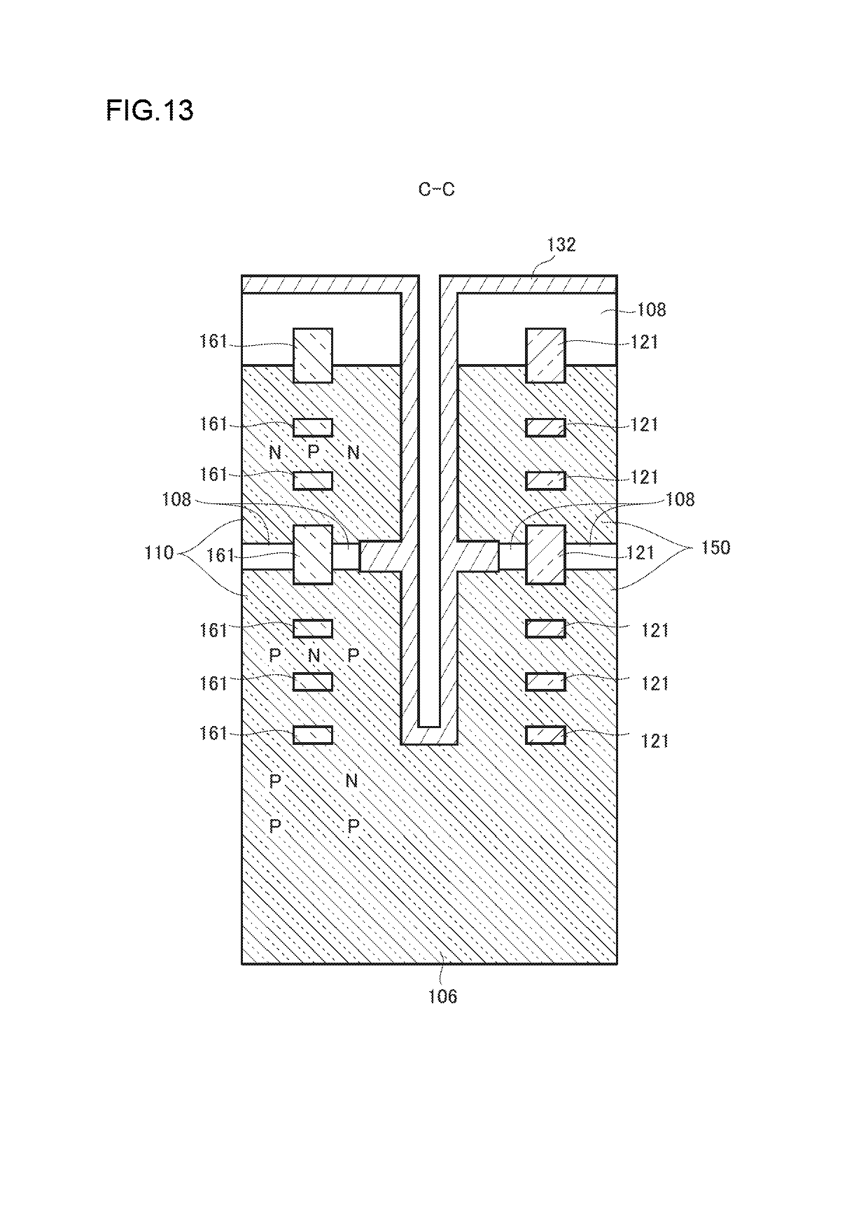

Next, as illustrated in FIGS. 10 to 13, an insulating layer 108 is formed on the entire surface of the substrate 106, and then the dummy gates 105 for one row and a semiconductor layer between the layers of the dummy gates 105 are removed and dug to form element isolation between the semiconductor layer 110 and the semiconductor layer 150. At this time, the insulating layer 108 formed between the N-type semiconductor layer 111 and the P-type semiconductor layer 112 and between the N-type semiconductor layer 151 and the P-type semiconductor layer 152 is partially removed. Furthermore, the insulating layer 108 on an STI 107 is partially removed below the semiconductor layer 110 and the semiconductor layer 150. Then, a Ti/TiN layer 132 is formed on the entire surface. As a result, the Ti/TiN layer 132 is formed on a side surface and a bottom surface of the element isolation region between the semiconductor layer 110 and the semiconductor layer 150. In addition, as illustrated in FIGS. 11 and 13, the Ti/TiN layer 132 intrudes into a part between the P-type semiconductor layer 112, 152 and the N-type semiconductor layer 111, 151, and a contact by the Ti/TiN layer 132 is formed between the P-type semiconductor layer 112, 152 and the N-type semiconductor layer 111, 151. Furthermore, a contact by the Ti/TiN layer 132 is formed in a part above the STI 107.

Note that, in FIGS. 11 to 13, the STI 107 formed on the substrate, and the insulating layer 108 formed on the semiconductor layer 110 and the semiconductor layer 150 are illustrated for the sake of explanation.

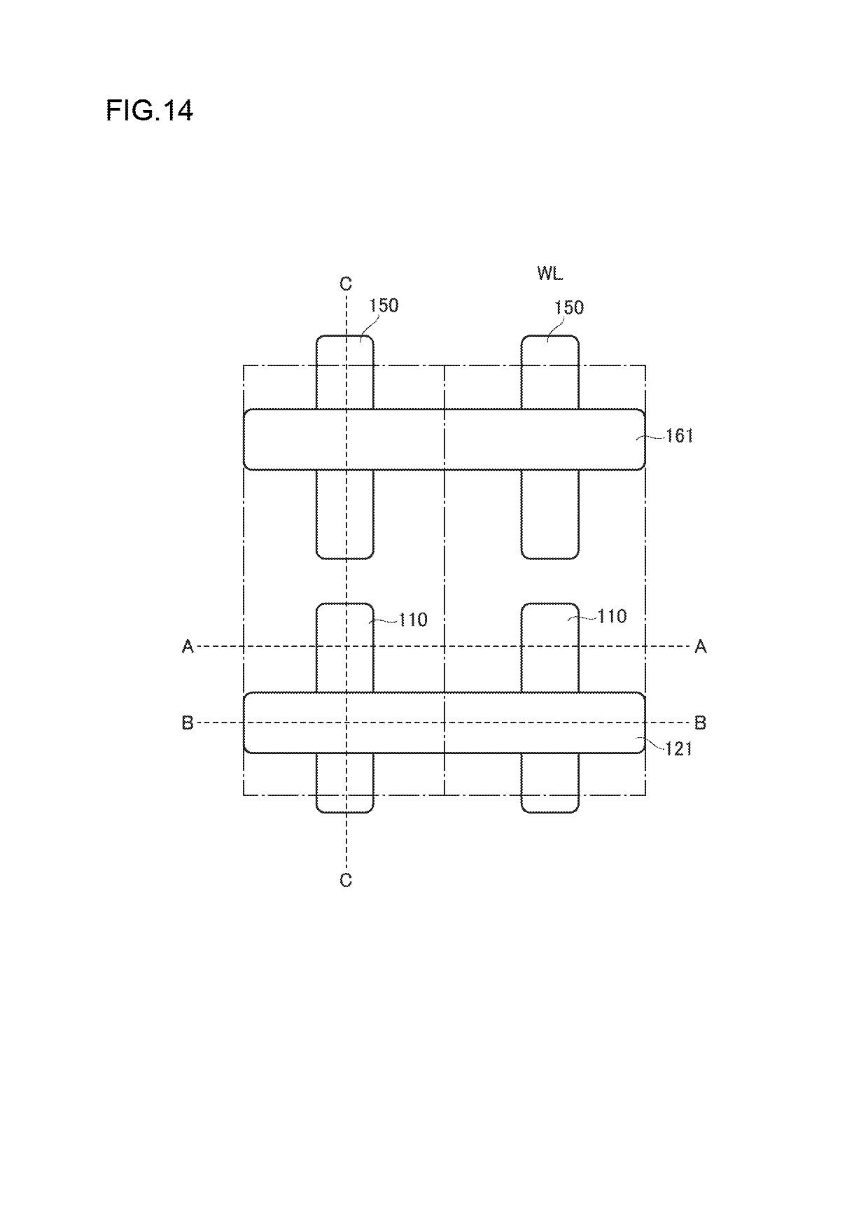

Next, as illustrated in FIGS. 14 to 17, the Ti/TiN layer 132 is etched back to leave the PN junction contact 131, 171 by the Ti/TiN layer between the P-type semiconductor layer 112, 152 and the N-type semiconductor layer 111, 151. In addition, the Ti/TiN layer 132 is left on the STI 107 below the N-type semiconductor layer 111, 151.

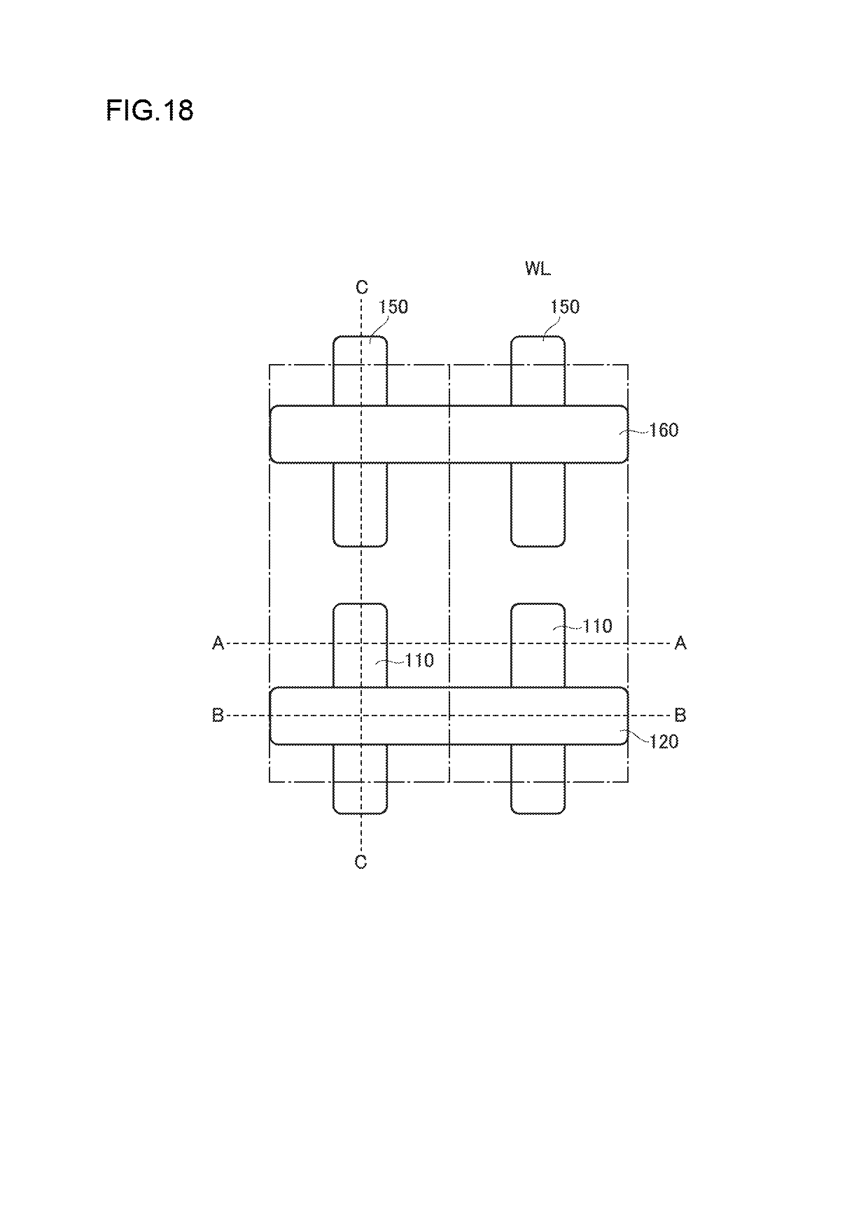

Next, as illustrated in FIGS. 18 to 21, the dummy gate 121, 161 is removed, and then a TiN layer is formed in a region from which the dummy gate 121, 161 has been removed. As a result, the gate electrode 120 is formed in the semiconductor layer 110, and the gate electrode 160 is formed in the semiconductor layer 150.

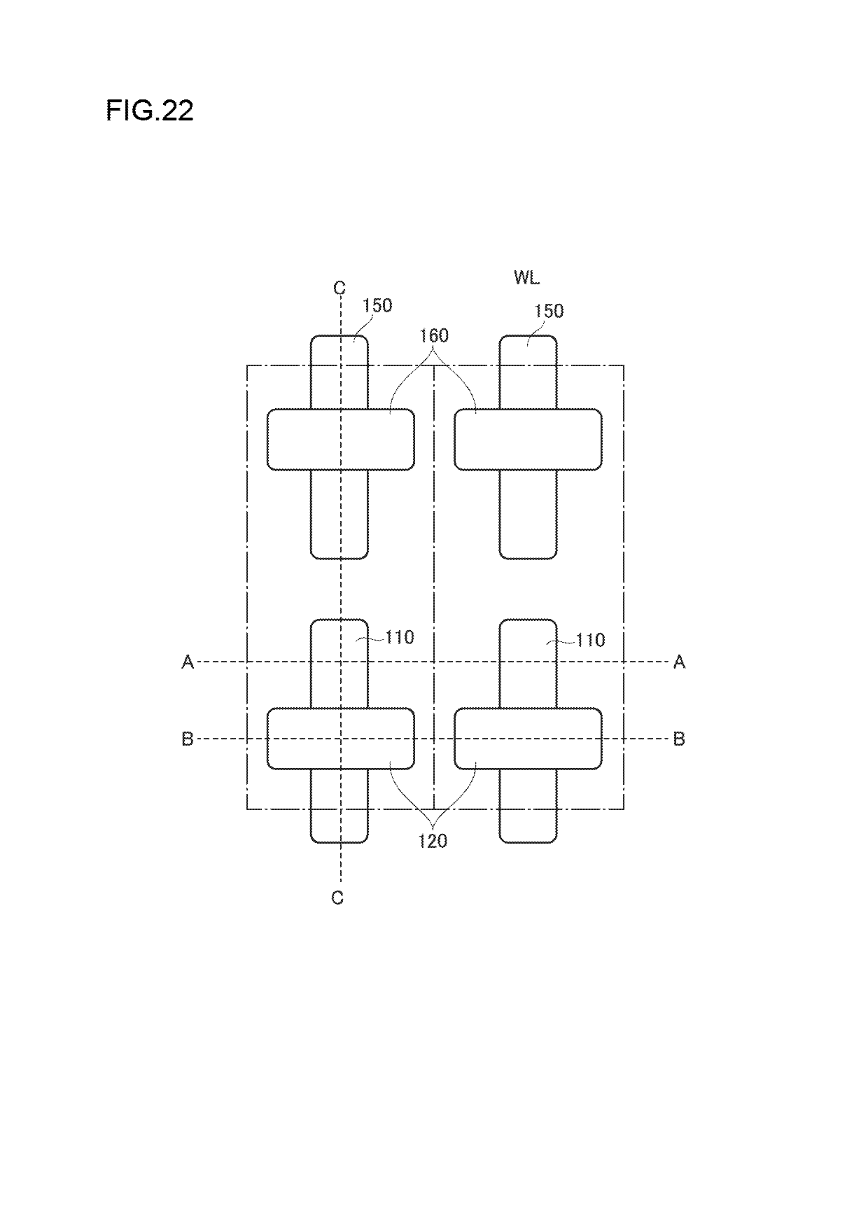

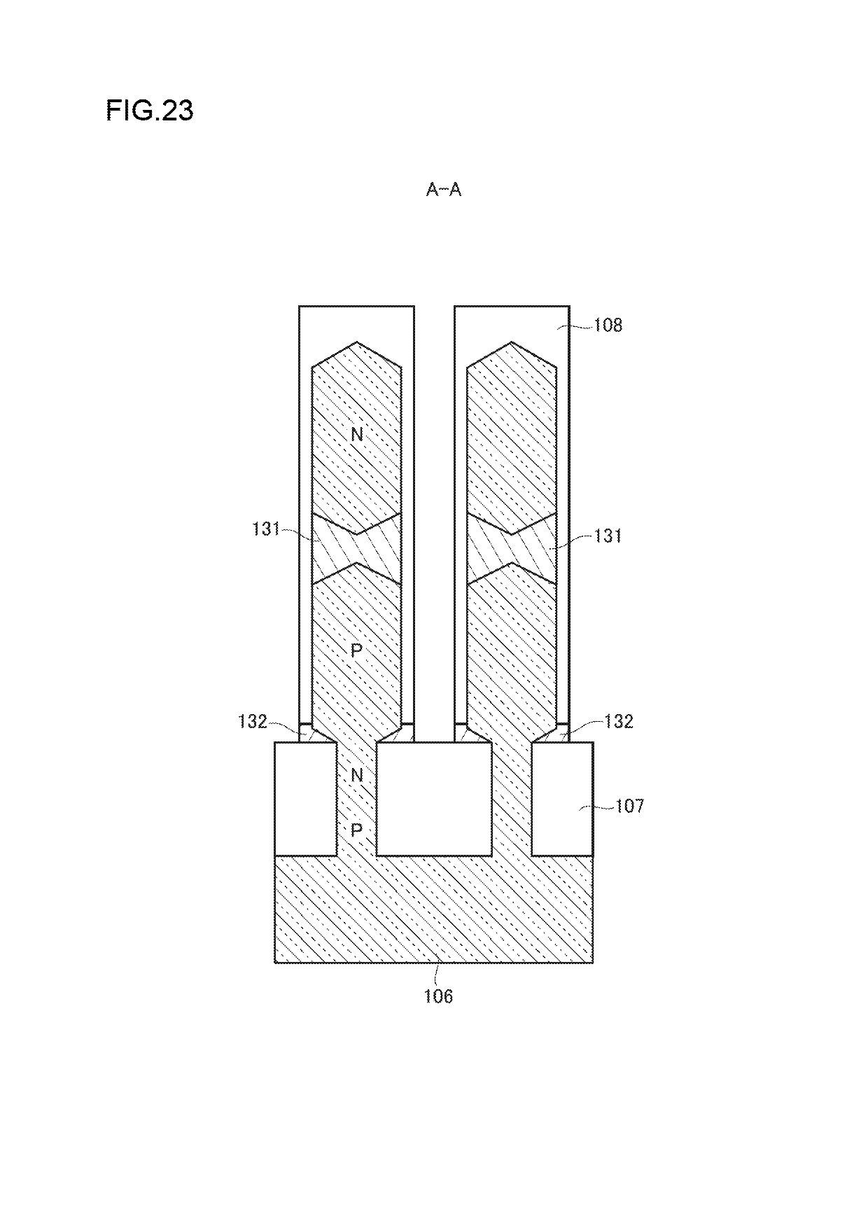

Next, as illustrated in FIGS. 22 to 25, the gate electrode 120, 160 in a region between elements of the adjacent SRAM cells 100 is removed. As a result, the gate electrode 120, 160 continuously formed between the elements of the adjacent SRAM cells 100 are isolated. At this time, as illustrated in FIG. 23, a region between the elements of the SRAM cells 100 is removed also from the Ti/TiN layer 132 left on the STI 107 below the N-type semiconductor layer 111.

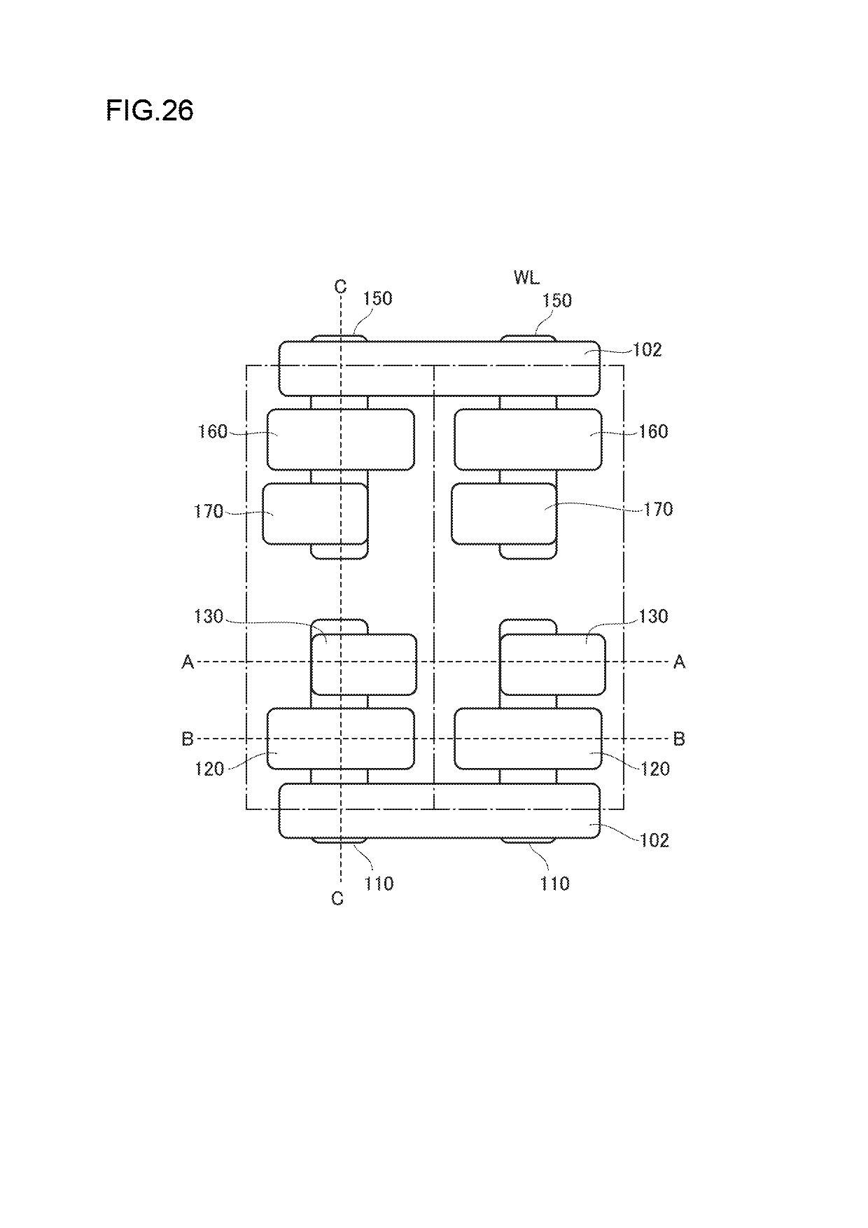

Next, as illustrated in FIGS. 26 to 29, the FET junction contact 130, 170 is formed on the N-type semiconductor layer 111, 151. The FET junction contact 130 is formed on the N-type semiconductor layer 111 which is a source/drain region of the transistor M3. The FET junction contact 170 is formed on the N-type semiconductor layer 151 which is a source/drain region of the transistor M4.

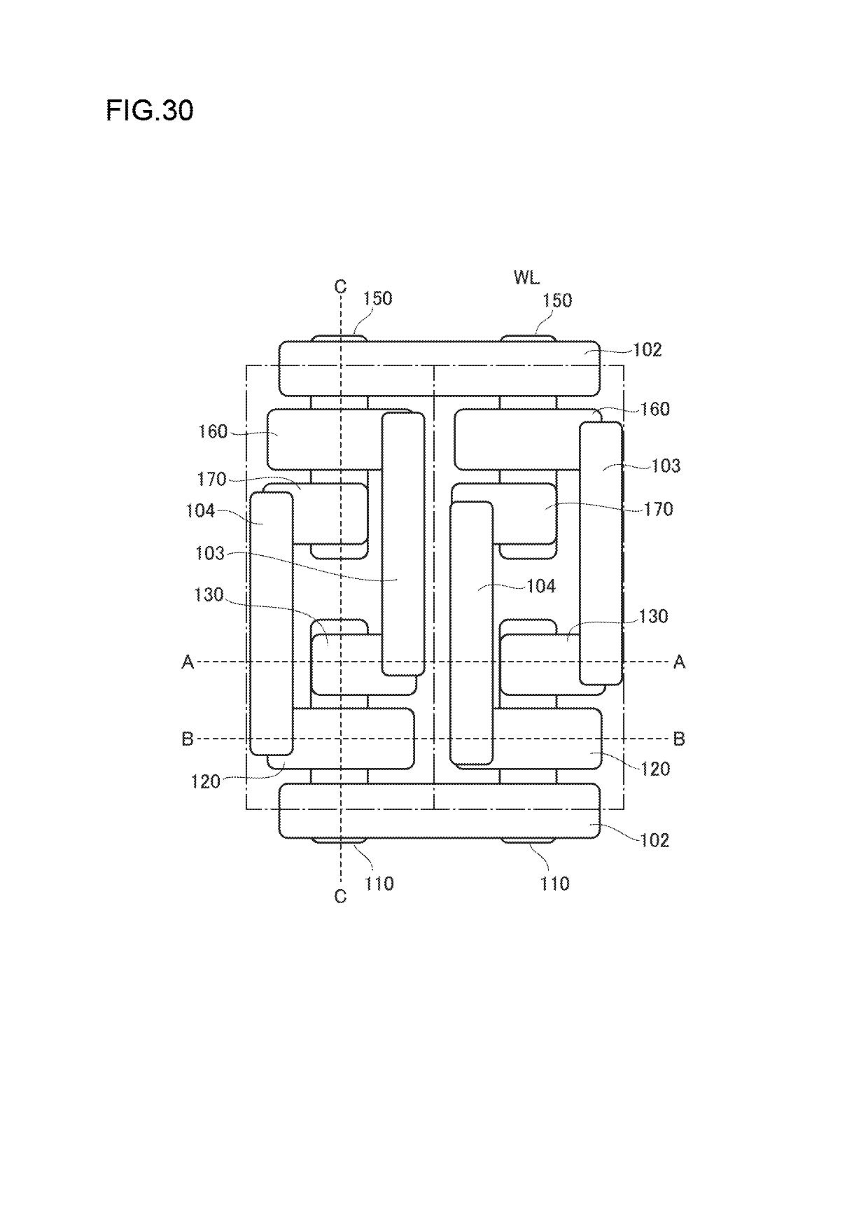

Next, as illustrated in FIGS. 30 to 33, the wiring line 103, 104 for connecting the first inverter and the second inverter is formed. The wiring line 103, 104 is formed on the FET junction contact 130, 170, the N-type semiconductor layer 111 which is a source/drain region of the transistor M3, and the N-type semiconductor layer 151 which is a source/drain region of the transistor M4. The wiring line 103 is formed so as to connect the FET junction contact 130 and the N-type semiconductor layer 151 which is a source/drain region of the transistor M4. The wiring line 104 is formed so as to connect the FET junction contact 170 and the N-type semiconductor layer 111 which is a source/drain region of the transistor M3.

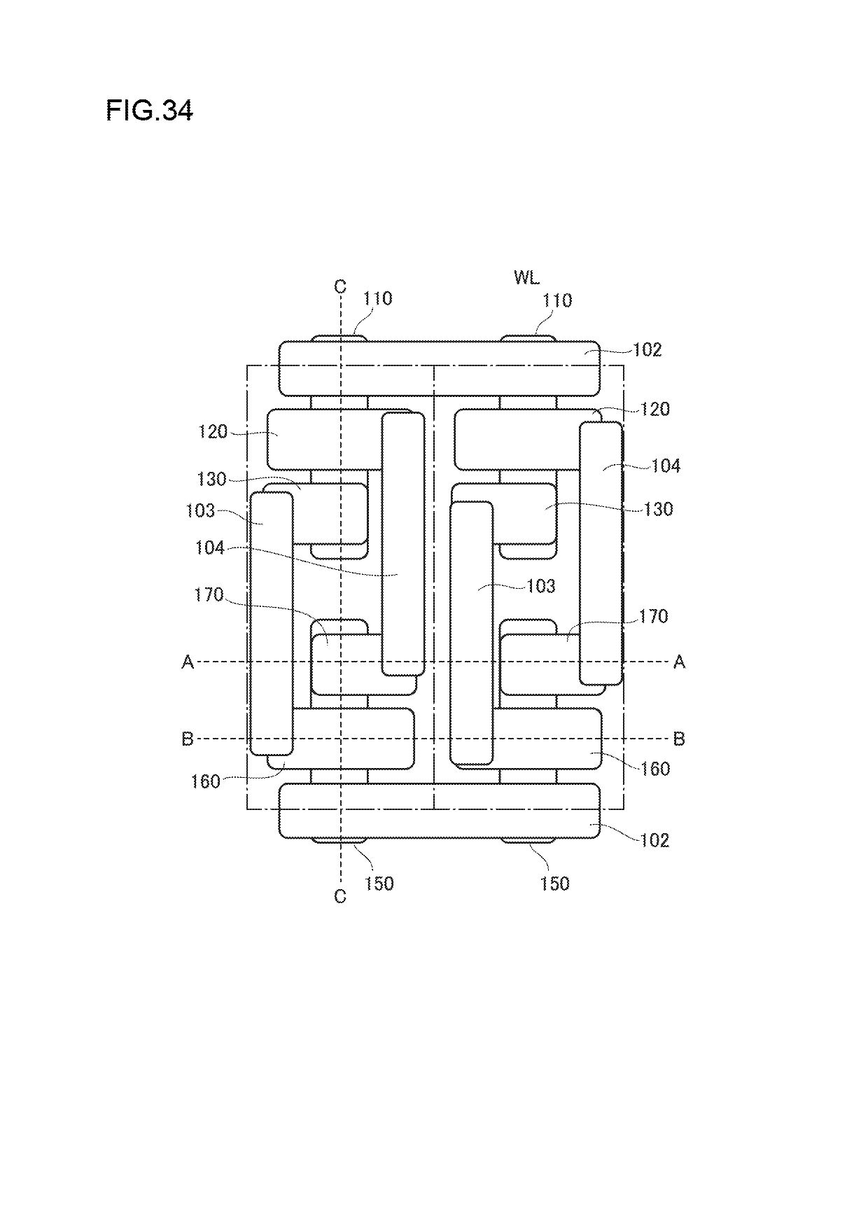

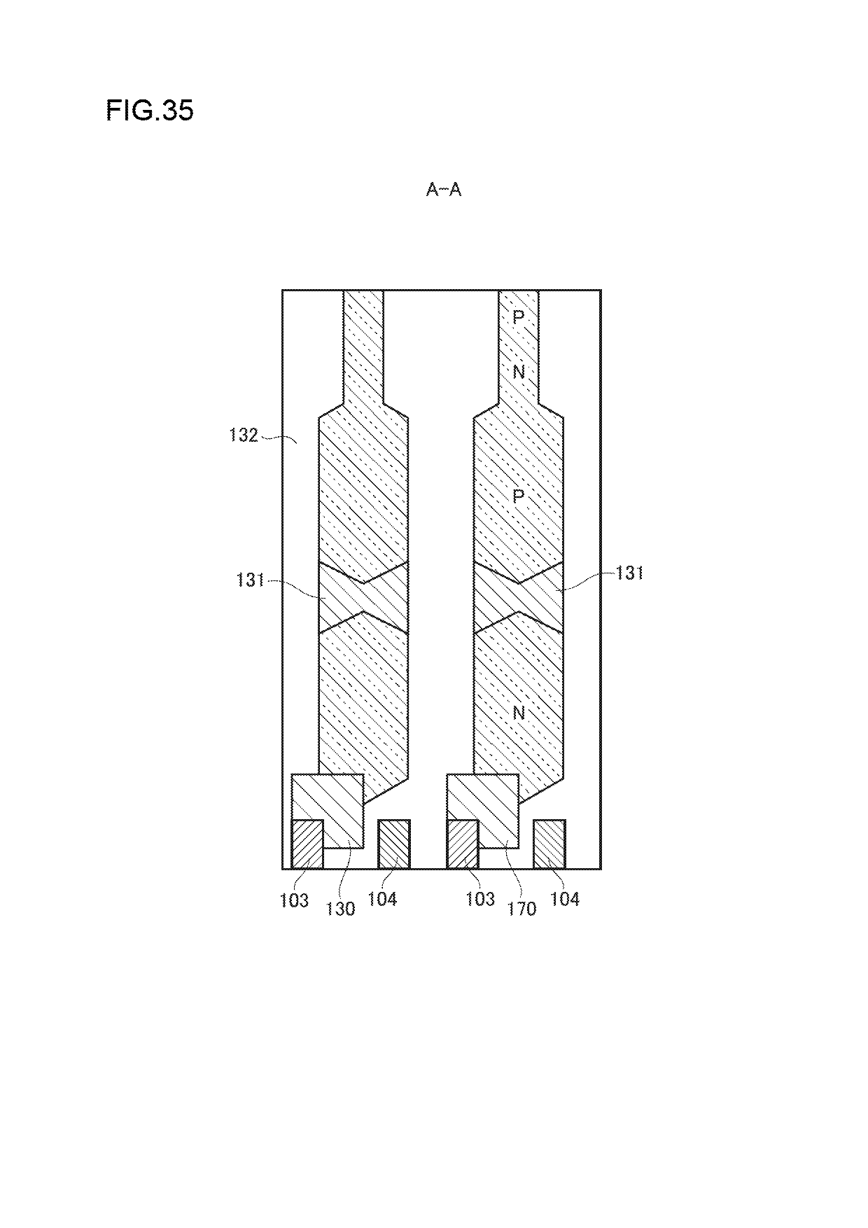

Next, as illustrated in FIGS. 34 to 37, the substrate 106 is turned upside down, and then the substrate 106 is removed. As a result, as illustrated in FIGS. 35 to 37, the P-type semiconductor layer 114, 154 is exposed.

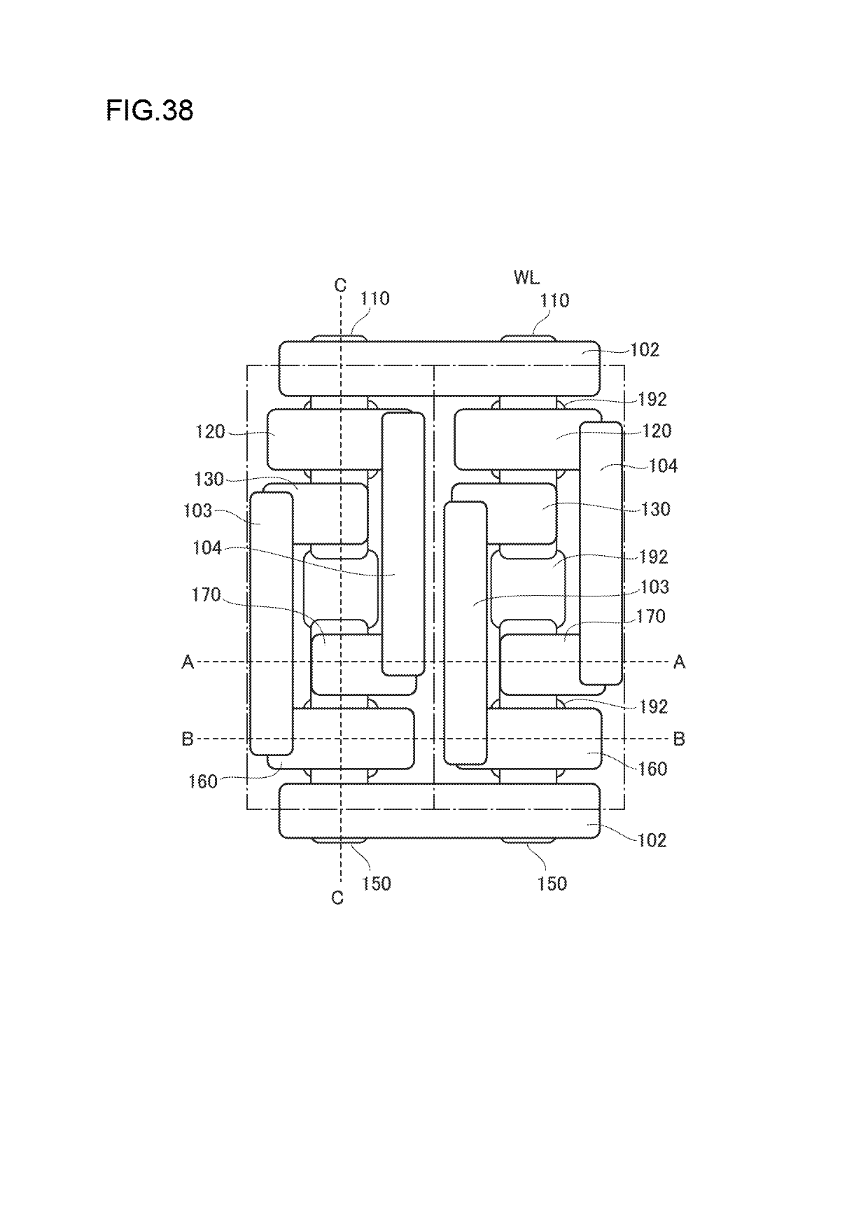

Then, as illustrated in FIGS. 38 to 41, the gate electrode 192 is formed on the gate electrode 120, 160 from a surface (back surface side) from which the substrate 106 has been removed. In the formation of the gate electrode 192, first, the semiconductor layer (P-type semiconductor layer 114) on the gate electrode 120, 160 and the semiconductor layer below the element isolation region between the semiconductor layer 110 and the semiconductor layer 150 formed in the steps illustrated in FIGS. 22 to 25 are removed to a height at which the gate electrode 120, 160 is exposed. Then, a gate insulating film, a dielectric layer, and the like are formed in the recess formed by removing the semiconductor layers, and then a metal layer such as TiN is embedded therein. As a result, the gate electrode 192 is formed on side surfaces of the N-type semiconductor layer 113 and the P-type semiconductor layer 114. At the same time, the gate electrode 192 is formed on side surfaces of the N-type semiconductor layer 153 and the P-type semiconductor layer 154. At this time, the gate electrode 192 is formed also in a region between the N-type semiconductor layer 113/P-type semiconductor layer 114 and the N-type semiconductor layer 153/P-type semiconductor layer 154, that is, on the element isolation between the semiconductor layer 110 and the semiconductor layer 150.

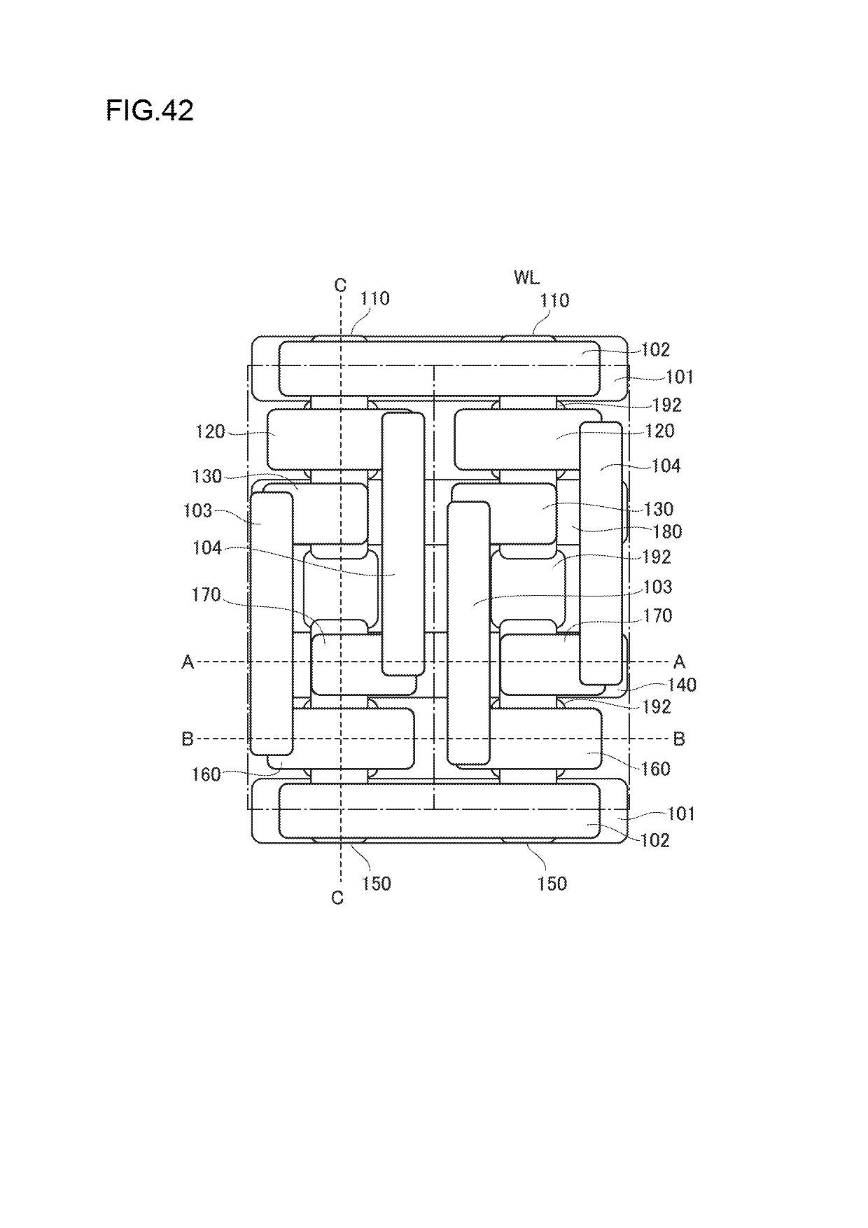

Next, as illustrated in FIGS. 42 to 45, the first bit line 140, the second bit line 180, and the VDD 101 are formed. The first bit line 140 is formed on the P-type semiconductor layer 114 in which the N-type semiconductor layer 113 is formed below. The second bit line 180 is formed on the P-type semiconductor layer 154 in which the N-type semiconductor layer 151 is formed below. The VDD 101 is formed on the P-type semiconductor layer 114, 154 in which the N-type semiconductor layer 113, 153 is not formed below. The first bit line 140, the second bit line 180, and the VDD 101 are continuously formed in the adjacent SRAM cells 100.

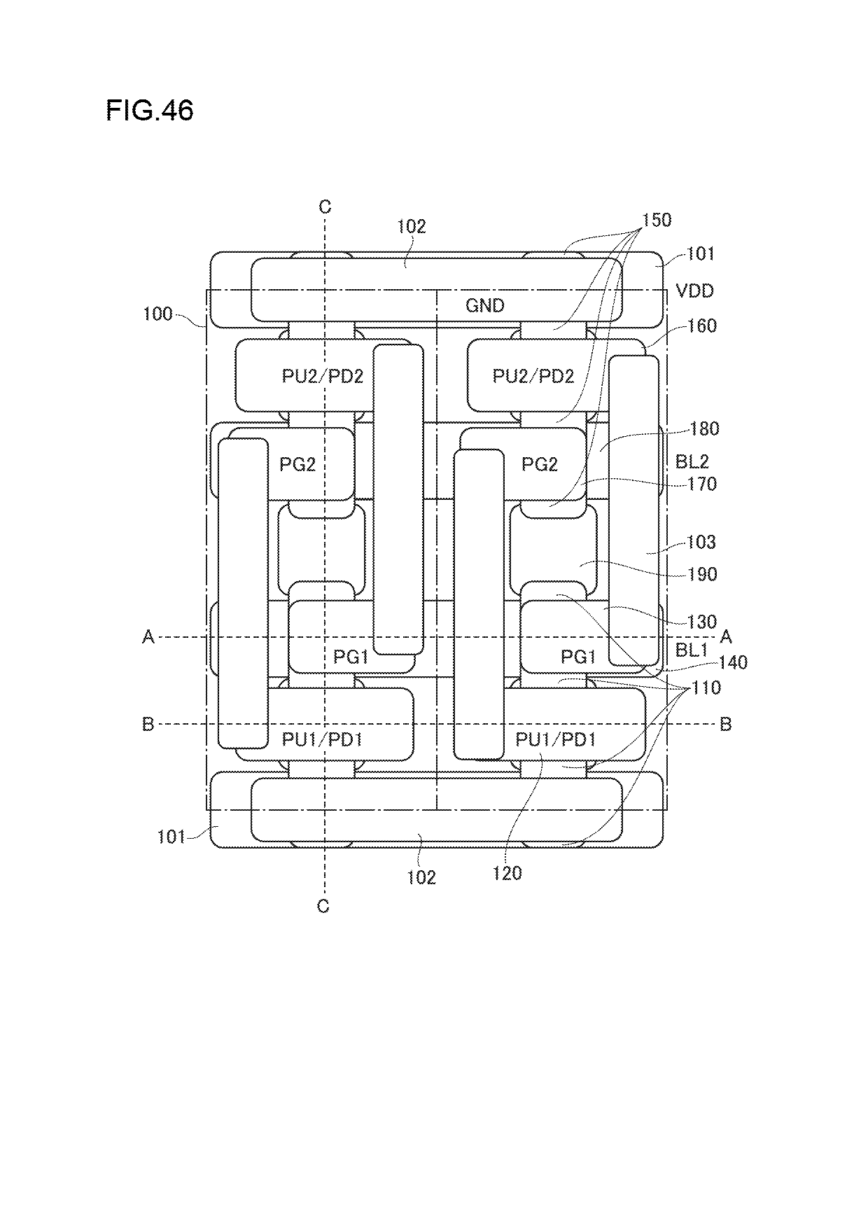

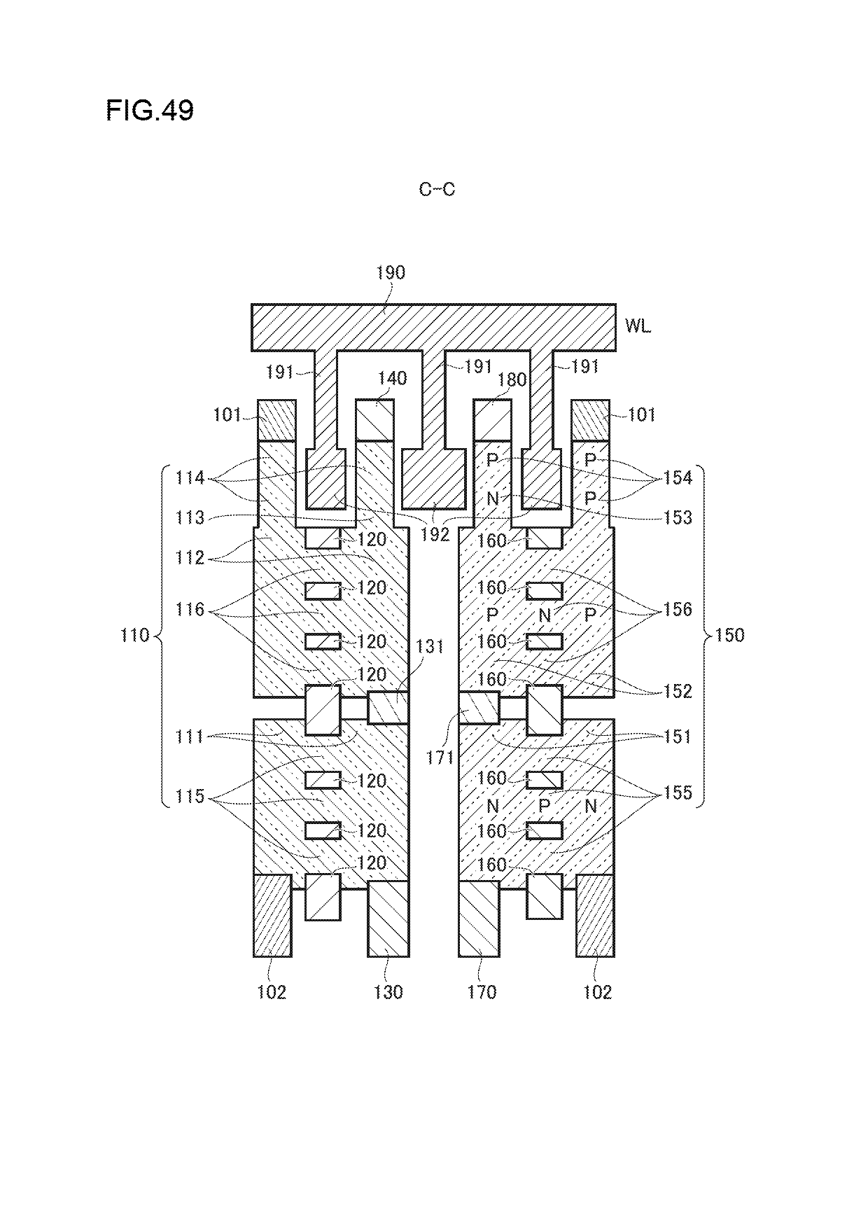

Next, as illustrated in FIGS. 46 to 49, the word contact 191 and the word line 190 are formed in the gate electrode 192. The word line 190 is formed above the gate electrode 120, the first bit line 140, the second bit line 180, and VDD 101. As illustrated in FIG. 49, the gate electrode 192 is formed on a side surface of the N-type semiconductor layer 113, 153 to be a channel of the transistor M5, M6. The plurality of gate electrodes 192 are connected to each other by one word line 190. Therefore, the word contact 191 is formed in a vertical direction from the word line 190 to the gate electrode 192, and the gate electrodes 192 are connected to the word line 190.

Through the above steps, it is possible to manufacture a semiconductor memory element (SRAM cell) having a CFET structure in which two nanosheet transistors having a GAA-FET structure are stacked in a vertical direction, illustrated in FIGS. 2 to 5.

3. Semiconductor device of second embodiment

Next, a second embodiment of the semiconductor device will be described. The semiconductor device of the second embodiment described below partially has a similar structure to the semiconductor device of the first embodiment described above. Therefore, description of the similar structure to that of the semiconductor device of the first embodiment described above is omitted.

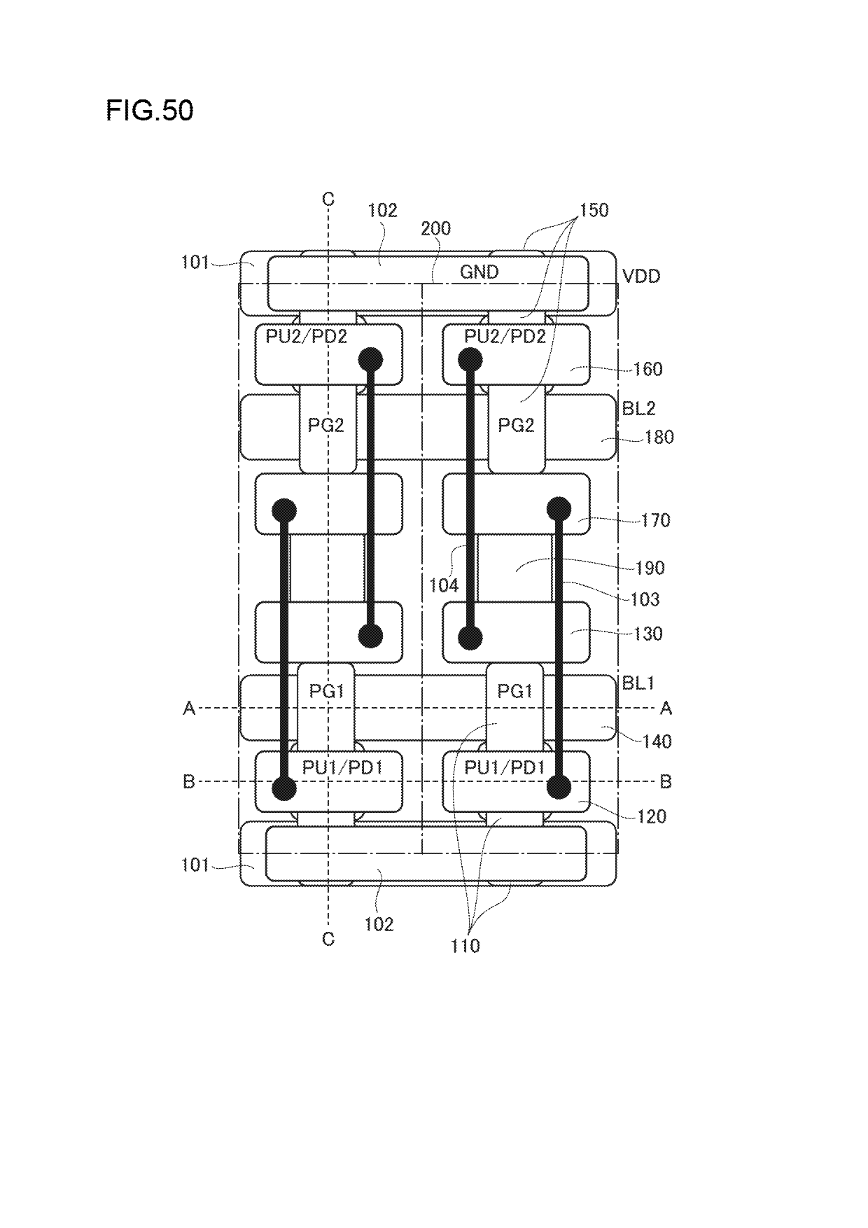

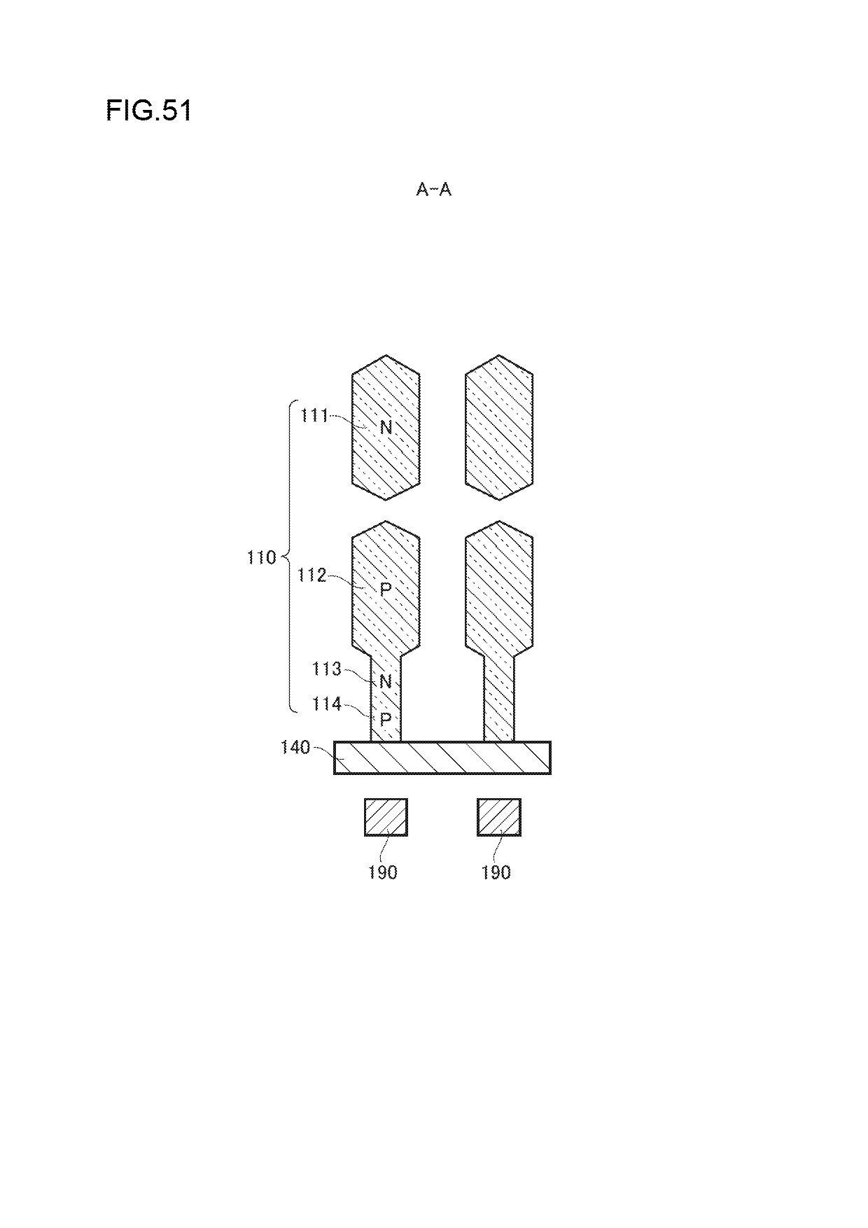

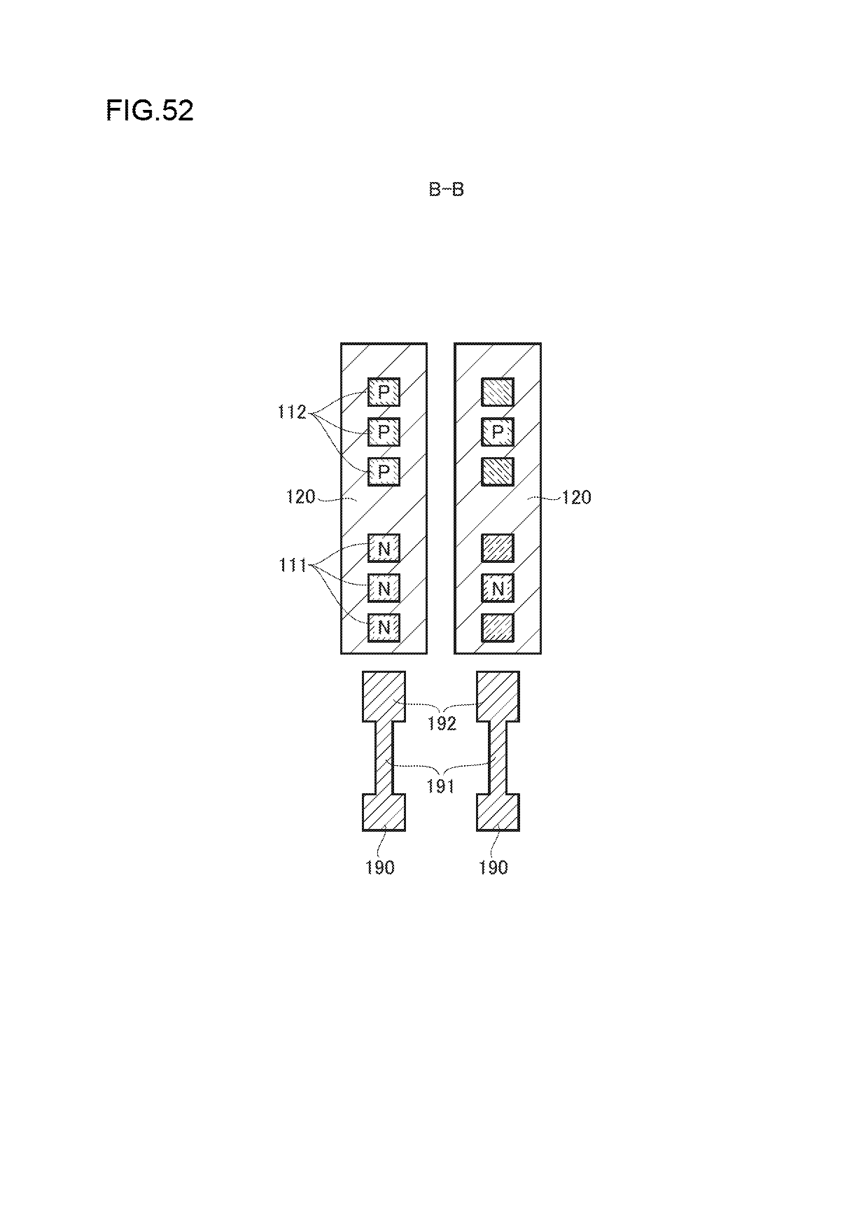

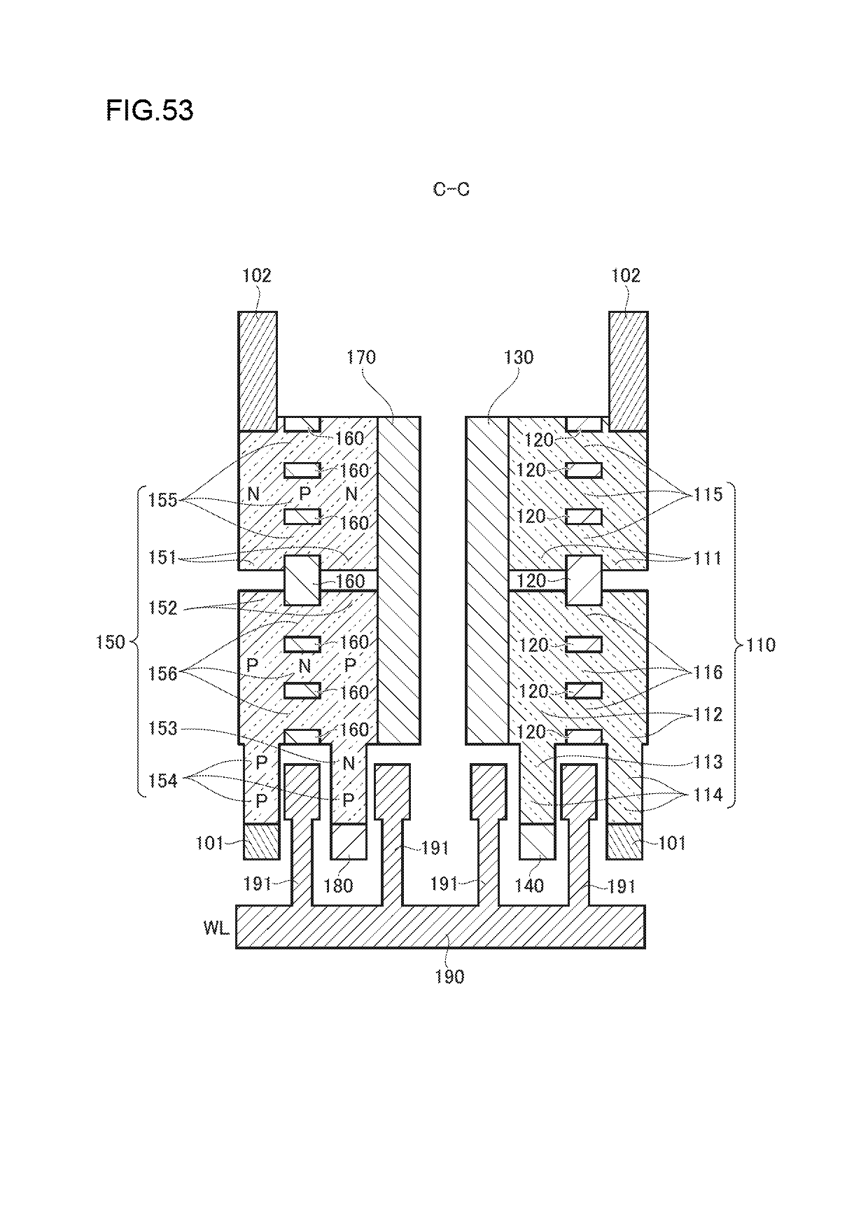

FIGS. 50 to 53 illustrate a structure of a semiconductor memory device (SRAM cell) including six transistors (6Tr) as an example of the semiconductor device. FIG. 50 is a plan layout view (top view) of the semiconductor memory element. FIG. 51 is a cross-sectional view taken along line A-A of the semiconductor memory element illustrated in FIG. 50. FIG. 52 is a cross-sectional view taken along line B-B of the semiconductor memory element illustrated in FIG. 50. FIG. 53 is a cross-sectional view taken along line C-C of the semiconductor memory element illustrated in FIG. 50.

In an SRAM cell 200 illustrated in FIGS. 50 to 53, the position of an FET junction contact 130, 170 and a distance from a semiconductor layer 110 to a semiconductor layer 150 are different from those of the SRAM cell 100 illustrated in FIGS. 2 to 5 described above. In addition, the shape of a wiring line 103, 104 for connecting a first inverter and a second inverter is different from that of the SRAM cell 100. A similar structure to the SRAM cell 100 illustrated in FIGS. 2 to 5 can be applied to the SRAM cell 200 illustrated in FIGS. 50 to 53 except for the above structure.

As illustrated in the plan view in FIG. 50, the FET junction contact 130, 170 is formed not on the semiconductor layer 110, 150 but beside the semiconductor layer 110, 150. Furthermore, a region of the FET junction contact 130, 170 is extended in a lateral direction (gate width direction of transistors M1 to M4). Therefore, the wiring line 103, 104 is formed above the SRAM cell 100 illustrated in FIGS. 2 to 5, and is connected to a gate electrode 120, 160 and an N-type semiconductor layer 111, 151 via a contact (via) or the like.

In addition, as illustrated in FIG. 51, in the cross-sectional view taken along line A-A in FIG. 50, there is no PN junction contact between the N-type semiconductor layer 111 and a P-type semiconductor layer 112. Furthermore, there is no FET junction contact 130 above the N-type semiconductor layer 111.

As illustrated in FIG. 52, in the cross-sectional view taken along line B-B in FIG. 50, a contact (via) and the like formed in the gate electrode 120 in order to be connected to the wiring line 103, 104 are not illustrated.

Furthermore, as illustrated in FIG. 53, in the cross-sectional view taken along line C-C in FIG. 50, the FET junction contact 130, 170 is formed in a region between the semiconductor layer 110 and the semiconductor layer 150. The FET junction contact 130 is formed continuously from a side surface of the N-type semiconductor layer 111 to a side surface of the P-type semiconductor layer 112 on a side surface of the semiconductor layer 110. Therefore, the FET junction contact 130 connects the N-type semiconductor layer 111 and the P-type semiconductor layer 112 only in a side surface direction of the N-type semiconductor layer 111 and the P-type semiconductor layer 112. There is no PN junction contact 131 (FIG. 5) between the N-type semiconductor layer 111 and the P-type semiconductor layer 112 in a stacking direction.

The FET junction contact 170 is formed continuously from a side surface of the N-type semiconductor layer 151 to a side surface of the P-type semiconductor layer 152 on a side surface of the semiconductor layer 150. Therefore, the FET junction contact 170 connects the N-type semiconductor layer 151 and the P-type semiconductor layer 152 only in a side surface direction of the N-type semiconductor layer 151 and the P-type semiconductor layer 152. There is no PN junction contact 171 (FIG. 5) between the N-type semiconductor layer 151 and the P-type semiconductor layer 152 in a stacking direction.

4. Method for manufacturing semiconductor device of second embodiment

Next, a method for manufacturing the above-described SRAM cell 200 will be described. Note that, to the method for manufacturing the SRAM cell 200, similar steps to those of the SRAM cell 100 of the first embodiment described above can be applied except for a part thereof. Therefore, in the method for manufacturing the SRAM cell 200, only steps different from those of the SRAM cell 100 of the first embodiment described above will be described.

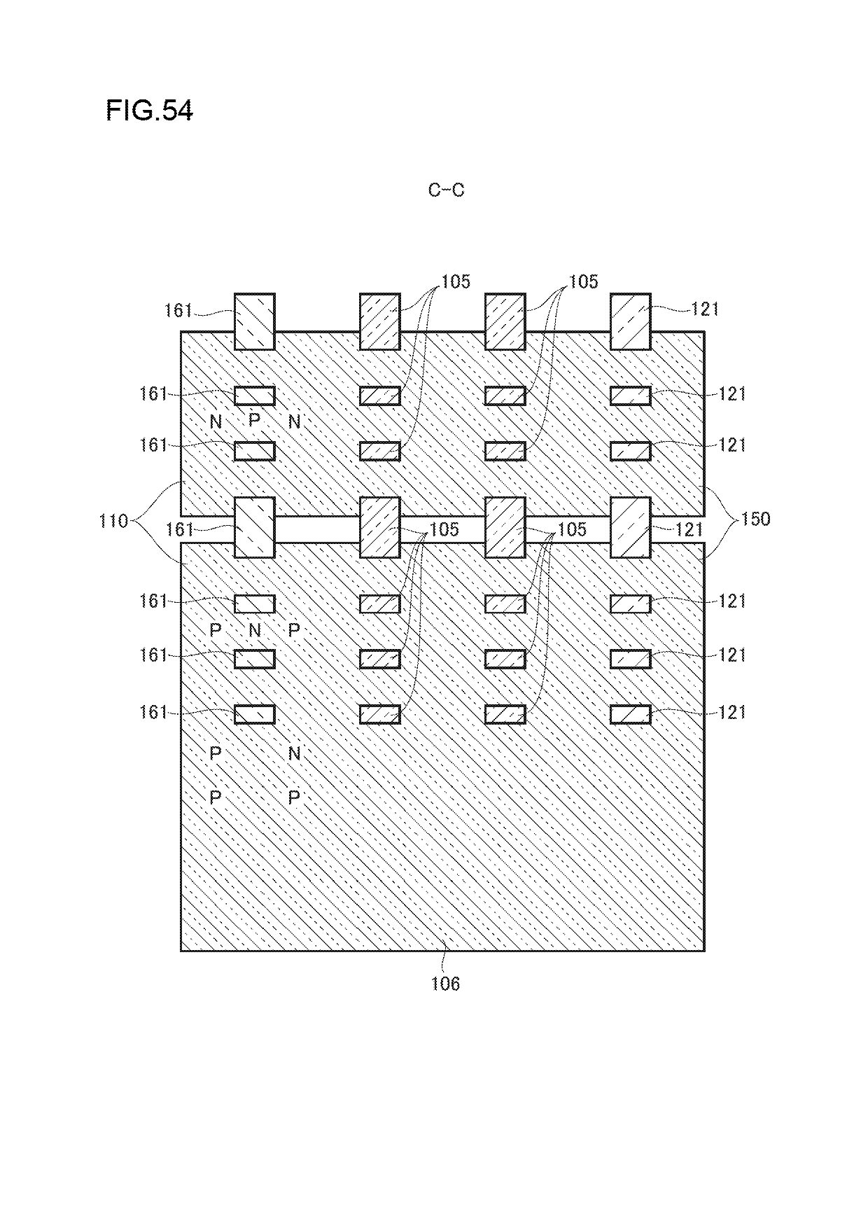

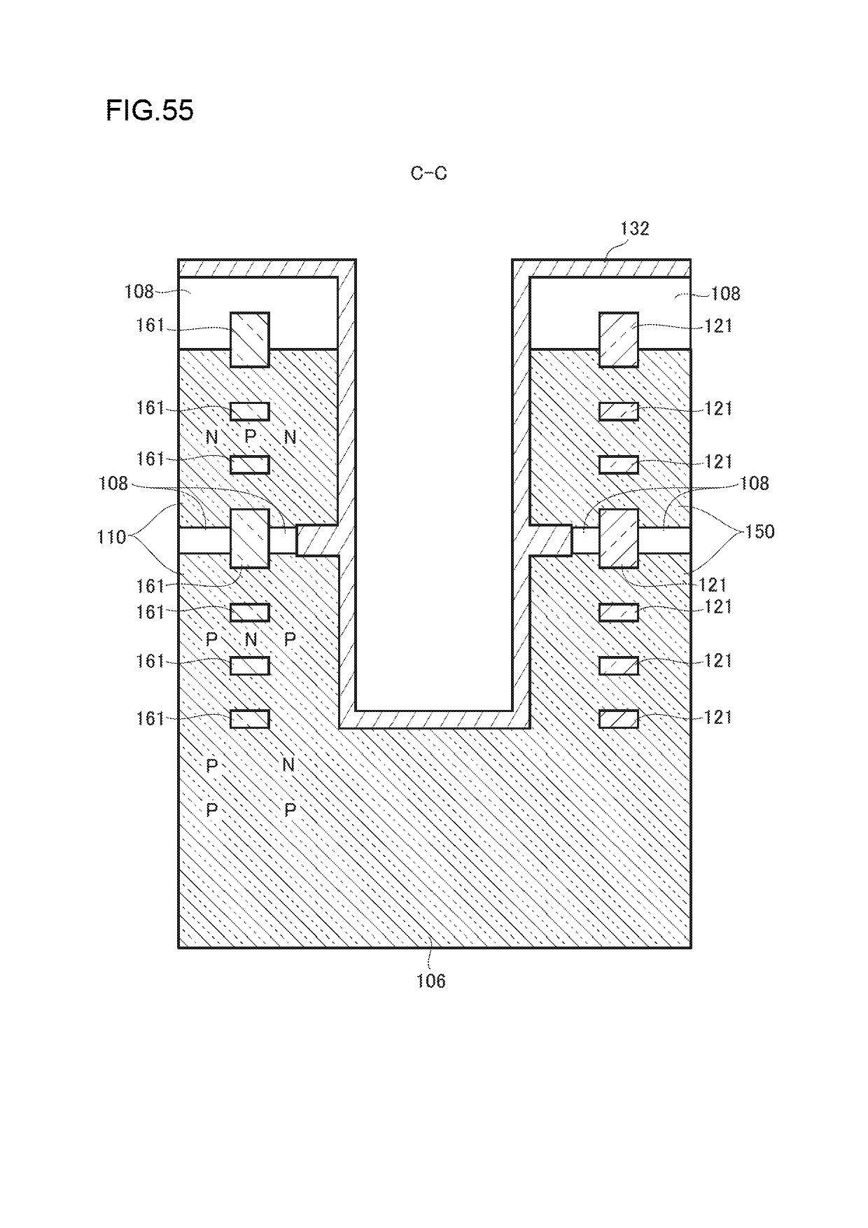

FIGS. 54 and 55 illustrate manufacturing process diagrams of the SRAM cell 200.

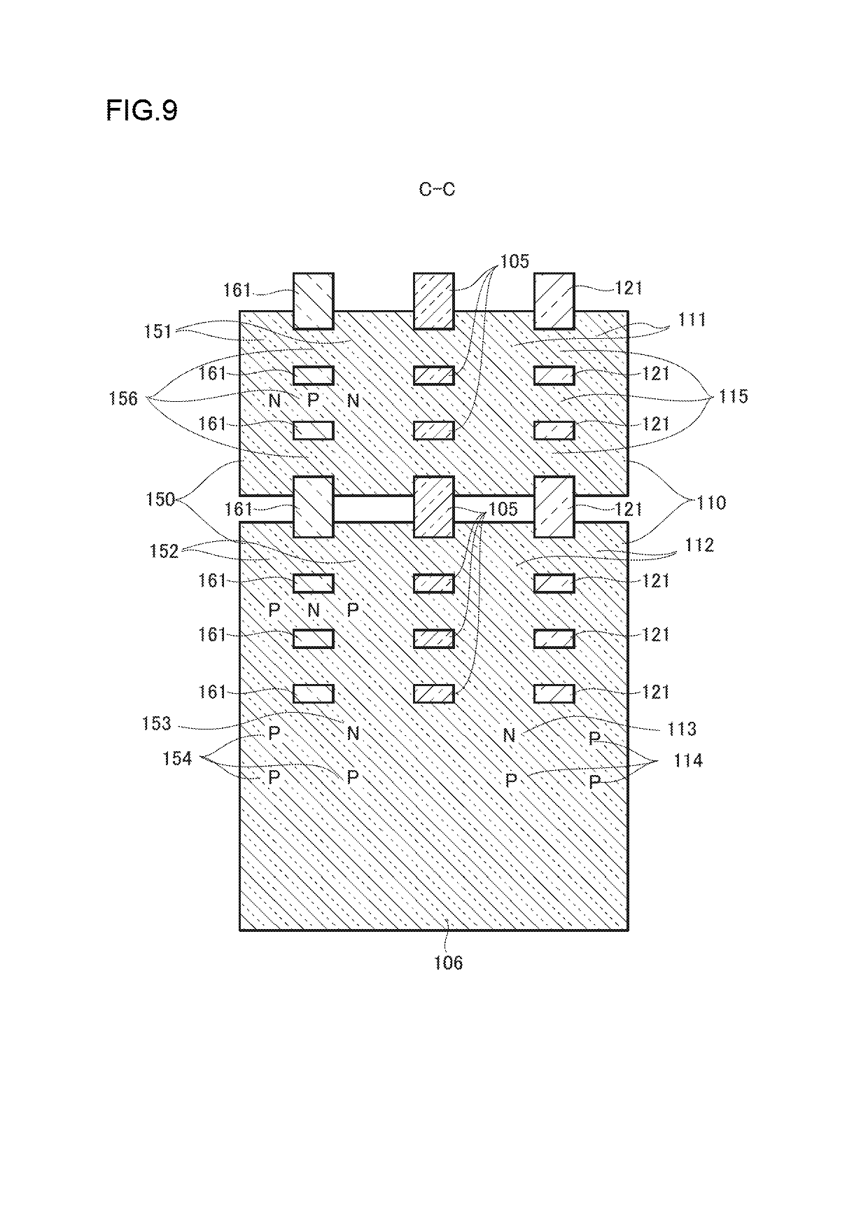

FIG. 54 is a cross-sectional view of the SRAM cell 200 illustrated in FIG. 50 taken along line C-C, and corresponds to FIG. 9 of the manufacturing process of the SRAM cell 100 of the first embodiment. FIG. 55 is a cross-sectional view of the SRAM cell 200 illustrated in FIG. 50 taken along line C-C, and corresponds to FIG. 13 of the manufacturing process of the SRAM cell 100 of the first embodiment.

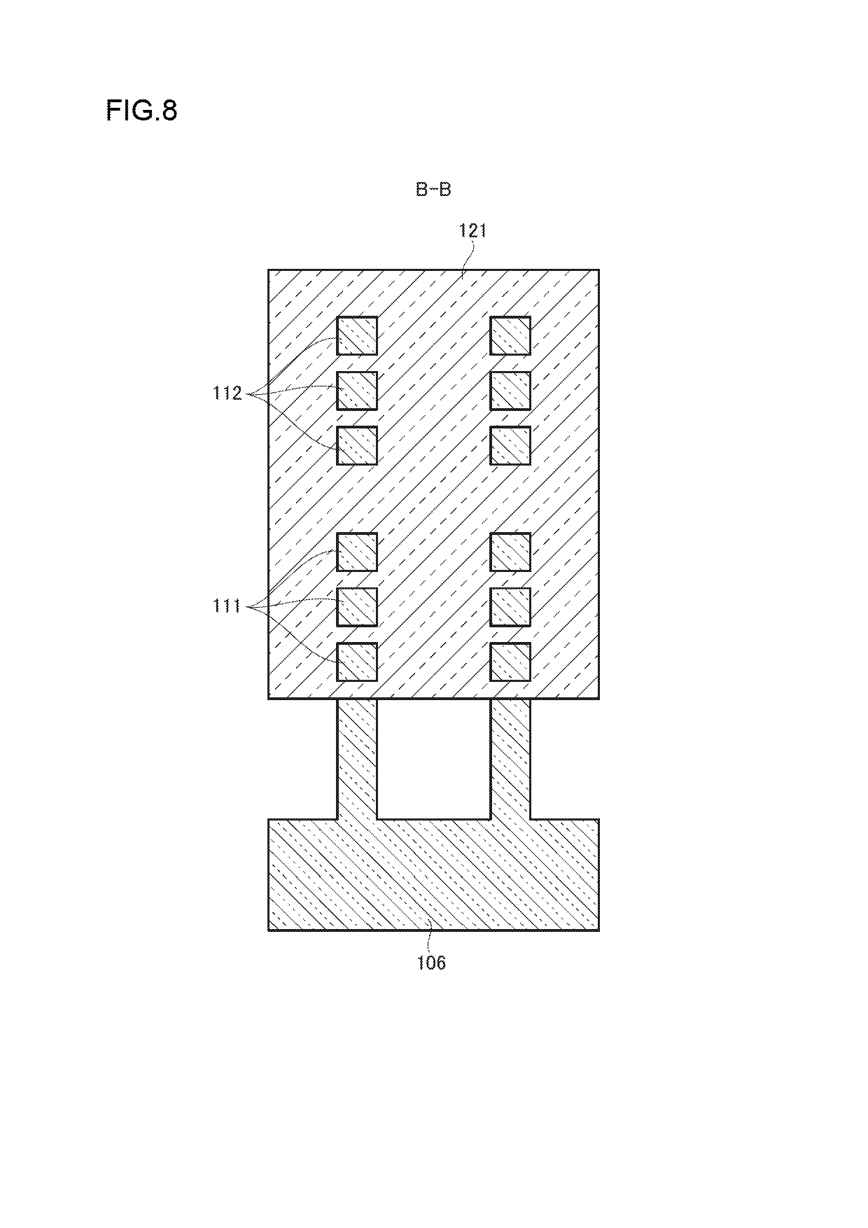

Note that, in the steps illustrated in FIGS. 54 and 55, the cross-sectional views of the SRAM cell 200 taken along line A-A and line B-B are similar to those in FIGS. 7 and 8.

First, as illustrated in FIG. 54, the semiconductor layer 110, 150 having a CFET structure in which two nanosheet transistors having a GAA-FET structure are stacked in a vertical direction and a dummy gate 105, 121, 161 are formed using a known method. At this time, two columns of dummy gates 105 are formed between the semiconductor layer 110 and the semiconductor layer 150, that is, between the dummy gate 121 and the dummy gate 161.

Next, as illustrated in FIG. 55, an insulating layer 108 is formed, and then the dummy gate 105 for two rows and a semiconductor layer between the layers of the dummy gates 105 are removed and dug to form element isolation between the semiconductor layer 110 and the semiconductor layer 150. Then, a Ti/TiN layer 132 is formed on the entire surface. As a result, the Ti/TiN layer 132 is formed on an upper surface of the insulating layer 108, and a side surface and a bottom surface of the element isolation region between the semiconductor layer 110 and the semiconductor layer 150. By removing the dummy gates 105 for two columns and the semiconductor layer between the layers of the dummy gates 105, an element isolation region between the semiconductor layer 110 and the semiconductor layer 150 is widened. Therefore, the FET contact 130, 170 for connecting the P-type semiconductor layer 112, 152 and the N-type semiconductor layer 111, 151 can be formed on side surfaces of the semiconductor layer 110 and the semiconductor layer 150. As a result, it is not necessary to form a PN junction contact between the P-type semiconductor layer 112, 152 and the N-type semiconductor layer 111, 151.

Thereafter, by performing similar steps to those in the first embodiment described above, the SRAM cell 200 can be manufactured.

5. Semiconductor device of third embodiment

Next, a third embodiment of the semiconductor device will be described. The semiconductor device of the third embodiment described below partially has a similar structure to the semiconductor device of the first embodiment described above. Therefore, description of the similar structure to that of the semiconductor device of the first embodiment described above is omitted.

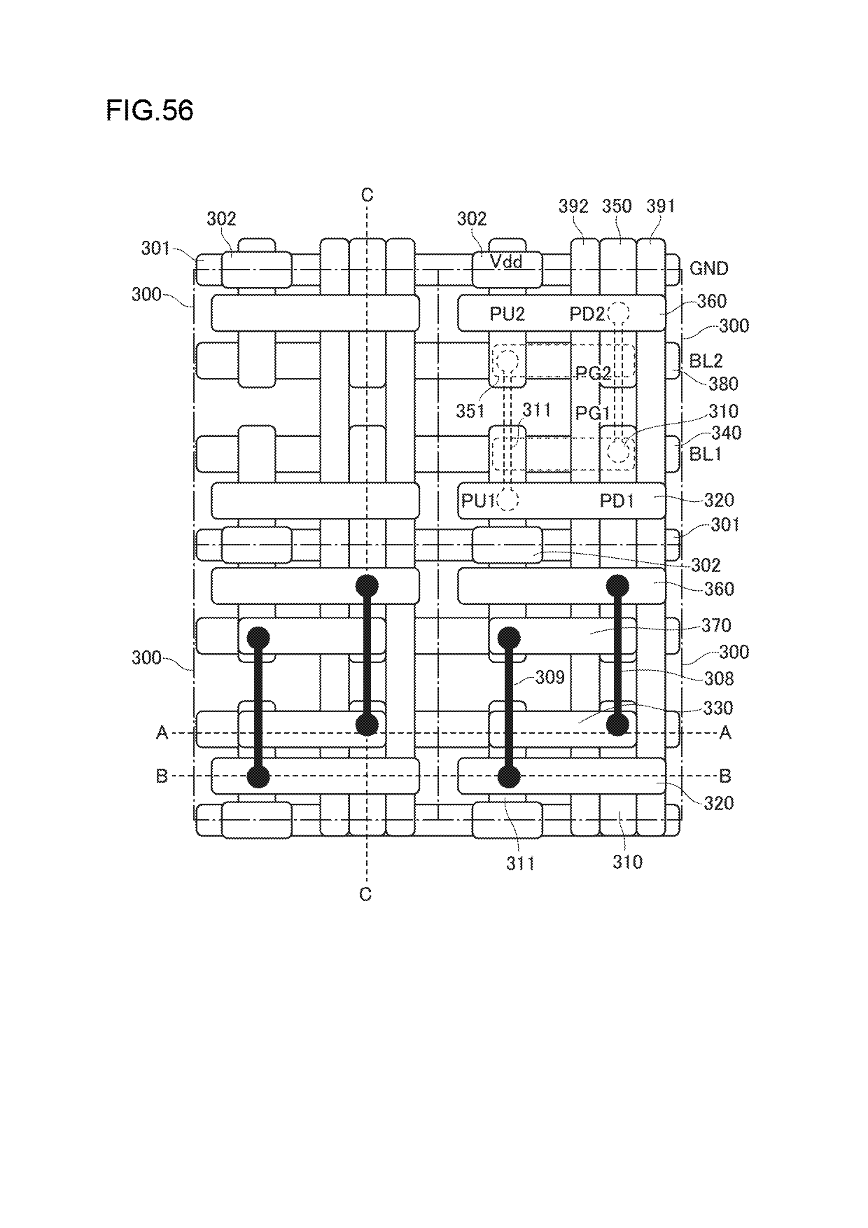

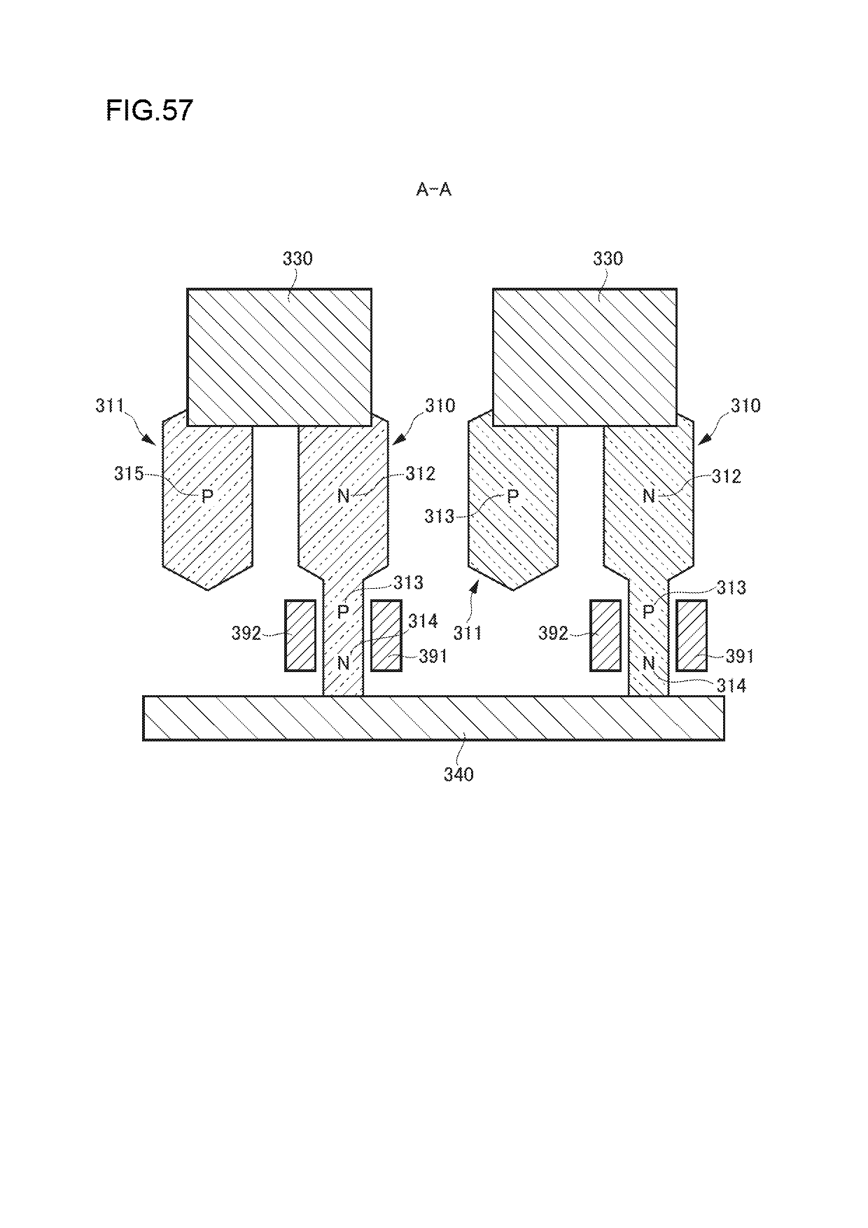

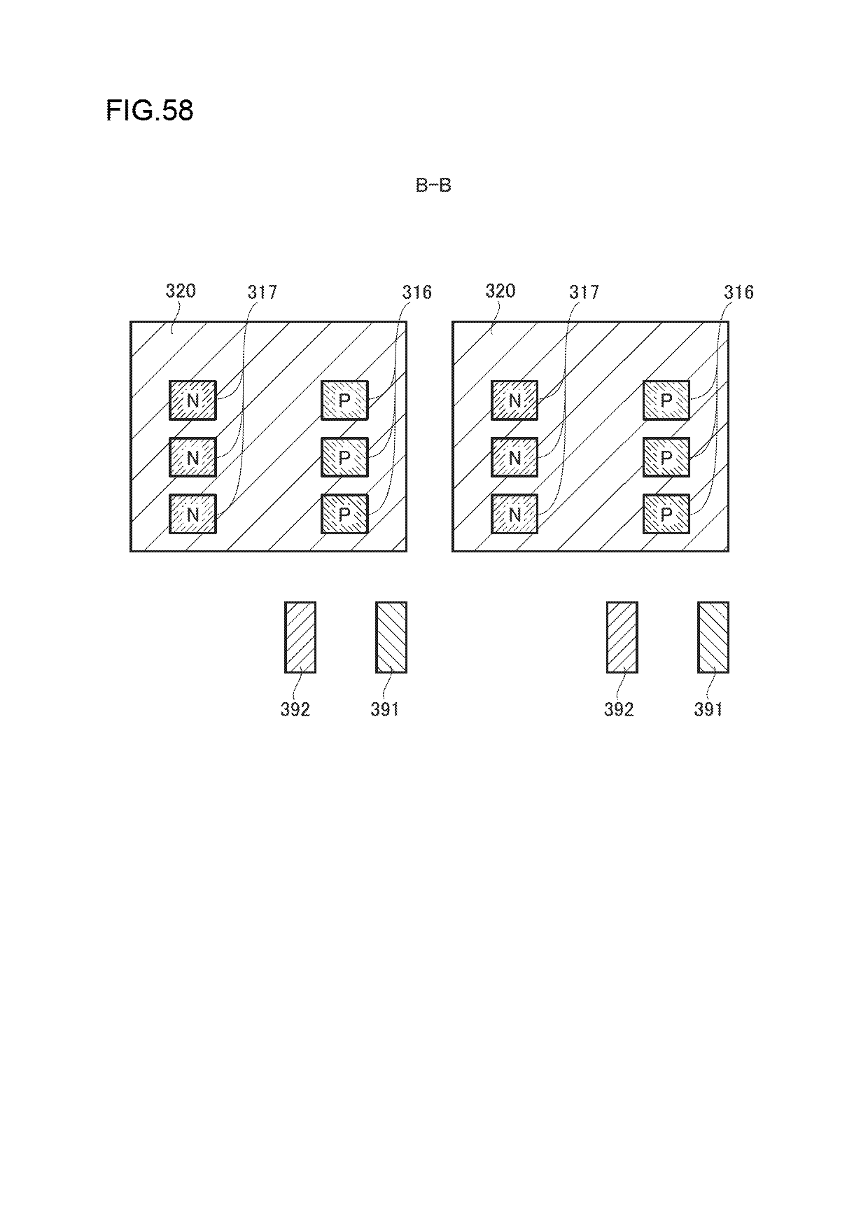

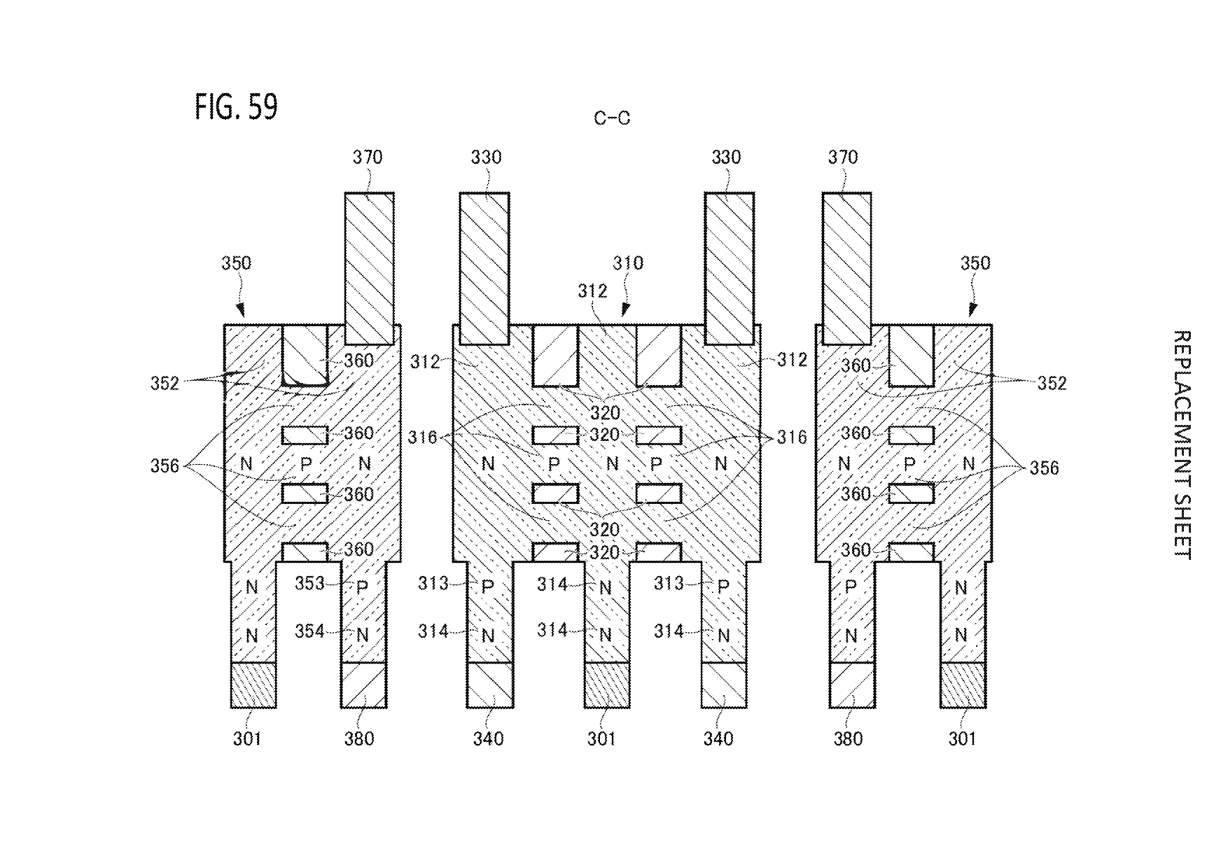

FIGS. 56 to 59 illustrate a structure of a semiconductor memory element (SRAM cell) including six transistors (6Tr) as an example of the semiconductor device. FIG. 56 is a plan layout view (top view) of the semiconductor memory element. FIG. 57 is a cross-sectional view taken along line A-A of the semiconductor memory element illustrated in FIG. 56. FIG. 58 is a cross-sectional view taken along line B-B of the semiconductor memory element illustrated in FIG. 57. FIG. 59 is a cross-sectional view taken along line C-C of the semiconductor memory element illustrated in FIG. 56.

The SRAM cell 100, 200 exemplified in the first embodiment and the second embodiment described above has a CFET structure in which two nanosheet transistors having a GAA-FET structure are stacked in a vertical direction. On the other hand, an SRAM cell 300, which is an example of the semiconductor memory element of the third embodiment illustrated in FIGS. 56 to 59, has a structure in which a nanosheet transistor having a GAA-FET structure is not stacked and all transistors M1 to M4 are formed in a planar arrangement.

The plan layout view illustrated in FIG. 56 illustrates a state of four cells in which two rows of the SRAM cells 300 are arranged vertically and horizontally. In FIG. 56, each of regions indicated by alternate long and short dash lines corresponds to one SRAM cell 300. Note that, in FIG. 56, description of a PN junction contact 330, 370 and a wiring line 308, 309 formed on a semiconductor layer 350, 351, 353, 354 is omitted in the two SRAM cells 300 illustrated on an upper side.

As illustrated in FIG. 56, one cell SRAM cell 300 has a word line 391, 392 on a VDD 301 and has a bit line (BL1) 340 and a bit line (BL2) 380 on the word line 391, 392. There is a semiconductor layer 310, 311, 350, 351 on the bit line (BL1, BL2)340, 380. The semiconductor layer 310, 311, 350, 351 is a diffusion layer for forming six transistors M1, M2, M3, M4, M5, and M6, and a channel, a source/drain, and the like of each of the transistors are formed in the semiconductor layer 310, 311, 350, 351. The semiconductor layer 310 is a diffusion layer for forming the transistor M1, M5. The semiconductor layer 311 is a diffusion layer for forming the transistor M3. The semiconductor layer 350 is a diffusion layer for forming the transistor M2, M6. The semiconductor layer 351 is a diffusion layer for forming the transistor M4.

A gate electrode 320, 360 of the transistor M1, M2, M3, M4 is formed on the semiconductor layer 310, 311, 350, 351. The gate electrode 320 forms the transistor M1, M3, and the gate electrode 360 forms the transistor M2, M4.

In addition, there is a PN junction contact 330, 370 of the transistor M1, M2, M3, M4, M5, M6 on the semiconductor layer 310, 311, 350, 351. That is, the transistor M1 (PD1) is formed by the gate electrode 320 and the semiconductor layer 310. The transistor M3 (PU1) is formed by the gate electrode 320 and the semiconductor layer 311. The transistor M2 (PD2) is formed by the gate electrode 360 and the semiconductor layer 350. The transistor M4 (PU2) is formed by the gate electrode 360 and the semiconductor layer 351.

There is a wiring line 308, 309 for connecting a first inverter and a second inverter on the gate electrode 320, 360 and the PN junction contact 330, 370.

As illustrated in FIG. 57, in the cross-sectional view taken along line A-A in FIG. 56, the semiconductor layer 310, 311 is formed on the first bit line 340. The semiconductor layer 310 includes an N-type semiconductor layer 314, a P-type semiconductor layer 313, and an N-type semiconductor layer 312 from the first bit line 340 side. Each of the N-type semiconductor layer 314 and the P-type semiconductor layer 313 is formed in a region narrower than the N-type semiconductor layer 312. The semiconductor layer 311 has a P-type semiconductor layer 315. The P-type semiconductor layer 315 is formed so as to have the same width as the N-type semiconductor layer 312 of the semiconductor layer 310. The P-type semiconductor layer 315 is separated from the first bit line 340.

A word line 391, 392 is disposed on side surfaces of the N-type semiconductor layer 314 and the P-type semiconductor layer 313 of the semiconductor layer 310. Therefore, the transistor M5 (PG1) is formed by the N-type semiconductor layer 314, the P-type semiconductor layer 313, the N-type semiconductor layer 312, and the word line 391, 392. That is, the word line 391, 392 functions as a gate electrode of the transistor M5.

As illustrated in FIG. 57, the transistor M5 to be PG1 is a vertical MOSFET. The N-type semiconductor layer 314 and the N-type semiconductor layer 312 are source/drain regions, and the P-type semiconductor layer 313 is a channel region. Therefore, the transistor M5 is an N-channel MOS. Note that the transistor M6 to be PG2 also has a vertical N-channel MOS structure similar to the transistor M5 illustrated in FIG. 57.

The N-type semiconductor layer 312 is a source/drain region constituting the transistor M1 to be PD1. The P-type semiconductor layer 315 is a source/drain region constituting the transistor M3 to be PU1.

There is the PN junction contact 330 between the N-type semiconductor layer 312 which is a source/drain region of the transistor M1 and the P-type semiconductor layer 315 which is a source/drain region of the transistor M3.

As illustrated in FIG. 58, in the cross-sectional view taken along line B-B in FIG. 56, there are three P-type semiconductor layers 316, three N-type semiconductor layers 317, and the gate electrode 320 formed around and between these semiconductor layers. The three P-type semiconductor layers 316 are channel regions of the transistor M1 to be PD1. The three N-type semiconductor layers 317 are channel regions of the transistor M3 to be PU1.

The three P-type semiconductor layers 316 and the three N-type semiconductor layers 317 to be channel regions are constituted by nanosheet layers. The entire side surfaces of the three P-type semiconductor layers 316 and the three N-type semiconductor layers 317 to be channel regions constituted by nanosheet layers in a gate width direction are surrounded by the gate electrode 320 via a gate insulating film (not illustrated).

That is, the transistor M1 to be PD1 and the transistor M3 to be PU1 are GAA-FETs. The transistor M2 to be PD2 and the transistor M4 to be PU2 are also GAA-FETs having a similar structure to the transistor M1, M3 illustrated in FIG. 58.

The word line 391, 392 is disposed above the gate electrode 320.

As illustrated in FIG. 59, in the cross-sectional view taken along line C-C in FIG. 56, the first bit line 340 and the VDD 301 are formed under the semiconductor layer 310. The second bit line 380 and the VDD 301 are formed under the semiconductor layer 350. The PN junction contact 330 is formed on the semiconductor layer 310. The PN junction contact 370 is formed on the semiconductor layer 150.

The semiconductor layer 310 includes the N-type semiconductor layer 314, the P-type semiconductor layer 313, and the N-type semiconductor layer 312 above the first bit line 340. The semiconductor layer 310 includes the N-type semiconductor layer 314 above the VDD 301.

In the semiconductor layer 310, the gate electrode 320 and the P-type semiconductor layer 316 are stacked. In FIG. 59, three P-type semiconductor layers 316 and four gate electrodes 320 are formed. An uppermost surface and a lowermost surface of the stack of the P-type semiconductor layer 316 and the gate electrode 320 are formed by the gate electrodes 320.

Furthermore, the semiconductor layer 310 includes the N-type semiconductor layer 312 on a side surface of the stack of the P-type semiconductor layer 316 and the gate electrode 320 and above the N-type semiconductor layer 314 and the P-type semiconductor layer 313.

In the semiconductor layer 310, the transistor M1 to be PD1 is formed by the gate electrode 320, the three P-type semiconductor layers 316, and the N-type semiconductor layer 312. The three P-type semiconductor layers 316 are channel regions, and the N-type semiconductor layer 312 formed on both side surfaces of the three P-type semiconductor layers 316 is a source/drain region.

The PN junction contact 330 is disposed above one of the N-type semiconductor layers 312 which are source/drain regions of the transistor M1 to be PD1.

The semiconductor layer 350 includes the N-type semiconductor layer 354, the P-type semiconductor layer 353, and the N-type semiconductor layer 352 above the second bit line 380.

In the semiconductor layer 350, the gate electrode 360 and the P-type semiconductor layer 356 are stacked. In FIG. 59, three P-type semiconductor layers 356 are formed, and four gate electrodes 360 are formed. An uppermost surface and a lowermost surface of the stack of the P-type semiconductor layer 356 and the gate electrode 360 are formed by the gate electrodes 360.

Furthermore, the semiconductor layer 350 includes the N-type semiconductor layer 352 on a side surface of the stack of the P-type semiconductor layer 356 and the gate electrode 360 and above the P-type semiconductor layer 353 and the N-type semiconductor layer 354.

In the semiconductor layer 350, the transistor M2 to be PD2 is formed by the gate electrode 360, the three P-type semiconductor layers 356, and the N-type semiconductor layer 352. The three P-type semiconductor layers 356 are channel regions, and the N-type semiconductor layer 352 formed on both side surfaces of the three P-type semiconductor layers 356 is a source/drain region.

The N-type semiconductor layer 352 which is a source/drain region of the transistor M2 to be PD2 and a P-type semiconductor layer (not illustrated) which is a source/drain region of the transistor M4 to be PU2 are connected by the PN junction contact 370.

6. Method for manufacturing semiconductor device of third embodiment

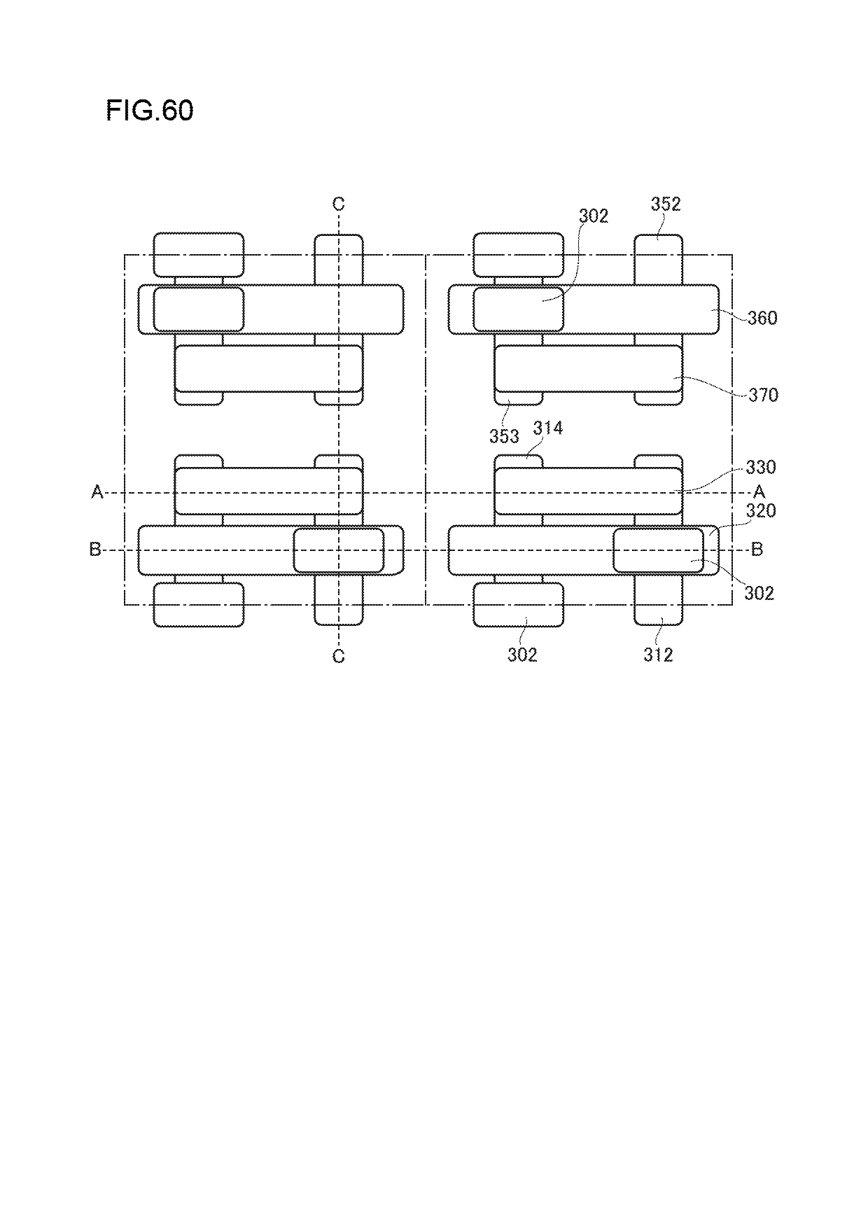

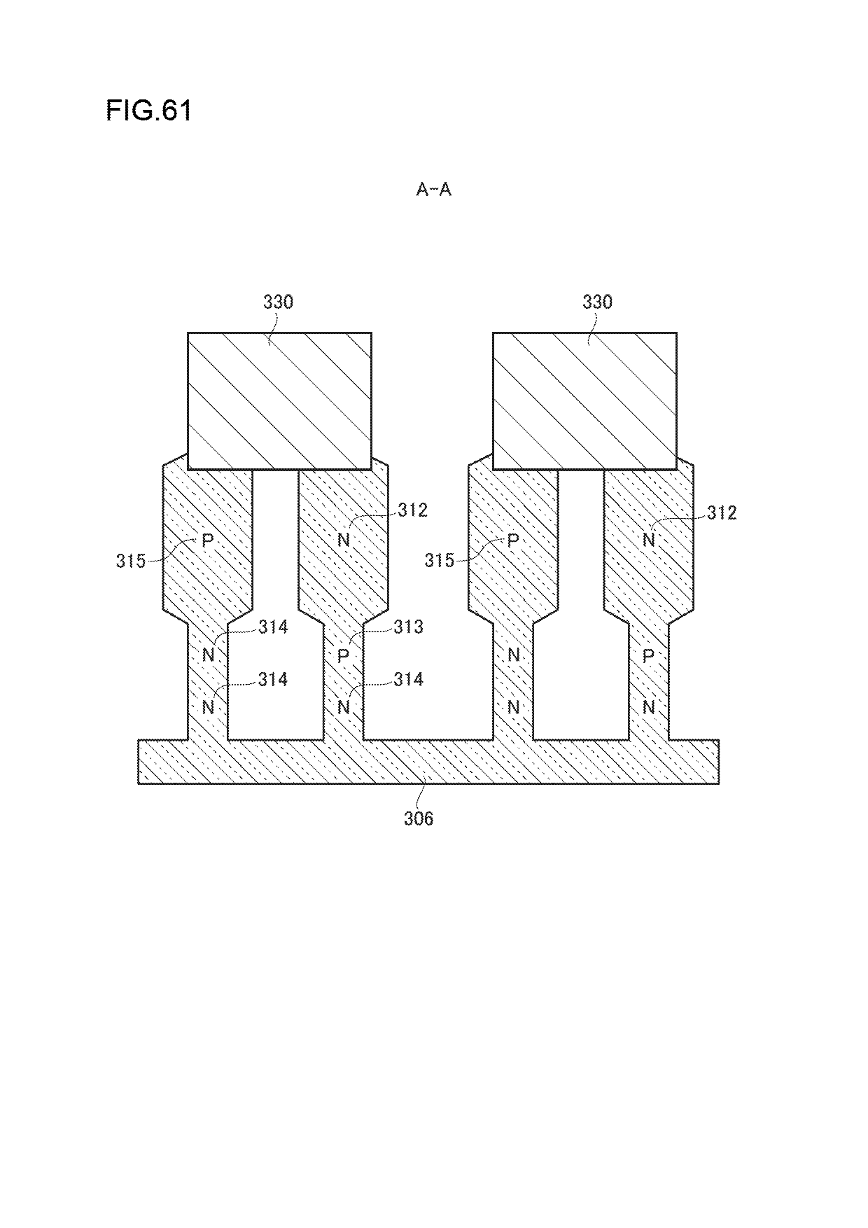

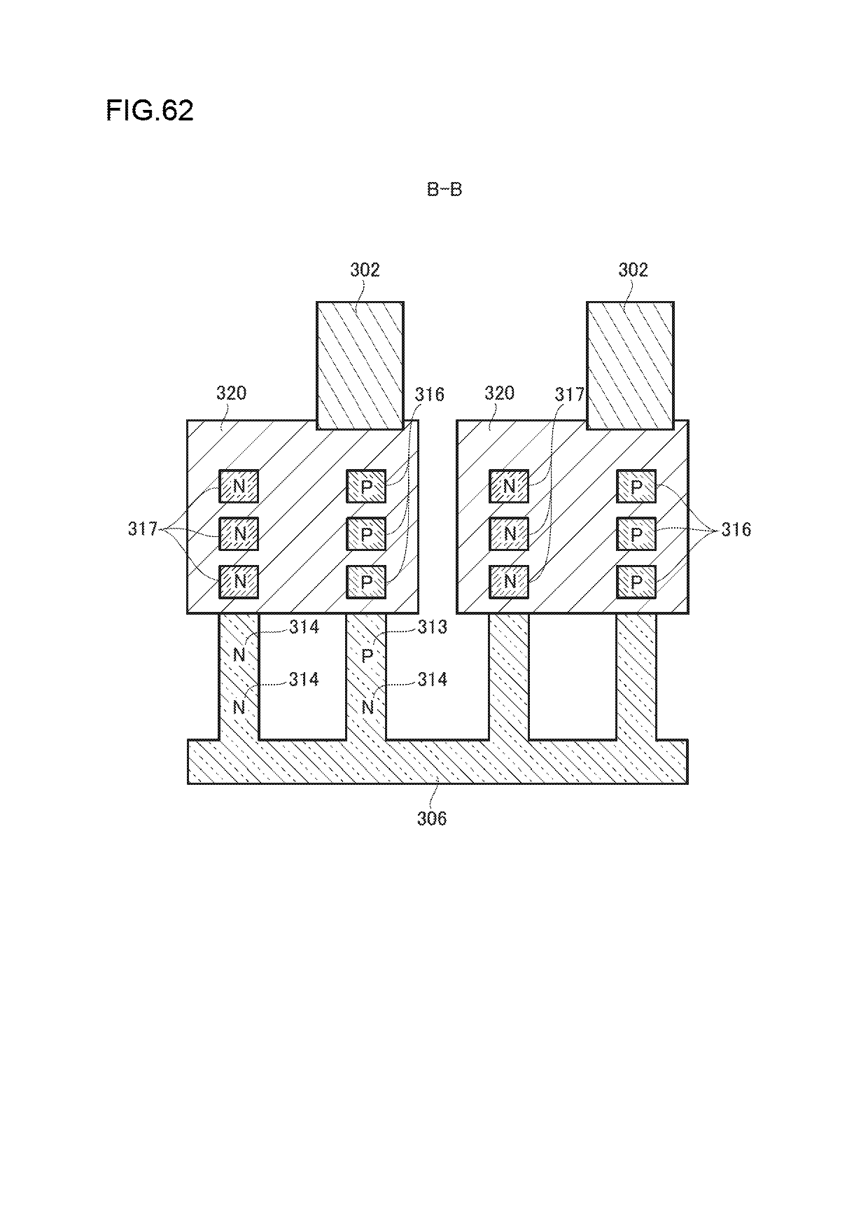

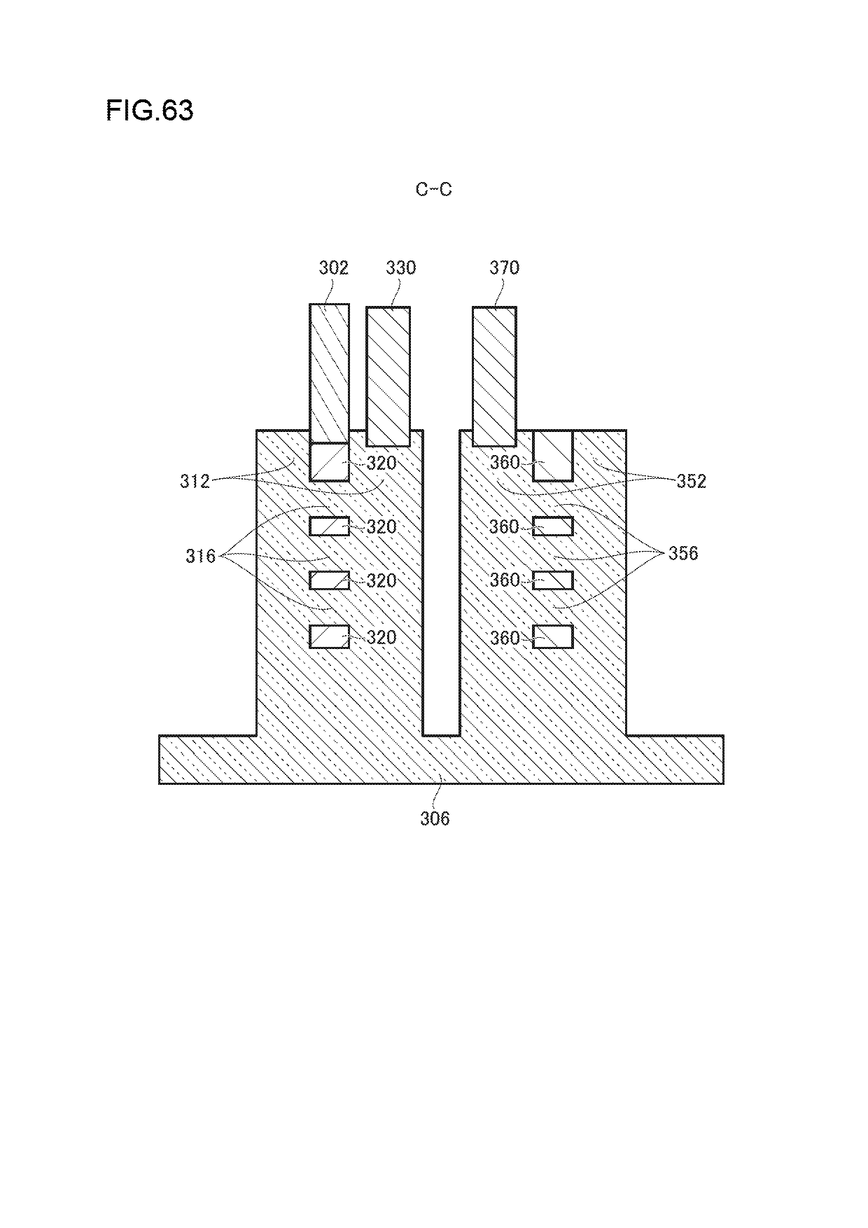

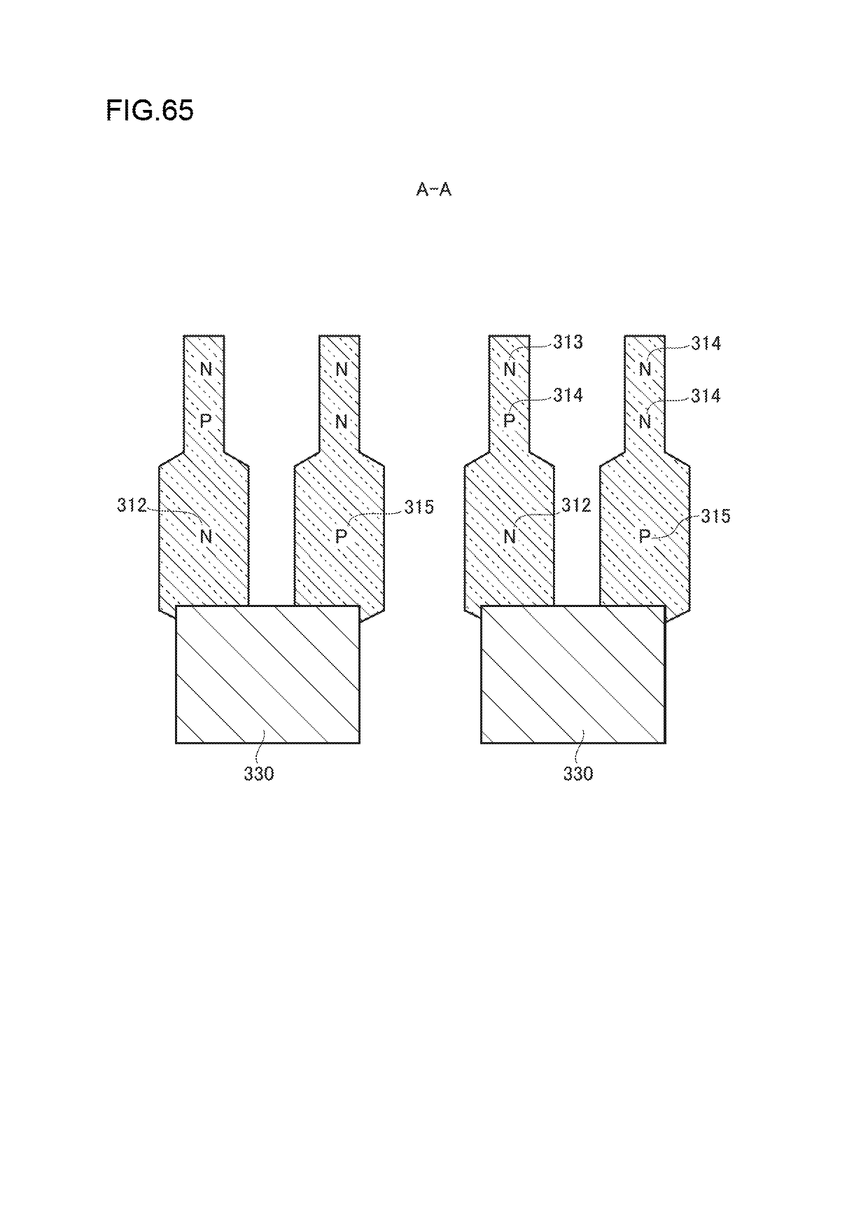

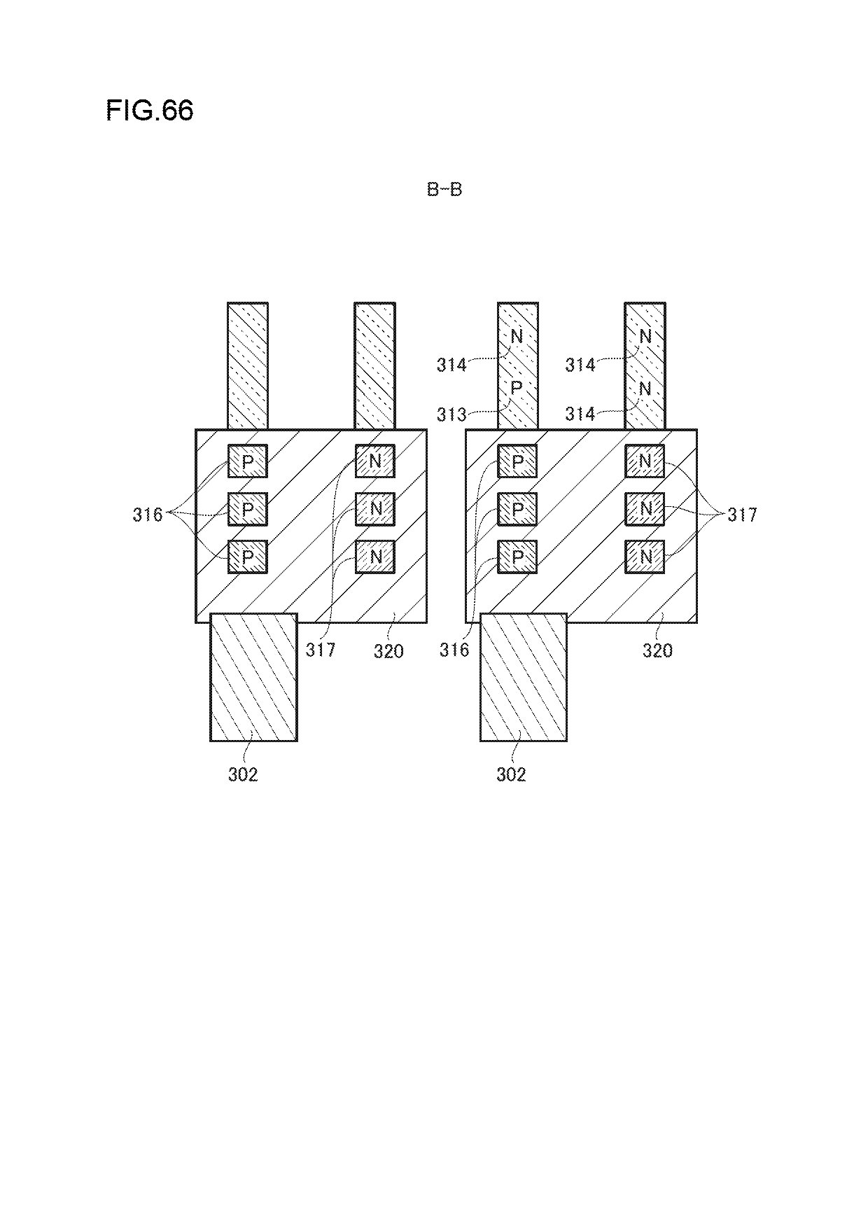

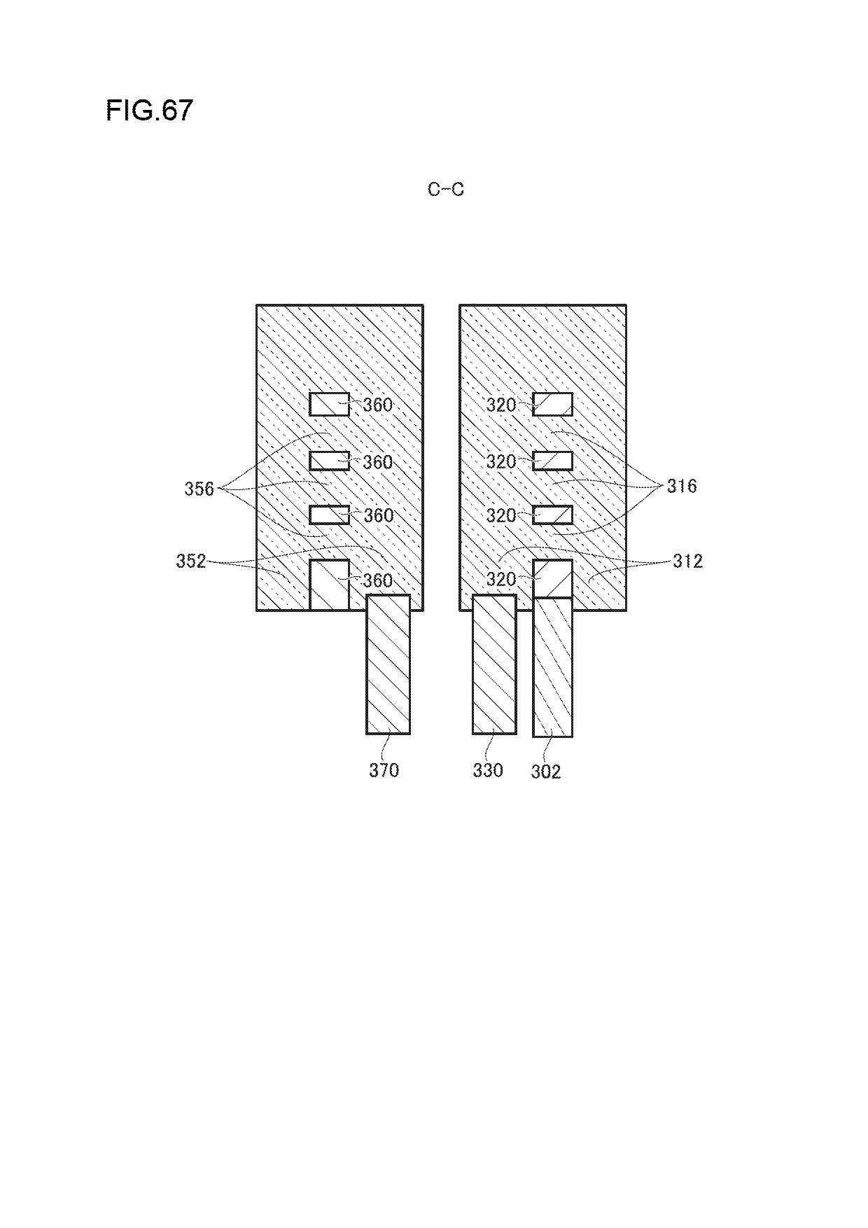

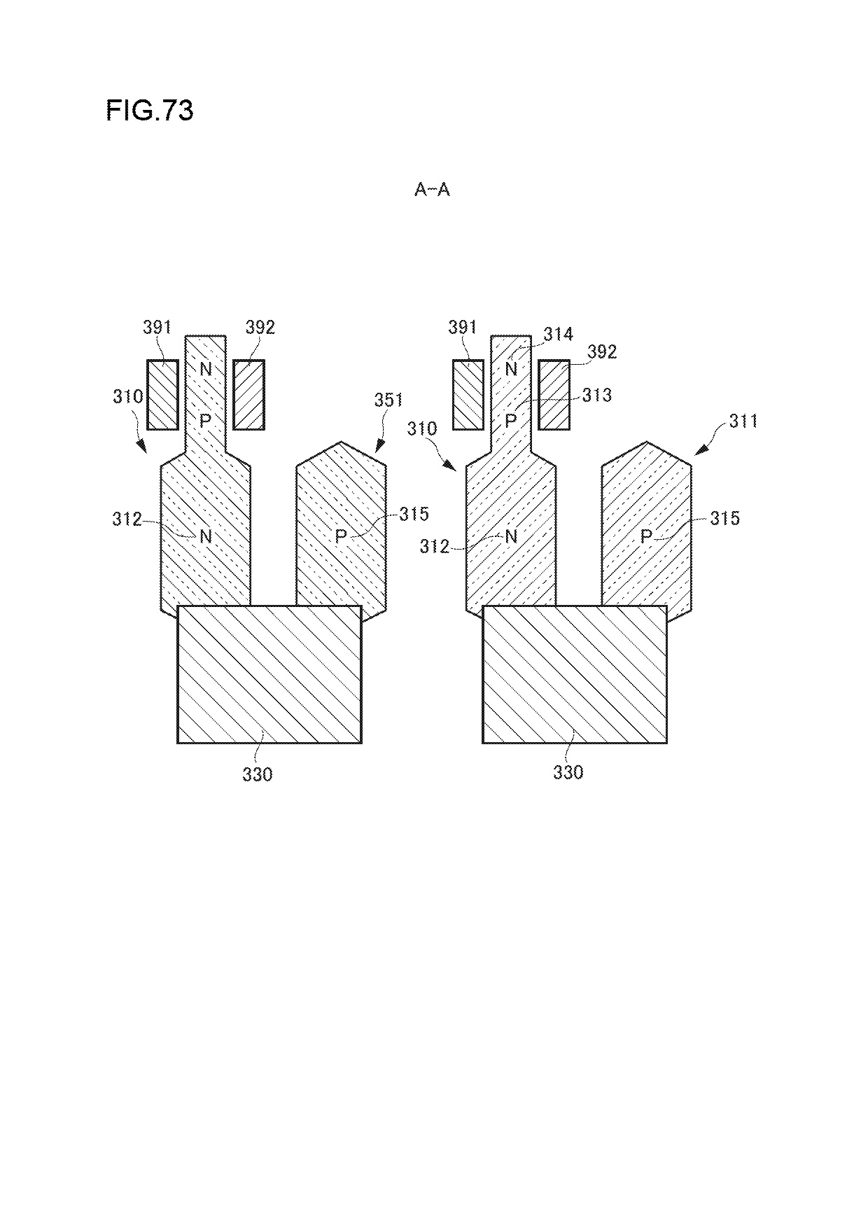

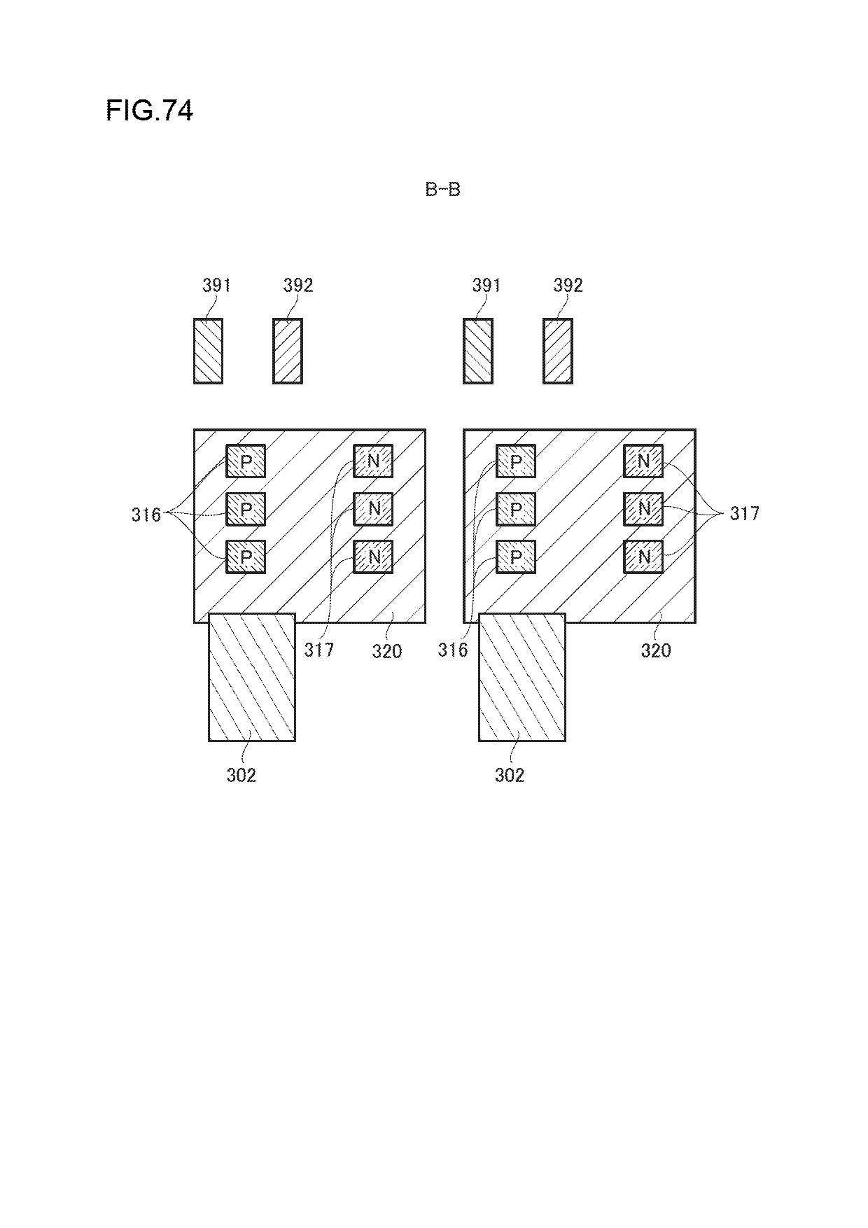

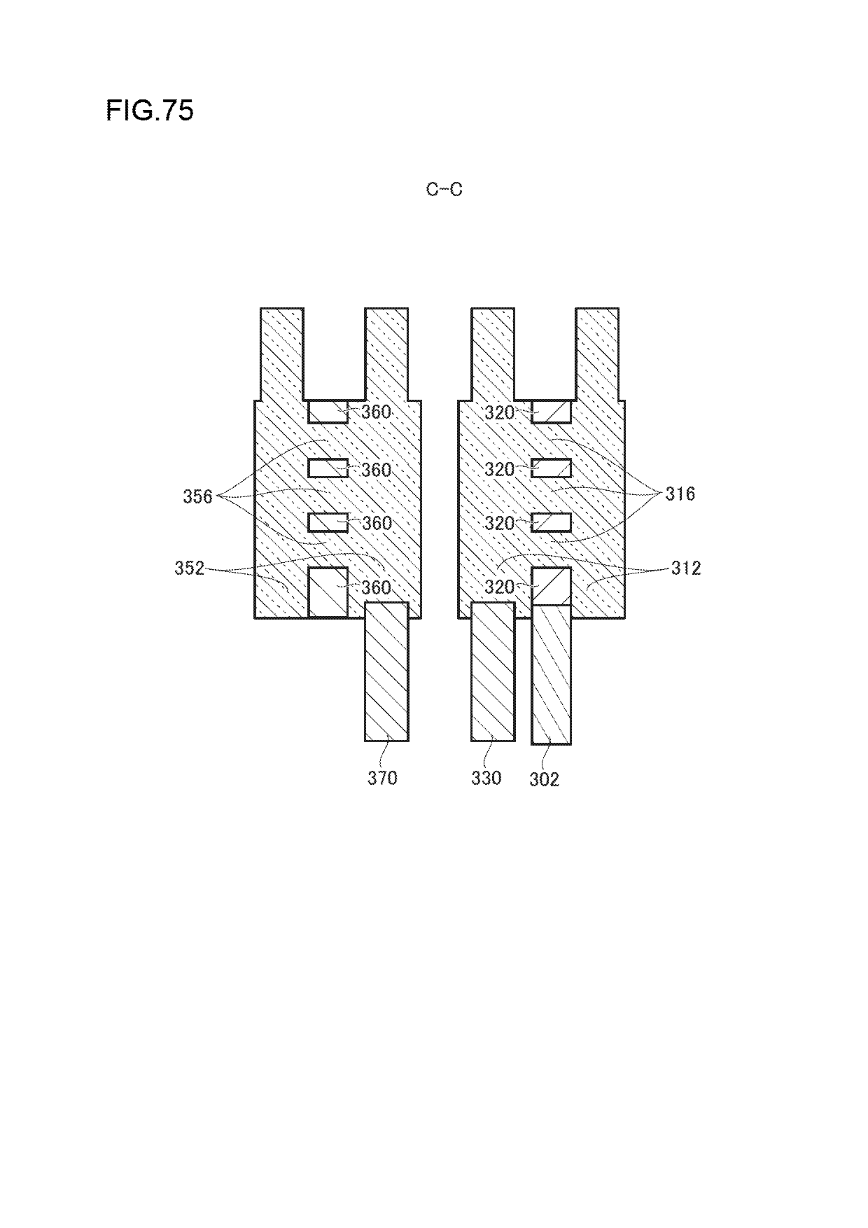

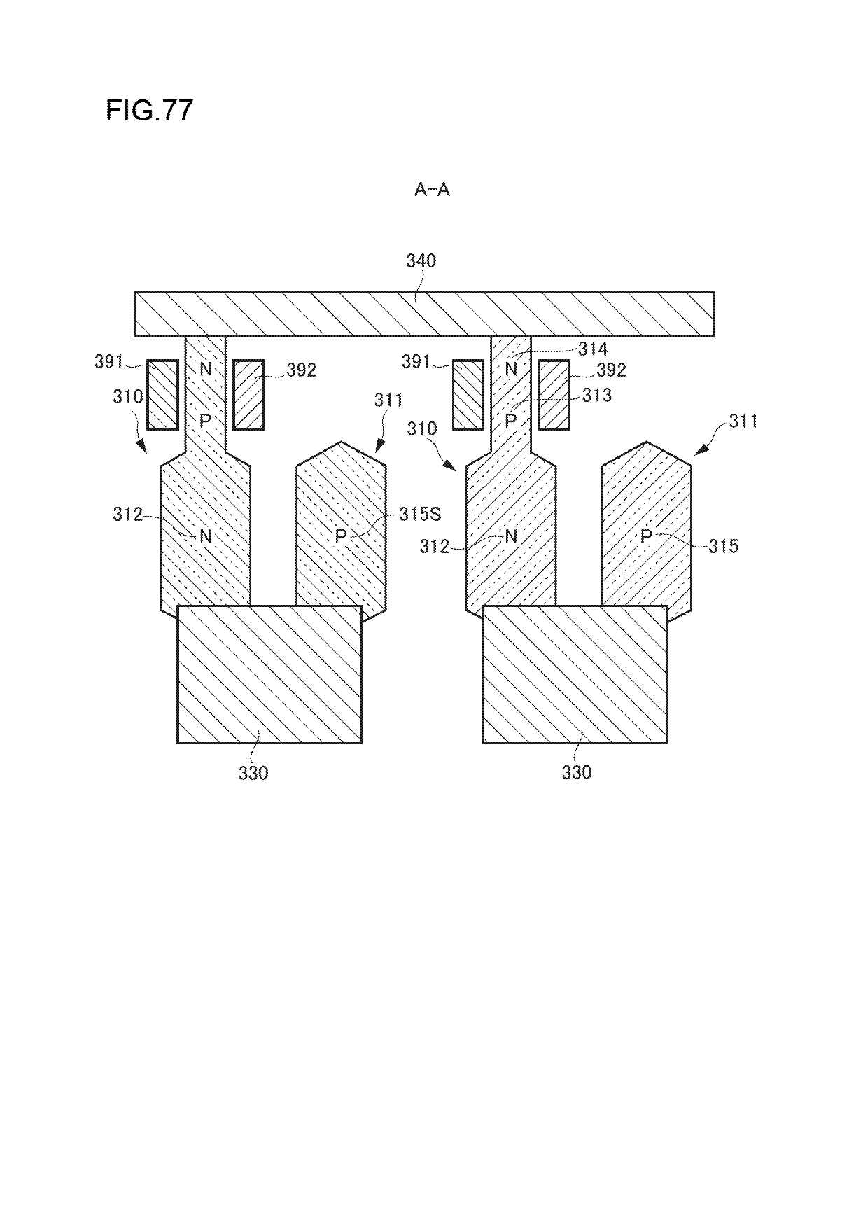

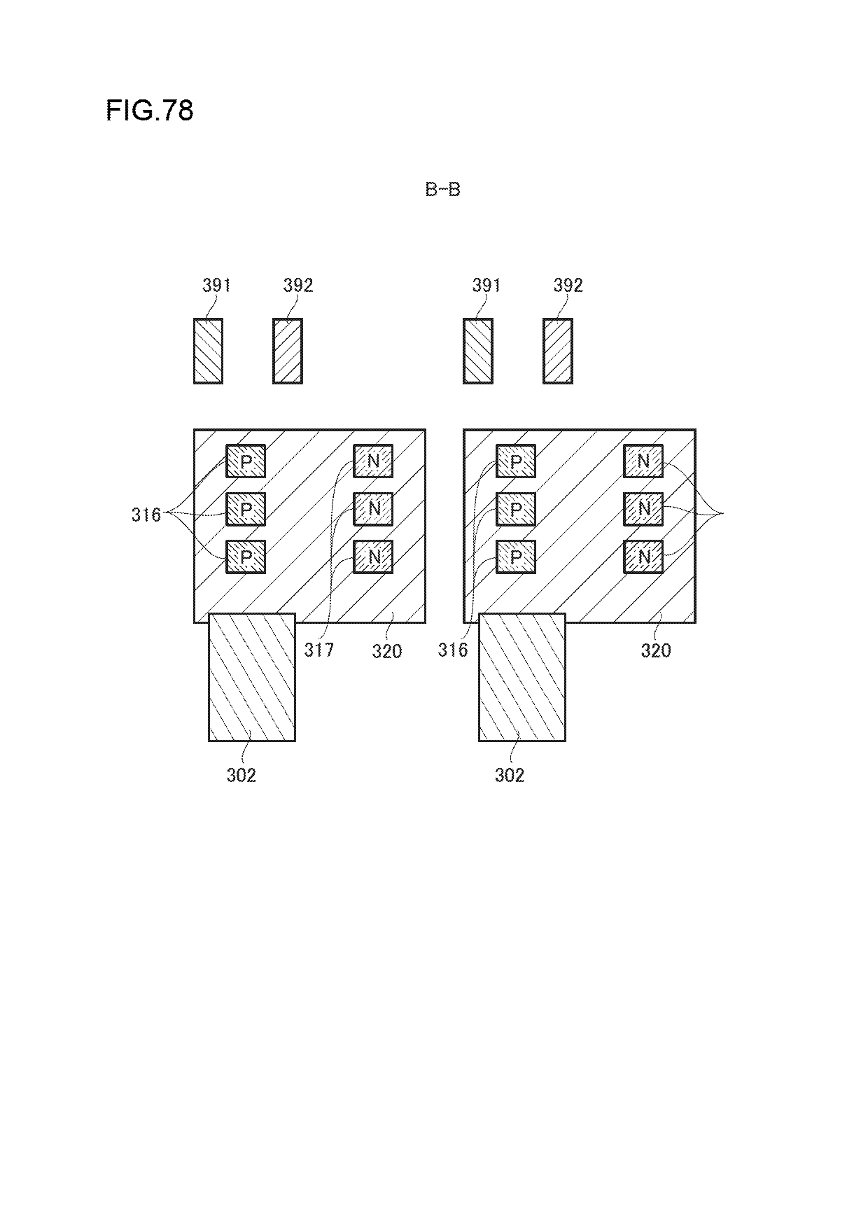

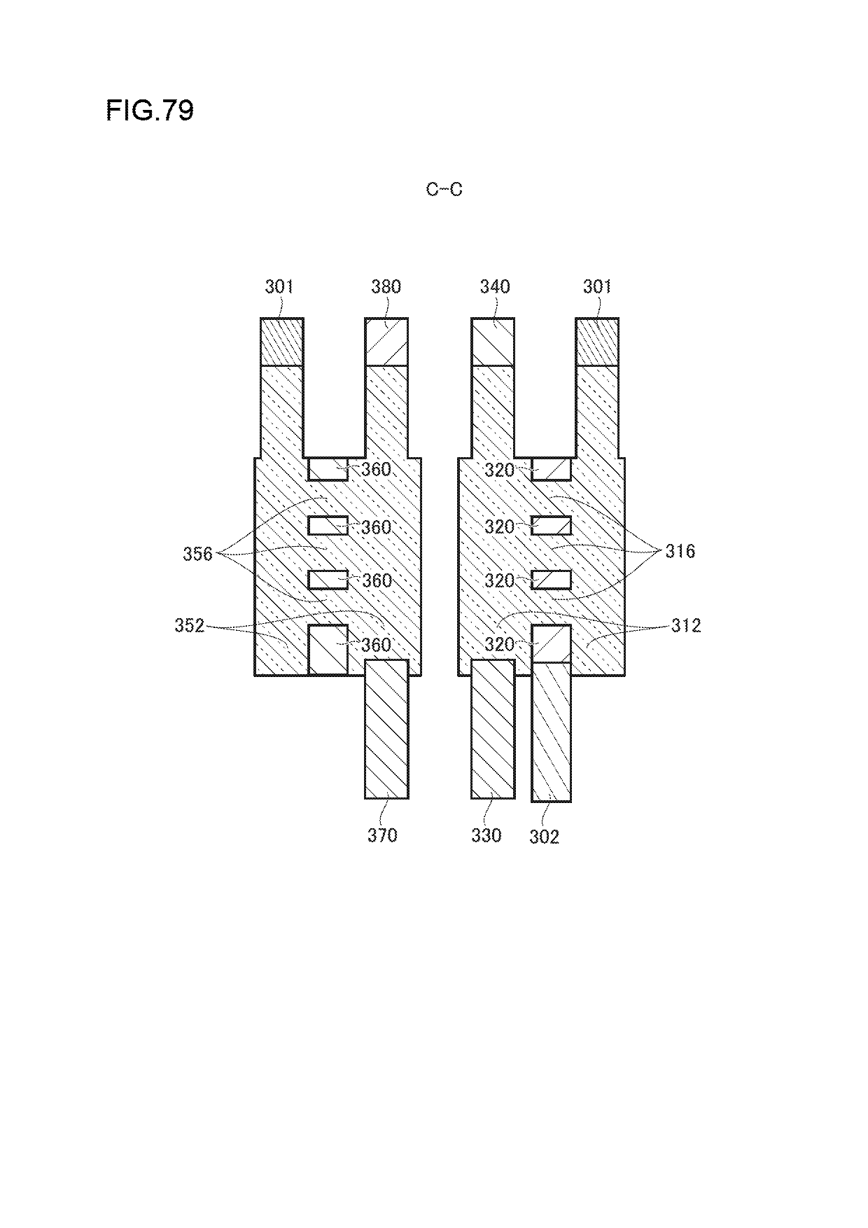

Next, a method for manufacturing the above-described SRAM cell 300 will be described. FIGS. 60 to 79 illustrate manufacturing process diagrams of the SRAM cell 100. In the process of manufacturing the SRAM cell 100 illustrated in FIGS. 60 to 79, similarly to FIGS. 2 to 5 described above, four diagrams consisting of a plan layout view, and a cross-sectional view taken along line A-A, a cross-sectional view taken along line B-B, and a cross-sectional view taken along line C-C in the plan layout view are illustrated for each step. Note that, to the method for manufacturing the SRAM cell 300, similar steps to those of the SRAM cell 100 of the first embodiment described above can be applied except for a part thereof. Therefore, in the method for manufacturing the SRAM cell 300, only steps different from those of the SRAM cell 100 of the first embodiment described above will be described. In the description of the method for manufacturing the SRAM cell 300, similar components to those in FIGS. 56 to 59 described above are denoted by the same reference numerals, and detailed description thereof is omitted.

First, as illustrated in FIGS. 60 to 63, the semiconductor layer 310, 311, 350, 351 which is a nanosheet transistor having a GAA-FET structure and the gate electrode 320, 360 are formed using a known method.

For example, first, N-type or P-type impurities are implanted into a region to be the transistor M5, M6 of a substrate 306 to form the P-type semiconductor layer 313, 353 and the N-type semiconductor layer 314, 354. Then, a stack of a SiGe layer and a Si layer is formed on the substrate 306 by epitaxial growth. In the structure of FIGS. 60 to 79, three SiGe layers and three Si layers are stacked. At this time, by implanting N-type or P-type impurities into the Si layer, the P-type semiconductor layer 316, 356 and the N-type semiconductor layer 317 to be channel regions are formed. Note that, as in the first embodiment, a Ge layer may be used instead of the Si layer.

Next, a patterned hard mask, a dummy gate, and the like are formed on the SiGe/Si stack, and the SiGe/Si stack is etched to form an SiGe/Si pillar. Furthermore, element isolation such as shallow trench isolator (STI) is formed on the substrate 306 in a region excluding the P-type semiconductor layer 313, 353 and the N-type semiconductor layer 314, 354 to be the transistor M5, M6.

A Si layer is formed on a side surface of the SiGe/Si stack by epitaxial growth. At this time, by implanting N-type or P-type impurities into the Si layer, the N-type semiconductor layer 312,352, the P-type semiconductor layer 315, and the like to be source/drain regions of the transistors M1 to M4 are formed.

The SiGe layer is selectively removed, and then TiN or the like is embedded in the region from which the SiGe layer has been removed to form the gate electrode 320, 360.

Then, an insulating layer is formed on the entire surface of the substrate 106. Thereafter, the gate electrode and the semiconductor layer formed between the gate electrode 320 and the gate electrode 360 are removed and dug to isolate the semiconductor layer 310 and the semiconductor layer 350 from each other.

Furthermore, the PN junction contact 330, 370 is formed on the semiconductor layer 310, 350. A VDD 302 is formed on the gate electrode 320, 360.

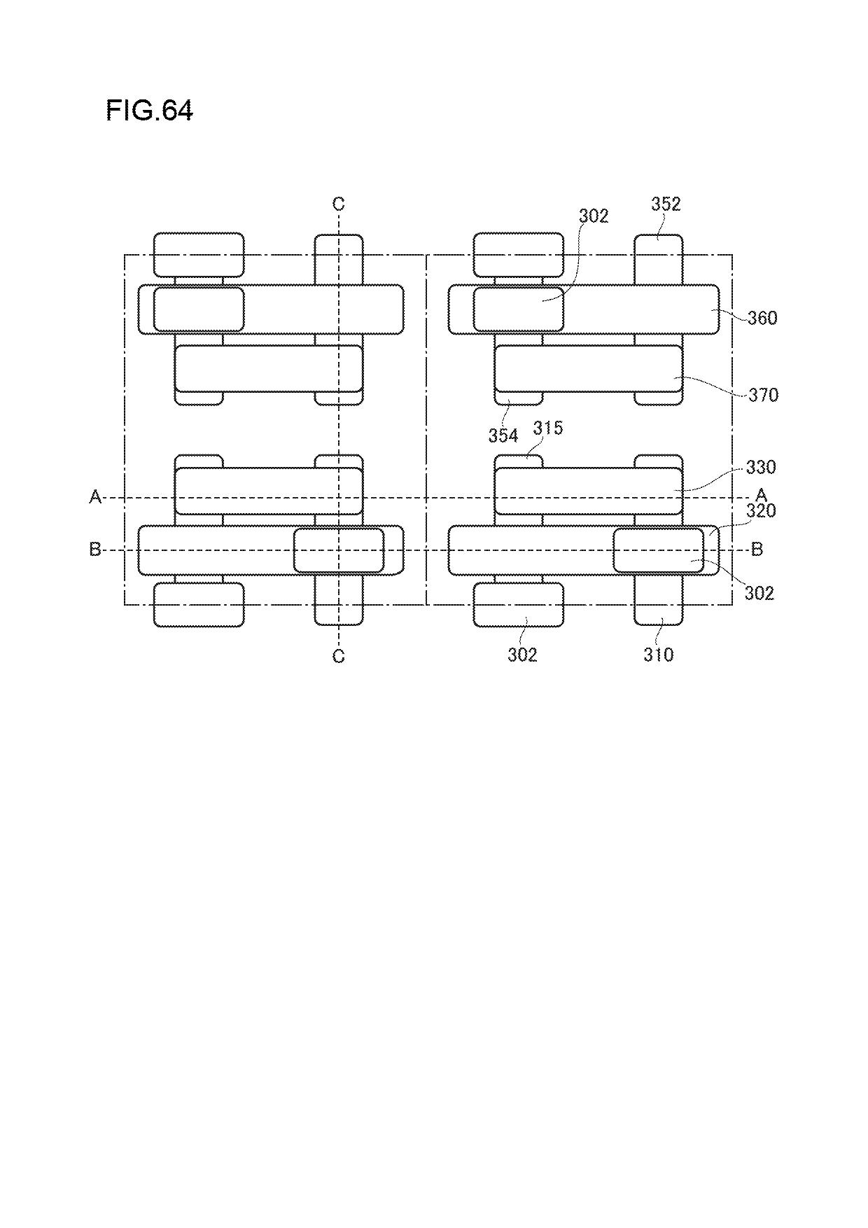

Next, as illustrated in FIGS. 64 to 67, the substrate 306 is turned upside down, and then the substrate 306 is removed. As a result, the N-type semiconductor layer 314, 354 is exposed.

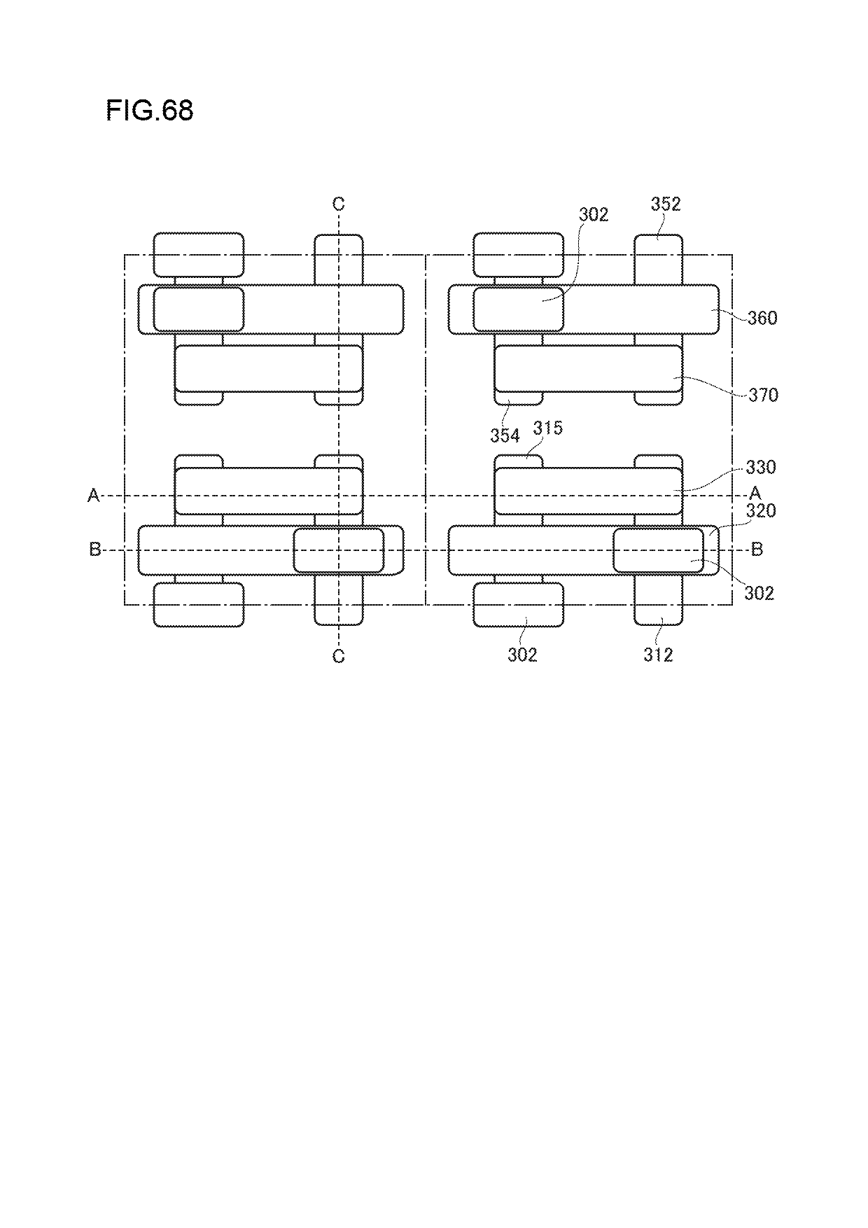

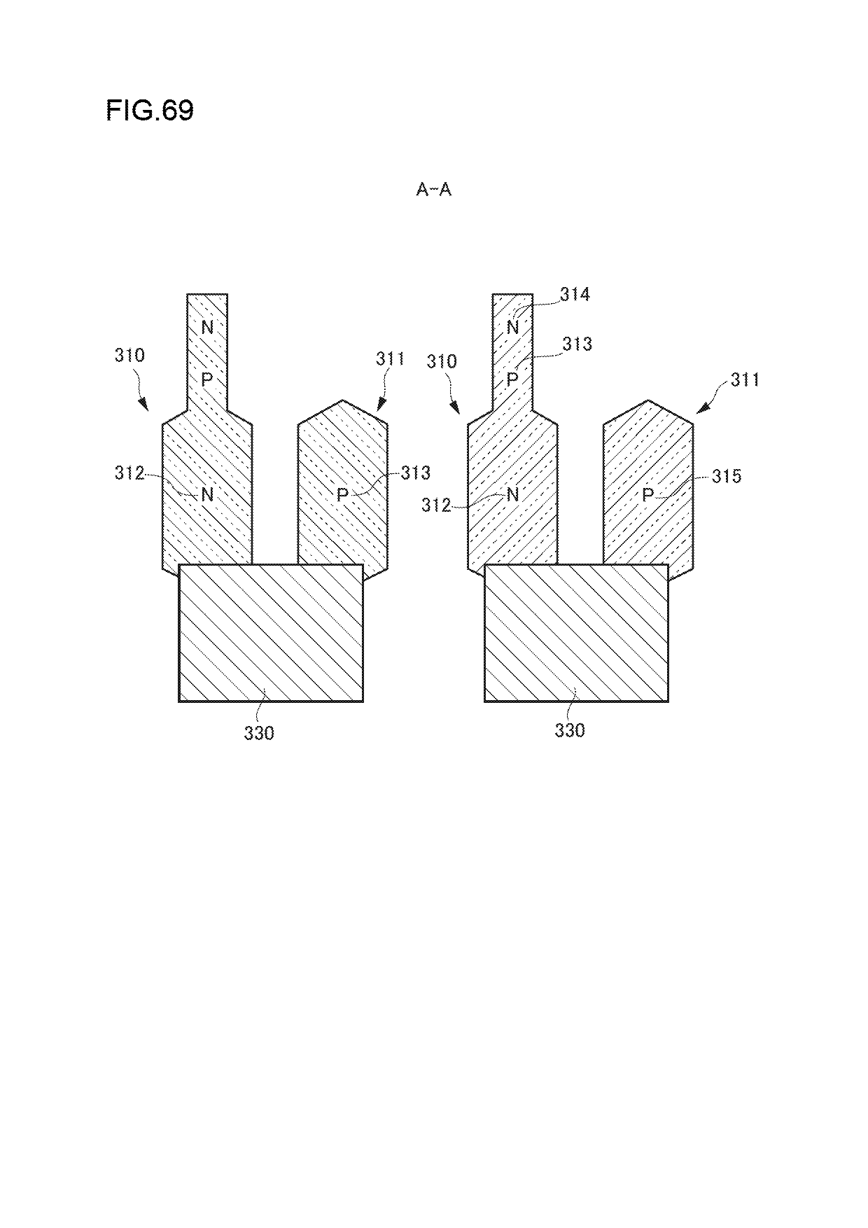

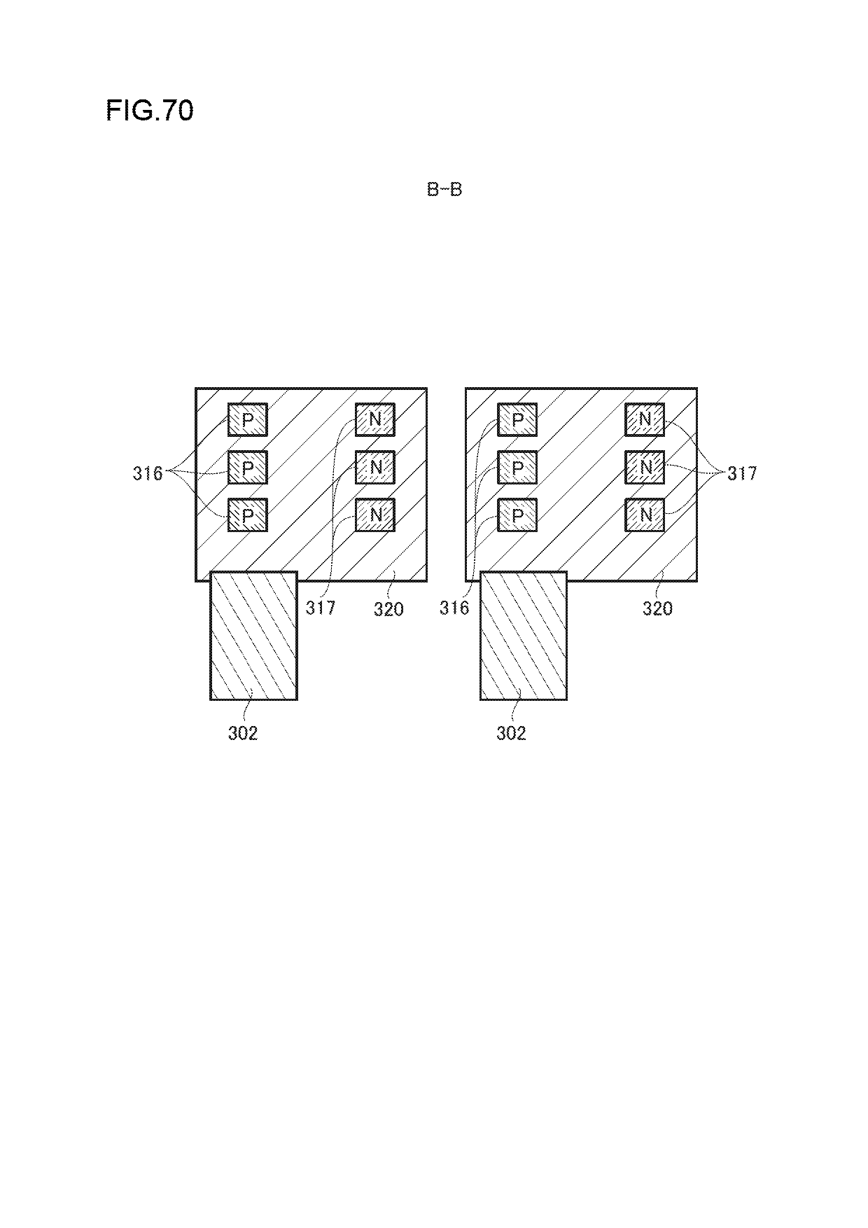

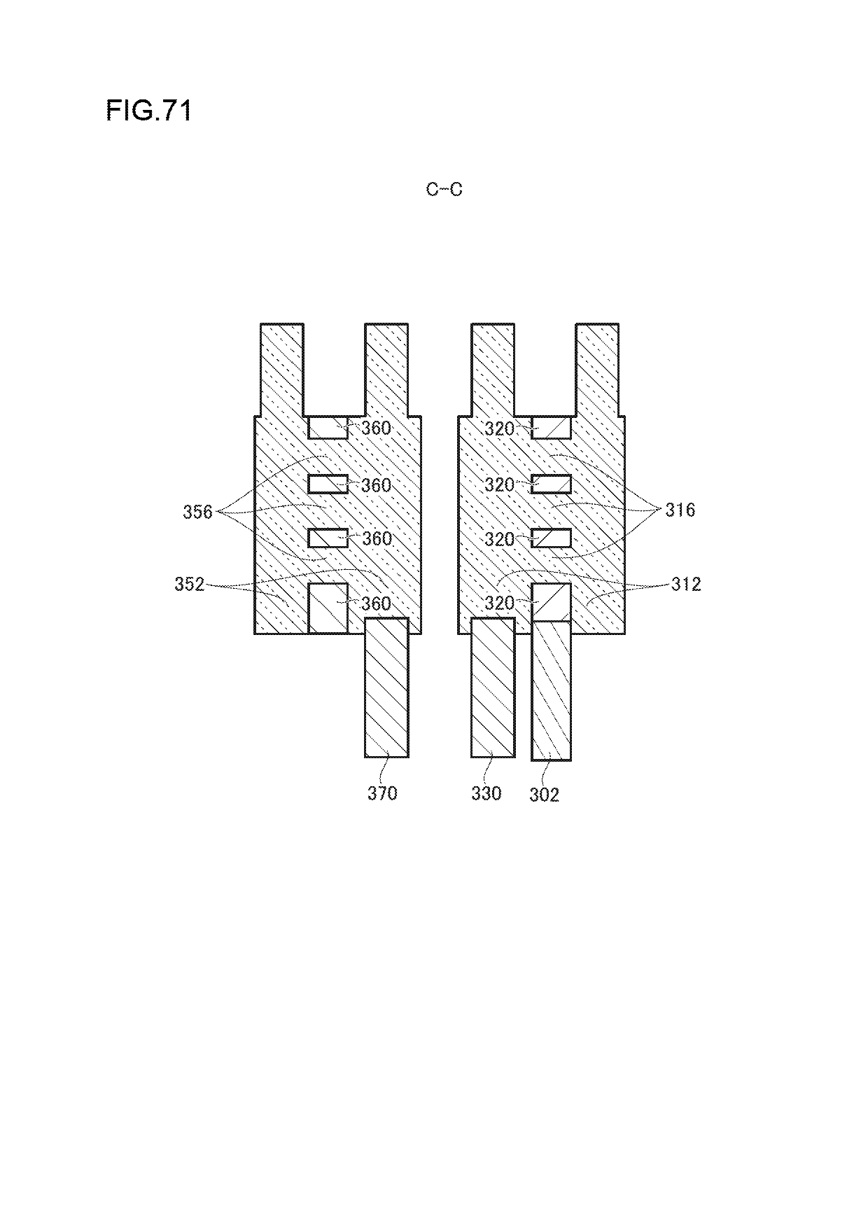

Next, as illustrated in FIGS. 68 to 71, a semiconductor layer above the gate electrode 320, 360 is removed in a region excluding the P-type semiconductor layer 313, 353 and the N-type semiconductor layer 314, 354 to be the transistor M5, M6 from a surface (back surface side) from which the substrate 306 has been removed. As a result, as illustrated in FIG. 69, the N-type semiconductor layer 314 on the P-type semiconductor layer 315 is removed. In addition, as illustrated in FIG. 70, the P-type semiconductor layer 313 and the N-type semiconductor layer 314 on the gate electrode 320 are removed. Furthermore, as illustrated in FIG. 71, a surface of the gate electrode 320, 360 which is an uppermost layer is exposed.

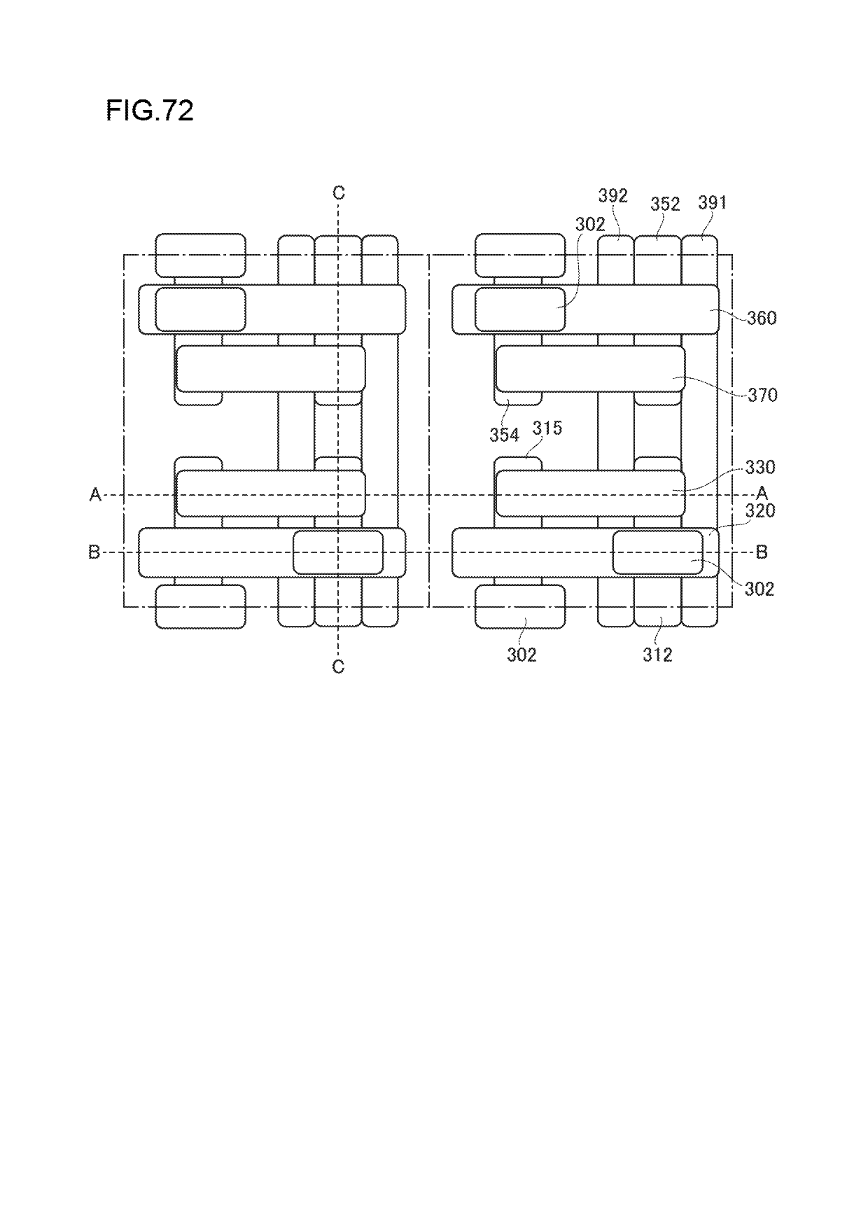

Next, as illustrated in FIGS. 72 to 75, the word line 391, 392 is formed on side surfaces of the P-type semiconductor layer 313, 353 and the N-type semiconductor layer 314, 354 to be the transistor M5, M6. A gate electrode of the transistor M5, M6 is formed by the word line 391, 392.

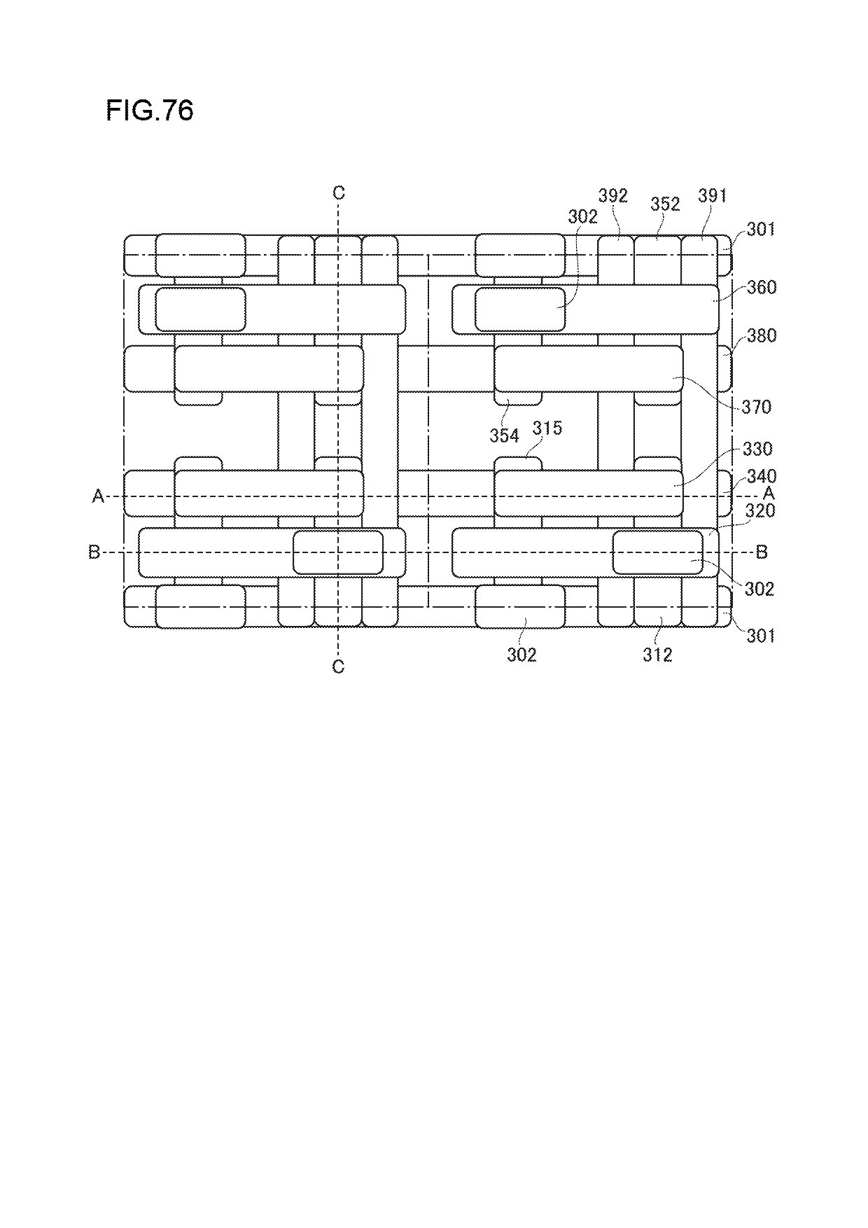

Next, as illustrated in FIGS. 76 to 79, the first bit line 340, the second bit line 380, and the VDD 301 are formed. The first bit line 340 is formed on the N-type semiconductor layer 314 in which the P-type semiconductor layer 313 is formed below. The second bit line 380 is formed on the N-type semiconductor layer 354 in which the P-type semiconductor layer 353 is formed below. The VDD 301 is formed on the N-type semiconductor layer 314, 354 in which the P-type semiconductor layer 313, 353 is not formed below. The first bit line 340, the second bit line 380, and the VDD 301 are continuously formed in the adjacent SRAM cells 300.

Through the above steps, it is possible to manufacture a semiconductor device (SRAM cell) in which nanosheet transistors having a GAA-FET structure are arranged planarly, illustrated in FIGS. 56 to 59.

According to the semiconductor devices of the first to third embodiments described above, each of the transistors M1 to M4 is constituted by GAA-FET. Therefore, the cell size of the semiconductor device can be reduced, and the integration density of the semiconductor device can be improved. In particular, each of the semiconductor devices of the first and second embodiments has a CFET structure in which the transistor M1 and the transistor M3 are stacked and the transistor M2 and the transistor M4 are stacked, and the vertical transistor M5, M6 is formed on CFET in each of the semiconductor devices. Therefore, the formation area of the transistor M5, M6 is not added to the formation area of the transistors M1 to M4. As a result, the element area of the SRAM cell can be reduced by reducing the formation area of the transistors M1 to M4. Therefore, the cell size of the semiconductor device can be further reduced, and the integration density of the semiconductor device can be further increased.

Note that the present invention is not limited to the structures described in the above-described embodiments, and various modifications and changes can be made without departing from the structure of the present invention.

### Reference Signs List

100, 200, 300 SRAM cell

101, 301, 302 POWER SUPPLY VOLTAGE (VDD)

102 Ground (GND)

102, 120, 160, 192, 320, 360 Gate electrode

103, 104, 308 Wiring line

105, 121, 161 Dummy gate

106, 306 Substrate

107 STI

108 Insulating layer

110, 150, 310, 311, 350, 351 Semiconductor layer

111, 113, 116, 141, 151, 153, 156, 312, 314, 317, 352, 354 N-type semiconductor layer

112, 114, 115, 152, 154, 155, 313, 315, 316, 353, 356 P-type semiconductor layer

130, 170 FET junction contact

131, 171, 330, 370 PN junction contact

132 Ti/TiN layer

140, 340 First bit line

180, 380 Second bit line

190, 391 Word line

191 Word contact

1. A semiconductor device comprising a plurality of semiconductor elements on a substrate, wherein each of the plurality of semiconductor elements includes a first nanosheet semiconductor element, a second nanosheet semiconductor element, and a vertical semiconductor element, and includes a contact that connects the first nanosheet semiconductor element and the second nanosheet semiconductor element, and the vertical semiconductor element is disposed between the substrate and the first nanosheet semiconductor element.

2. The semiconductor device according to claim 1, wherein the second nanosheet semiconductor element is stacked on the first nanosheet semiconductor element, and the contact is formed between a layer of the first nanosheet semiconductor element and a layer of the second nanosheet semiconductor element.

3. The semiconductor device according to claim 1, wherein the second nanosheet semiconductor element is stacked on the first nanosheet semiconductor element, and the contact is continuously formed on a side surface of the first nanosheet semiconductor element and a side surface of the second nanosheet semiconductor element.

4. The semiconductor device according to claim 1, wherein a channel region of the vertical semiconductor element is formed adjacent to a source/drain region of the first nanosheet semiconductor element.

5. The semiconductor device according to claim 4, wherein the first nanosheet semiconductor element and the vertical semiconductor element share one source/drain region.

6. A semiconductor device comprising a plurality of semiconductor elements on a substrate, wherein each of the plurality of semiconductor elements includes at least a first nanosheet semiconductor element, a second nanosheet semiconductor element, and a third nanosheet semiconductor element, the second nanosheet semiconductor element is stacked on the first nanosheet semiconductor element, the first nanosheet semiconductor element and the third nanosheet semiconductor element are arranged in parallel to a surface of the substrate, there is a contact connecting the first nanosheet semiconductor element and the second nanosheet semiconductor element in an element isolation region between the first nanosheet semiconductor element and the second nanosheet semiconductor element, and a gate of the first nanosheet semiconductor element, a gate of the third nanosheet semiconductor element, and the contact are isolated from each other.

7. A method for manufacturing a semiconductor device including a first nanosheet semiconductor element, a second nanosheet semiconductor element, and a vertical semiconductor element on a substrate, the method comprising: a step of forming a channel region constituting the vertical semiconductor element and one source/drain region on the substrate; a step of forming a stack of a first semiconductor layer and a sacrificial layer on the channel region of the vertical semiconductor element; a step of forming a stack of a second semiconductor layer and a sacrificial layer; a step of removing the sacrificial layers, embedding a metal layer, and forming a gate electrode covering a periphery of the first semiconductor layer and the second semiconductor layer in a cross section in a gate width direction; a step of forming source/drain regions on side surfaces of the first semiconductor layer and the second semiconductor layer; and a step of forming a contact connecting the source/drain regions formed on the side surfaces of the first semiconductor layer and the second semiconductor layer.

8. The method for manufacturing a semiconductor device according to claim 7, wherein in the step of forming the gate electrode, a plurality of rows of the gate electrodes sandwiching one row of dummy gates are formed, a step of forming element isolation by removing and digging the dummy gates and a semiconductor layer between layers of the dummy gates is included, and in the step of forming the contact, the contact is formed between the first semiconductor layer and the second semiconductor layer from the element isolation region.

9. The method for manufacturing a semiconductor device according to claim 7, wherein in the step of forming the gate electrode, a plurality of rows of the gate electrodes sandwiching two rows of dummy gates are formed, a step of forming element isolation by removing and digging the two rows of dummy gates and a semiconductor layer between layers of the dummy gates is included, and in the step of forming the contact, the contact is formed on side surface of the first semiconductor layer and the second semiconductor layer in the element isolation region.
